(19) United States
(12) Patent Application Publication
(10) Pub. No.: US 2025/0341025 A1
(43) Pub. Date: Nov. 6, 2025

(54) PEROVSKITE SUPERLATTICES WITH EFFICIENT CARRIER DYNAMICS

(71) Applicant: THE REGENTS OF THE UNIVERSITY OF CALIFORNIA, Oakland, CA (US)

(72) Inventors: Yusheng LEI, La Jolla, CA (US); Sheng XU, La Jolla, CA (US)

(21) Appl. No.: 18/698,945

(22) PCT Filed: Oct. 28, 2022
(86) PCT No.: PCT/US2022/048156

§ 371 Date: Apr. 5, 2024

Related U.S. Application Data
(60) Provisional application No. 63/272,734, filed on Oct. 28, 2021.

(51) Int. Cl. C30B 29/68; C30B 7/00; C30B 7/06; C30B 29/12; C30B 29/54; H10K 30/40; H10K 85/50

(52) U.S. Cl. CPC C30B 29/68; C30B 7/005; C30B 7/06; C30B 29/12; C30B 29/54; H10K 30/40; H10K 85/50

(57) ABSTRACT

A method of forming a perovskite superlattice includes providing a single crystal substrate. The single crystal substrate is exposed to a precursor composition having ions and molecules therein of which a perovskite is composed to thereby form a perovskite superlattice on the single crystal substrate. The perovskite superlattice includes at least one series of layers having alternating inorganic slabs and organic spacers. The single crystal substrate and the inorganic slabs have lattice constants that differ from one another by less than a prescribed amount.

### BACKGROUND

Metal halide perovskites, with a general formula of AMX₃ (e.g., A=CH₃NH₃⁺ (MA), HC(NH₂)₂⁺, Cs⁺, Rb⁺; M=Pb²⁺, Sn²⁺; X=Cl⁻, Br⁻, I⁻), are emerging as next-generation optoelectronic materials because of their phenomenal performance and processability in low-cost solutions. However, their practical applications have been hindered by three issues: instability, electrical hysteresis, and toxicity. Recently, low-dimensional (two-dimensional (2D) and quasi-2D) metal halide perovskites with a formula of B₂Aₙ₋₁MₙX₃ₙ₊₁ (e.g., B═R—NH₃⁺) have been invented to mediate the instability and hysteresis issues. In these materials, the insulating ammonium interlayer spacers divide the semiconductive metal-halide structure into slabs, forming a multiple-quantum-well. Existing single crystals are grown with the insulating organic spacers parallel to the substrate surface and cannot support carrier transport in the film thickness direction, which is required for device integration. Moreover, the strong confinement of the multiple-quantum-well leads to a large exciton binding energy, which limits the generation and transport of carriers within the inorganic slabs. Polycrystals contain grain boundaries that further compromise carrier dynamics. Even though 3D/2D polycrystalline thin films have been fabricated, the 2D components are introduced by conventional surface passivation strategies for 3D perovskites but not a way to engineer the 2D structure. As a result, the orientation, lattice strain, and carrier dynamics of formed low-dimensional perovskites are still uncontrollable. Furthermore, lead-free metal halide perovskites have been developed, but their device performance is limited by their low crystallinity and structural instability.

### SUMMARY

In one aspect, described herein is a low-dimensional metal halide perovskite superlattice with efficient carrier transport in three dimensions that is fabricated by epitaxial growth. Epitaxy on a slightly lattice-mismatched substrate compresses the organic spacers in the superlattice, which weakens the quantum confinement and further improves carrier dynamics. The performance of a low-dimensional perovskite superlattice solar cell has been certified under the quasi-steady state for the first time. Moreover, the resulting device shows an unusually high open-circuit voltage, due to a unique intra-band exciton relaxation mechanism.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Furthermore, the claimed subject matter is not limited to implementations that solve any or all disadvantages noted in any part of this disclosure.

### BRIEF DESCRIPTION OF THE DRAWINGS

FIGS. 1(a)-1d) present structural characterizations of the BA₂SnI₄ superlattice.

FIGS. 2(a)-2(f) illustrate carrier transport properties of the BA₂SnI₄ superlattice.

FIGS. 3(a)-3(d) illustrate strain properties of BA₂MAₙ₋₁SnₙI₃ₙ₊₁ superlattices.

FIGS. 4(a)-4(e) present photovoltaic studies of Bi³⁺-alloyed BA₂MA₂Sn₃I₁₀ superlattices.

FIGS. 5(a)-5(b) illustrate a dynamics analysis of hot electrons in Bi³⁺-alloyed superlattices.

FIGS. 6(a)-6(c) show schematics of different epitaxial models.

FIG. 7 shows detailed merging processes of epitaxial low-dimensional perovskites.

FIG. 8 shows epitaxial growth of low-dimensional perovskites on different 3D perovskite substrates.

FIGS. 9 (a)-9(c) show studies of the precursors' n-purity.

FIG. 10 shows fabrication of superlattices on commercially available BaF₂ substrates.

FIGS. 11 (a)-11(b) show mapping of the d-spacing.

FIG. 12 shows cross-sectional high-resolution STEM image of a polycrystalline film.

FIGS. 13(a)-13(b) show Grazing-Incidence Wide-Angle X-ray Scattering mapping of superlattices and polycrystalline thin films.

FIG. 14 shows schematics of polarized photocurrent measurements.

FIGS. 15(a)-15(c) show orientation-dependent transient photovoltage measurements.

FIG. 16 shows SEM images of polycrystalline thin films.

FIGS. 17(a)-17(c) show schematics of transient photocurrent measurements of different device structures.

FIG. 18 shows fabrication processes for in-situ superlattice devices.

FIGS. 19(a)-19(b) show configuration of in-situ fabricated devices.

FIGS. 20(a)-20(b) show imperfect merging in the superlattice.

FIG. 21 shows schematic models of the epitaxial lattice strain.

FIG. 22 shows Fourier-transform infrared spectroscopy characterizations.

FIGS. 23(a)-23(b) show a summary of degradation of superlattices with different n-values.

FIGS. 24(a)-24(b) show degradation in the superlattice.

FIG. 25 shows bandgaps for conventionally grown and superlattice low-dimensional Sn perovskites.

FIG. 26 shows simulated unit cell of the BA₂MA₂Sn₃I₁₀ (n=3) superlattice.

FIGS. 27(a)-27(b) show total energy calculations with Bi³⁺ alloying.

FIGS. 28(a)-28(b) show XRD and PL characterizations of the Bi³⁺ alloyed superlattice.

FIGS. 29(a)-29(b) show calculated electronic structures of the Bi³⁺ alloyed BA₂MA₂Sn₃I₁₀ superlattice.

FIG. 30 shows calculated electronic structures of the BA₂MA₂Sn₃I₁₀ superlattice when Bi³⁺ replaces Sn²⁺ at different sites.

FIGS. 31(a)-31(b) show X-ray photoelectron spectroscopy measurements of Bi³⁺ alloyed superlattice.

FIGS. 32(a)-32(b) show textured surfaces and light-trapping properties of the superlattice.

FIGS. 33(a)-33(b) show band structures of the ICBA layer.

FIGS. 34(a)-(c) show the photovoltaic performance of a certificate device.

FIGS. 35(a)-35(d) show stability studies of strain-free superlattices.

FIGS. 36(a)-36(b) show stability studies of strain-free superlattice solar cells.

FIGS. 37(a)-37(b) show the in-situ fabricated flexible superlattice photovoltaics.

FIG. 38 shows schematics of carrier transport in the superlattice photovoltaic device.

FIGS. 39(a)-39(b) show fabrication processes of devices for transient absorption characterizations.

FIGS. 40(a)-40(b) show measurements of transient absorption spectra.

FIGS. 41(a)-41(d) show processes of transient absorption measurements.

FIGS. 42(a)-42(d) show measurements of hot carrier relaxation lifetimes and diffusion lengths without bias.

FIGS. 43(a)-43(b) show measurements of hot carrier relaxation lifetimes with bias.

### DETAILED DESCRIPTION

Described herein is a BA₂MAₙ₋₁SnₙI₃ₙ₊₁ (BA: butylammonium; n=1, 3, 5) superlattice with long-range order. The superlattice was epitaxially grown on a 3D perovskite substrate. The inorganic slabs are aligned vertical to the substrate and interconnected in a crisscross 2D network parallel to the substrate, leading to efficient carrier transport both in-plane and out-of-plane. In addition, due to the lattice mismatch with the substrate, the superlattice is under compressive strain, which reduces the width of the organic spacers. This weakens the quantum confinement of the organic spacers and thus further improves the carrier dynamics of the superlattice. Their efficient carrier dynamics have been proved and certified by an in-situ Bi³⁺-alloyed superlattice solar cell under the quasi-steady state for the first time with a stable 12.36% photoelectric conversion efficiency and an unusually high open-circuit voltage.

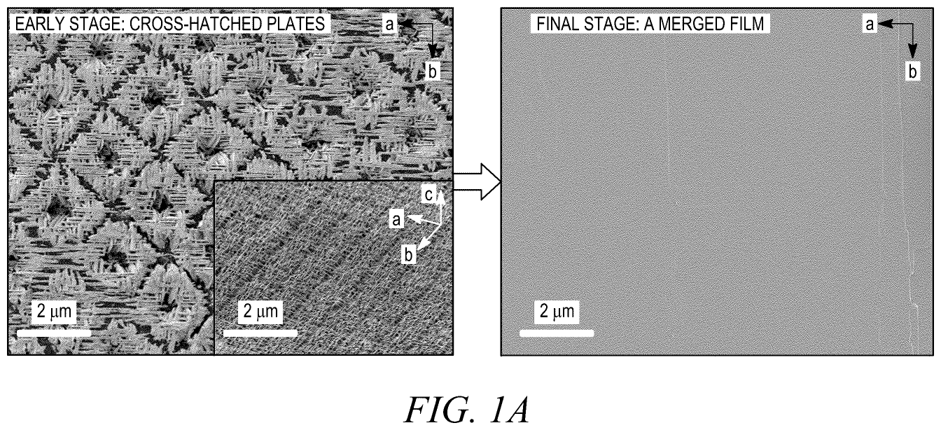

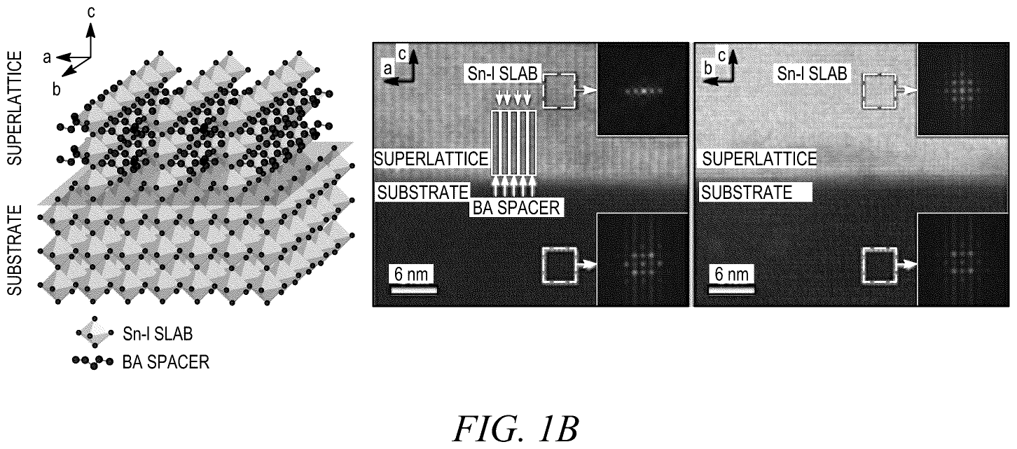

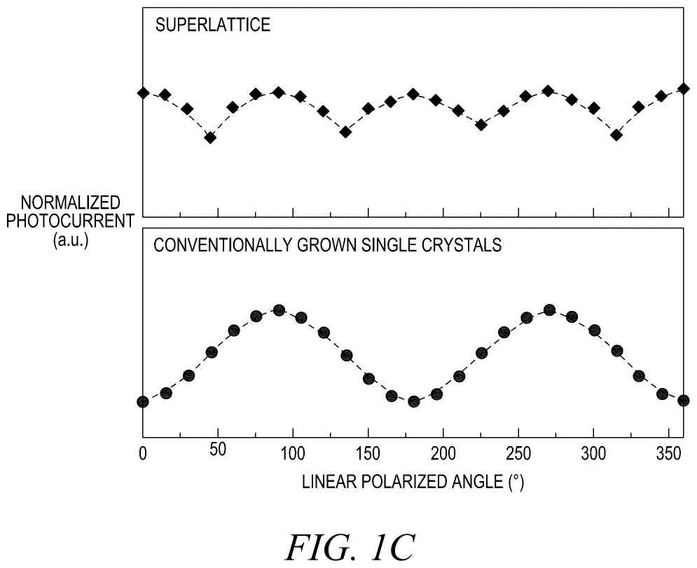

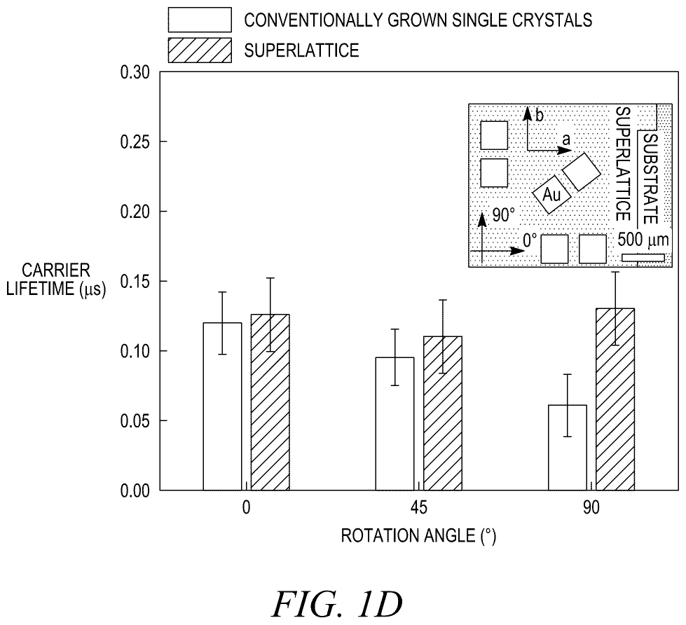

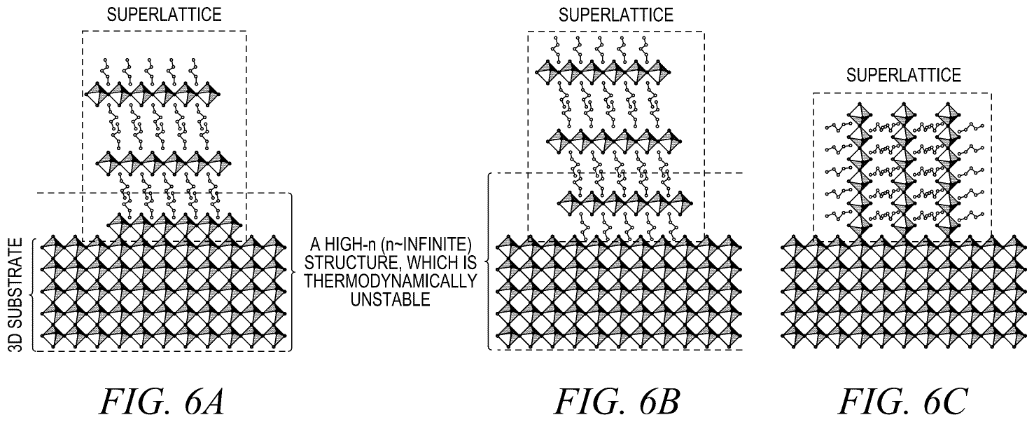

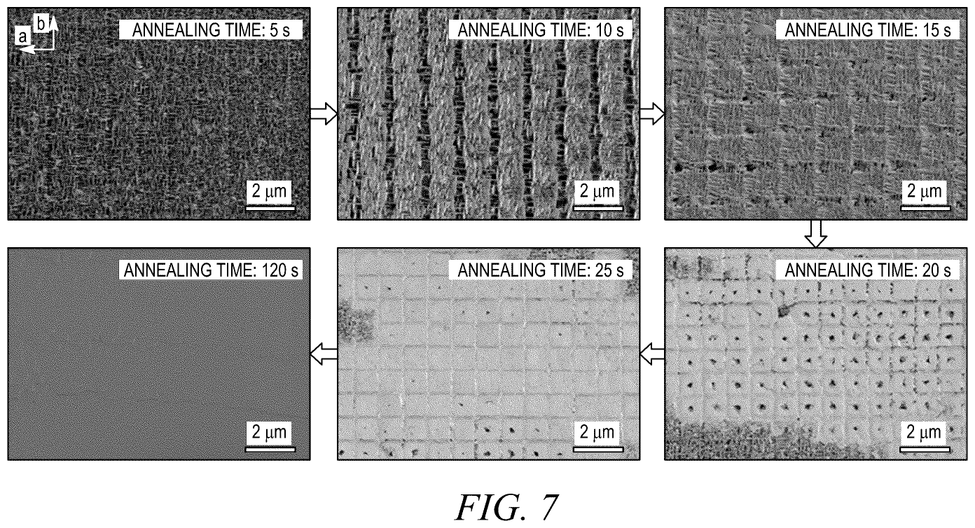

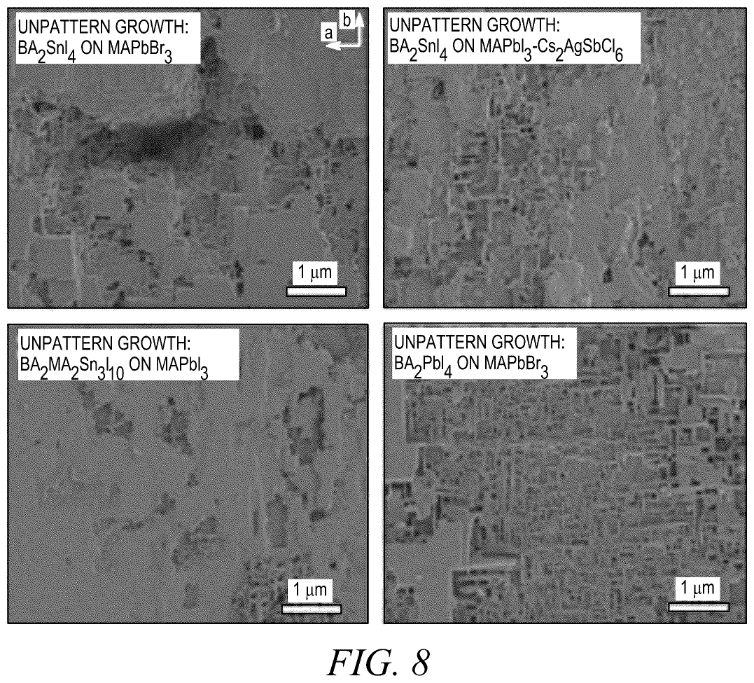

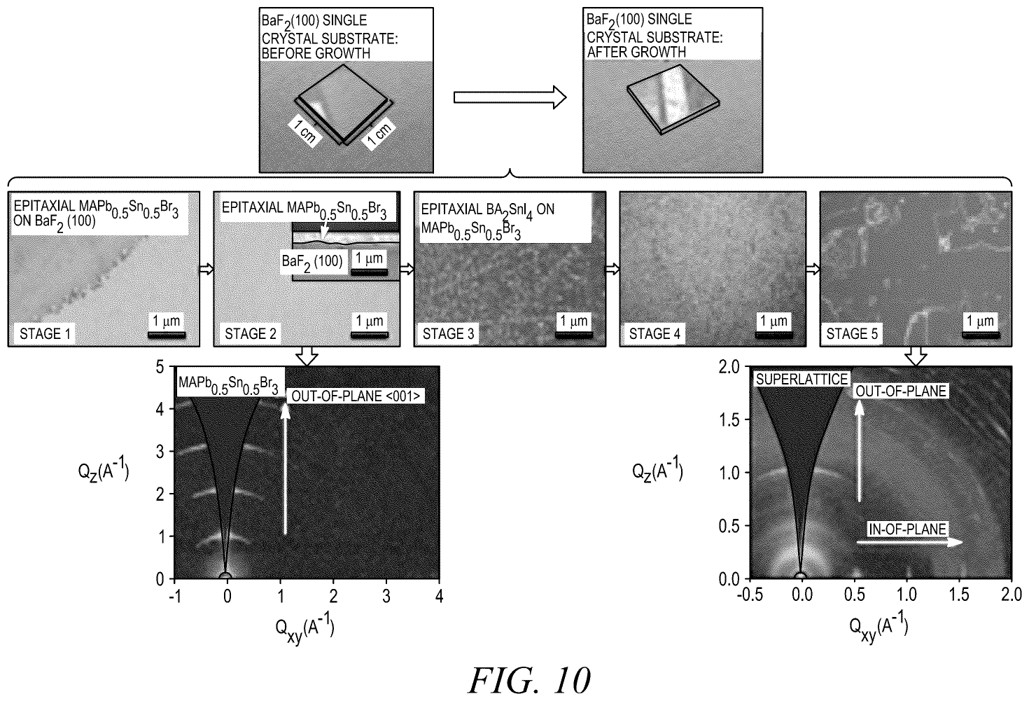

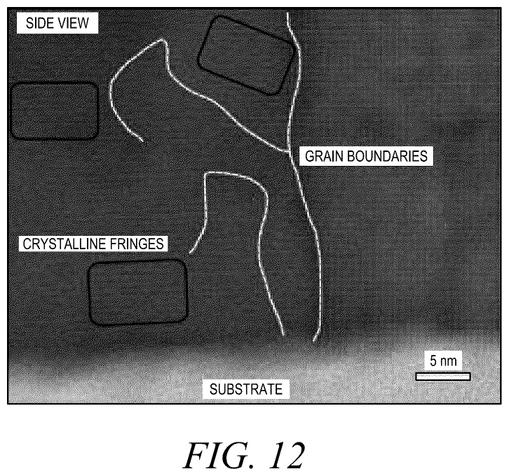

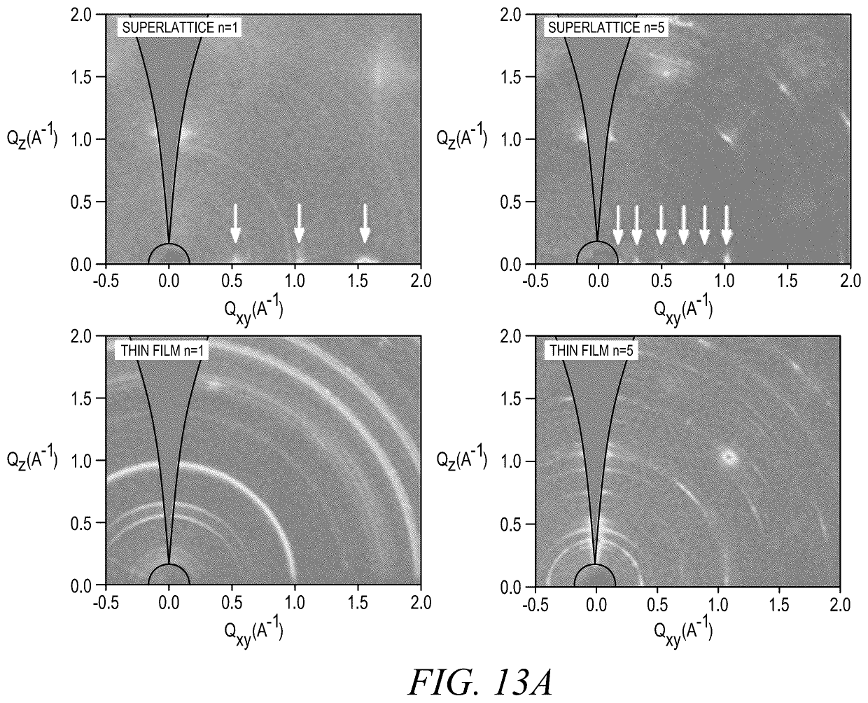

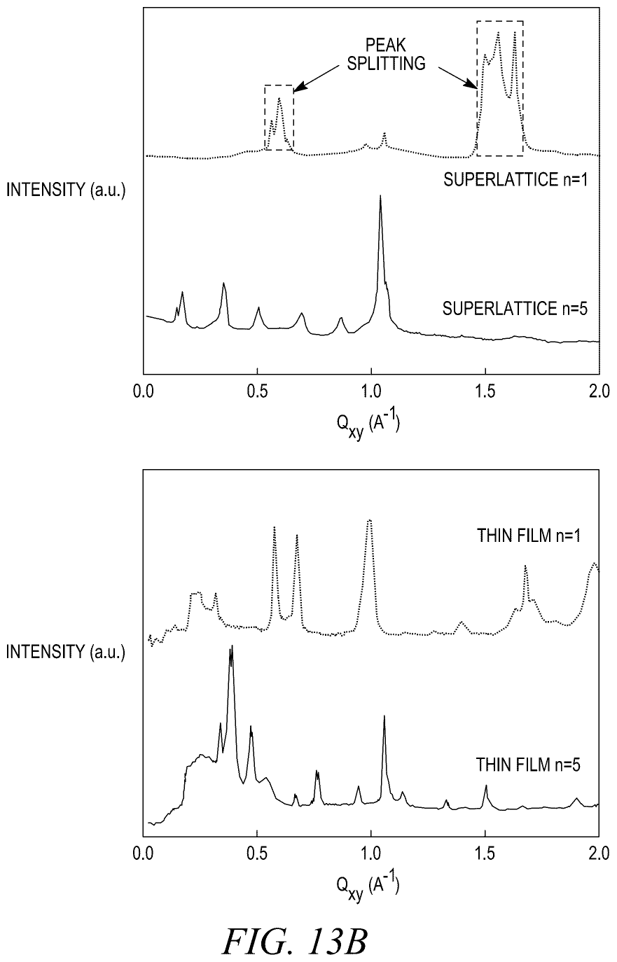

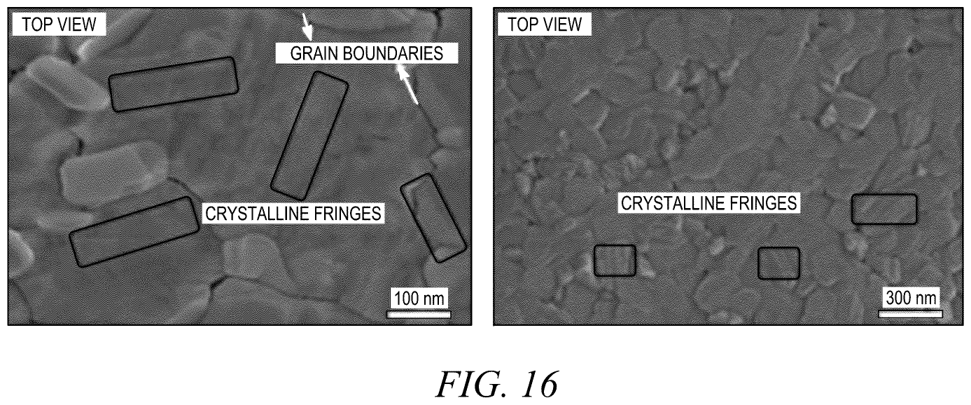

We studied the growth process and structure of BA₂SnI₄ (n=1) superlattice on a MAPb_{0.5}Sn_{0.5}Br₃ substrate. The superlattice is formed by a unique epitaxial mechanism (see the section below concerning the epitaxial superlattice structure and FIGS. 1, 2, 3, and 4). The Sn—I slabs exhibit a favorable epitaxial relationship with the substrate but cannot form a horizontally aligned lattice, which would contain thermodynamic unstable high n value structures (FIG. 6(a)-6(c)). A vertically aligned lattice structure is energetically most favorable under experimental conditions in this work. Scanning electron microscopy images reveal that the crystals first grow into crisscross vertical thin plates (FIG. 1a; FIG. 7). This is because the crystal structure of the substrate is cubic, and therefore the epitaxial growth behavior along the a and b directions is symmetric. As the growth progresses, they merge into a smooth film (FIG. 1a; FIG. 7). Similar growth behavior is observed in other low-dimensional perovskites grown on different 3D perovskite substrates (e.g., double perovskites, FIG. 8; commercially available BaF₂ (001) substrates, FIG. 10), suggesting potential practicability and scalability. Cryogenic-scanning transmission electron microscope was used to study the structure of a single plate, which exhibits an anisotropic structure (FIG. 1b). The a-c plane image shows a periodic distribution of inorganic Sn—I slabs and organic BA spacers along the a direction (FIG. 1b, middle; FIG. 16). The b-c plane image shows a continuous Sn—I slab with a coherent heteroepitaxial interface with the substrate (FIG. 1b, right). Therefore, the crisscross vertical plates on the substrates create a 3D network of Sn—I slabs, unseen in any polycrystals (FIG. 12) or conventionally grown single crystals. Additionally, grazing incidence wide angle x-ray scattering (GIWAXS) has also been carried out to verify the general orientation in epitaxial superlattices (FIG. 13). The epitaxial superlattices exhibit sharp and discrete Bragg spots that almost only appear along the xy and z directions. Specifically, periodic Bragg spots only appear in the xy axis in superlattices, clearly revealing that the inorganic slab/organic spacer quantum wells are perpendicular to the xy directions (i.e., the substrate surface) and parallel to the z direction, confirming their vertical out-of-plane orientations. In contrast, the random arc-like Bragg signals in polycrystalline thin films indicate considerable randomness in the orientation of crystal domains.

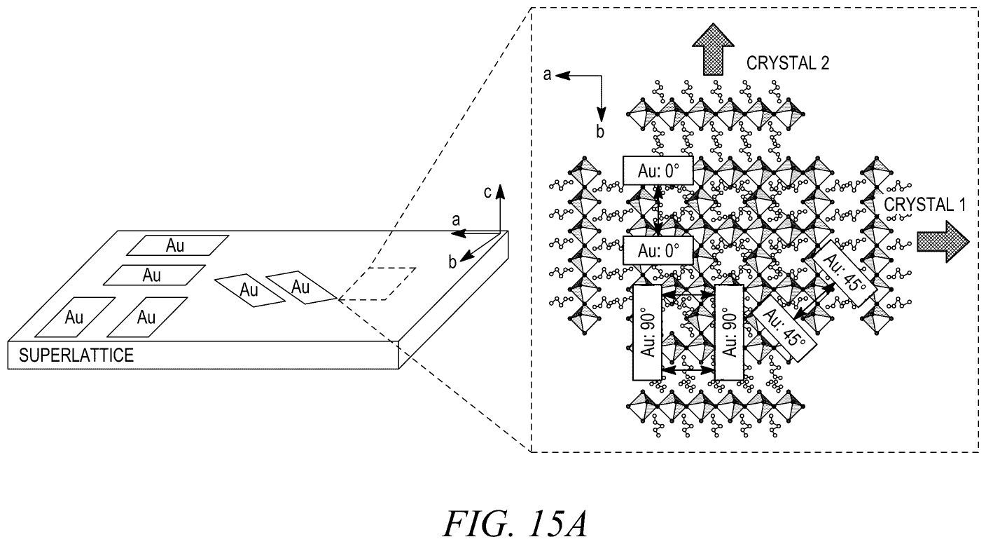

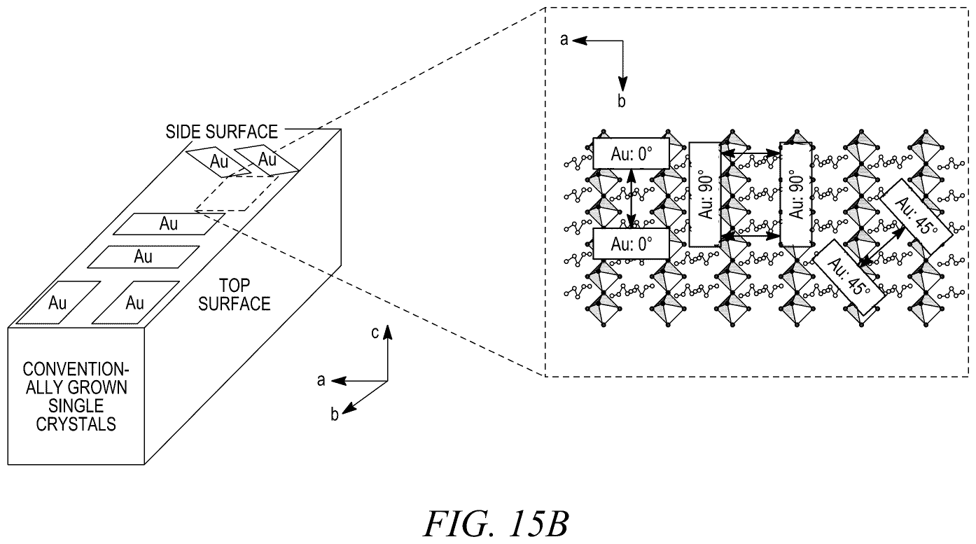

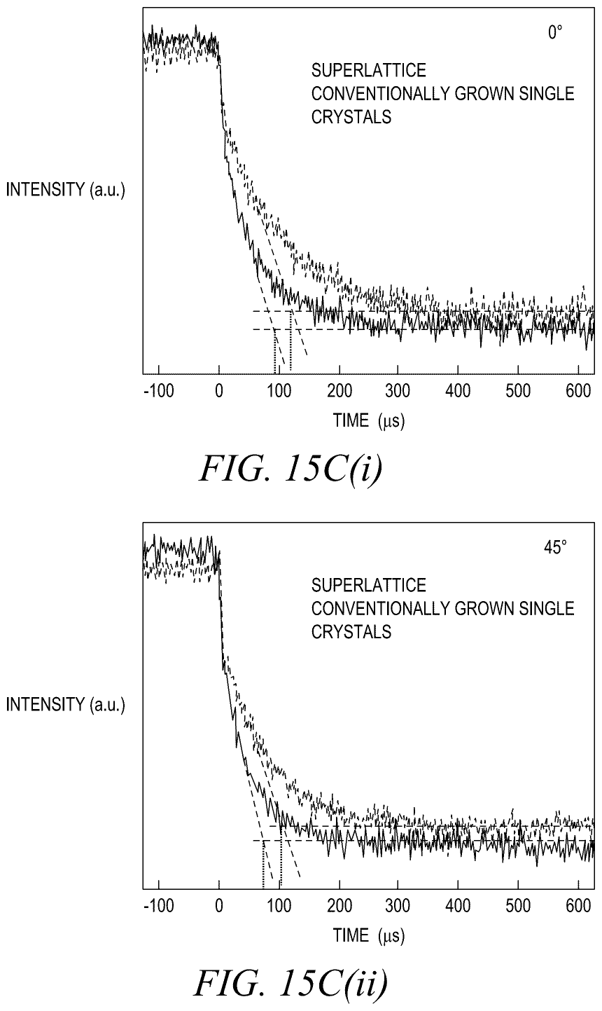

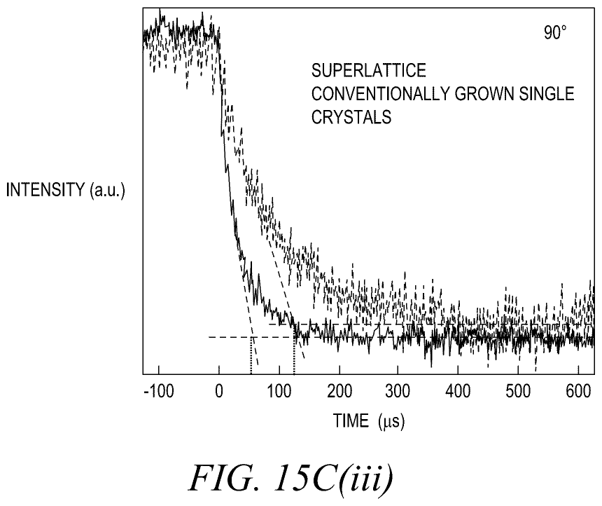

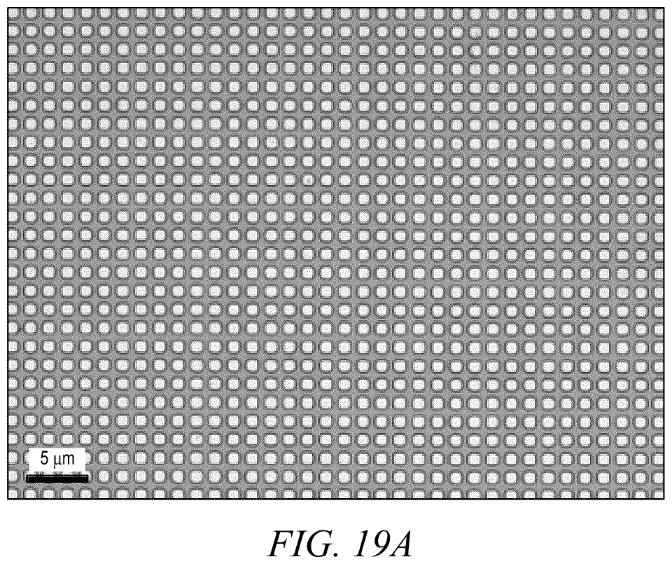

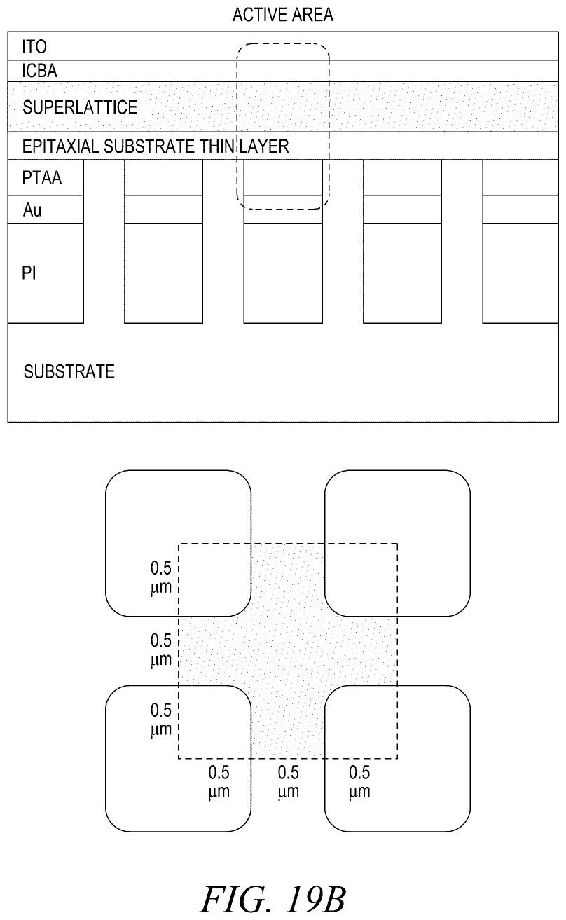

To further study the crystal orientation in the a-b plane, we measured polarization-dependent photocurrent of the superlattice and a conventionally grown single crystal with a linearly polarized excitation source (FIG. 1c). The results in both show a strong dependence on the polarization direction, but the response of the superlattice has a 90° period while that of the conventionally grown single crystal has a 180° period. This is because the inorganic slabs are aligned in two perpendicular orientations in the a-b plane of the superlattice, but in only one orientation of the conventionally grown single crystal (FIG. 19). Similar trends can also be observed in the carrier lifetime obtained from orientation-dependent transient photovoltage measurements (FIG. 1d; FIG. 15). These results collectively support that the superlattice has Sn—I slabs interconnected, with numerous crisscross thin plates merged in the a-b plane.

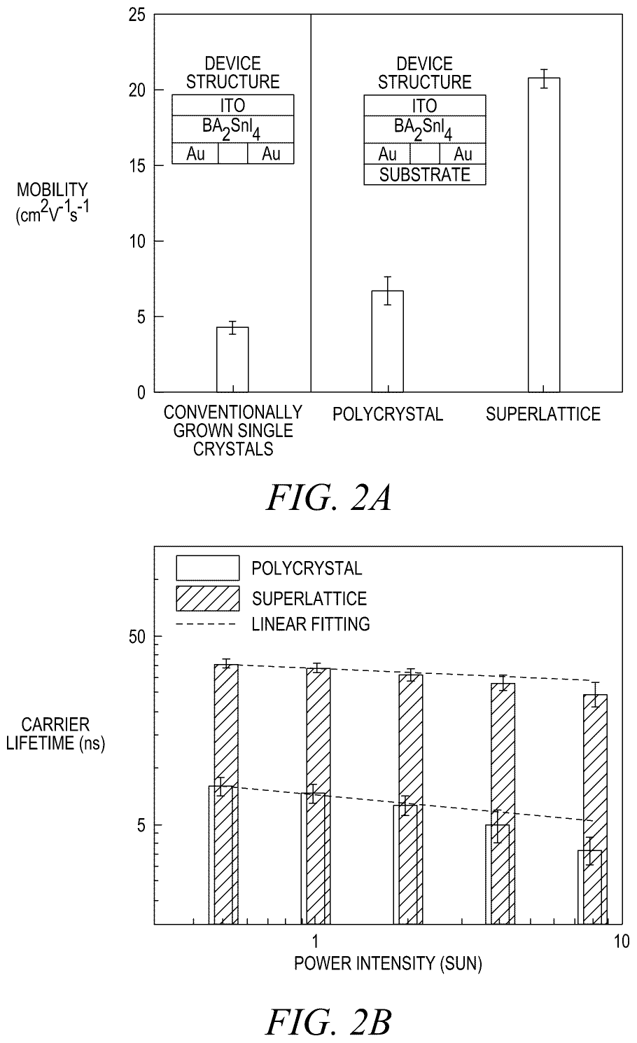

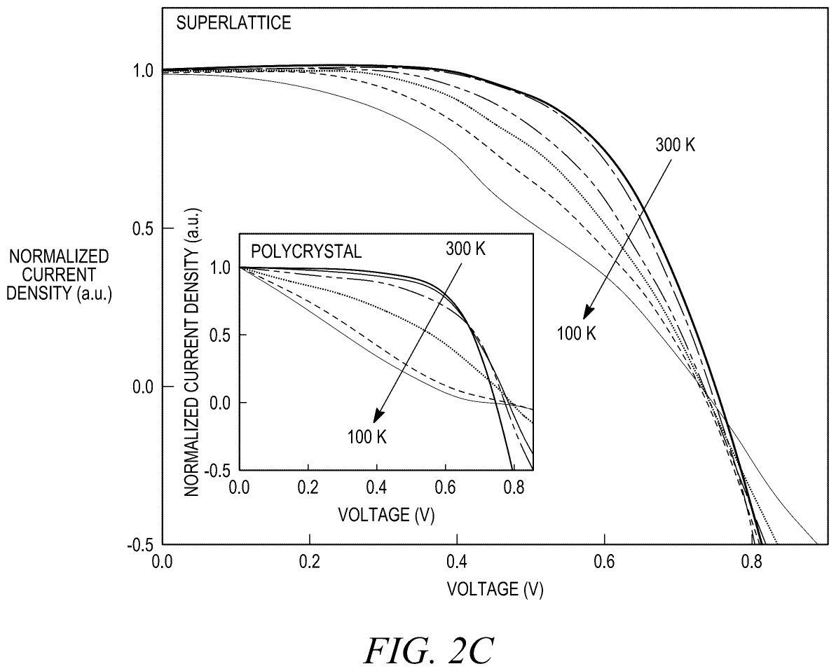

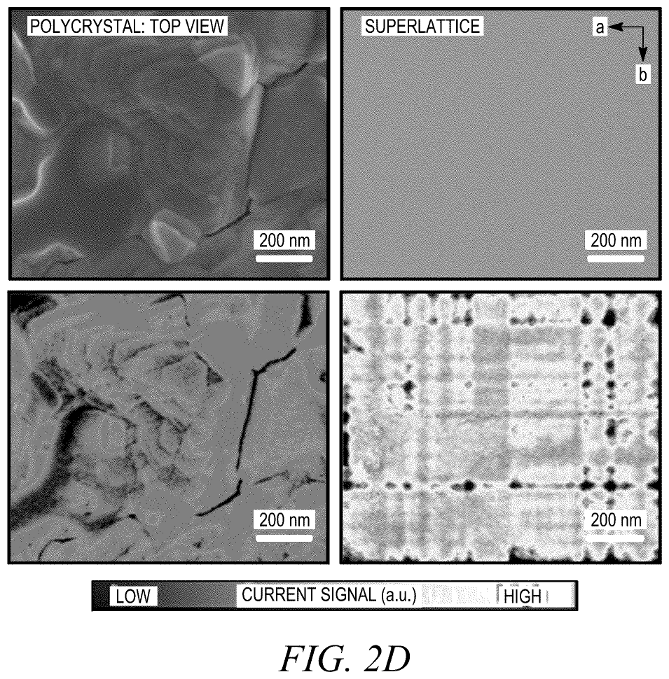

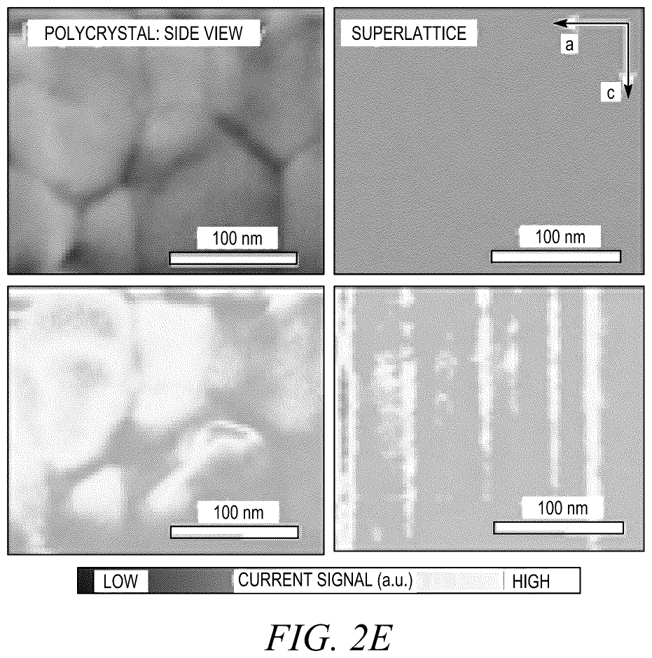

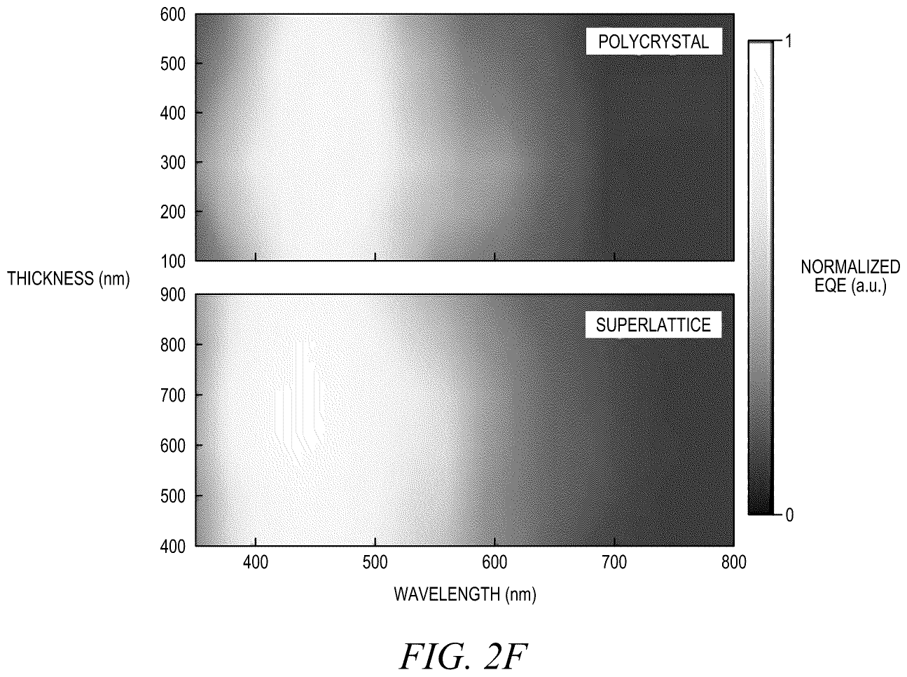

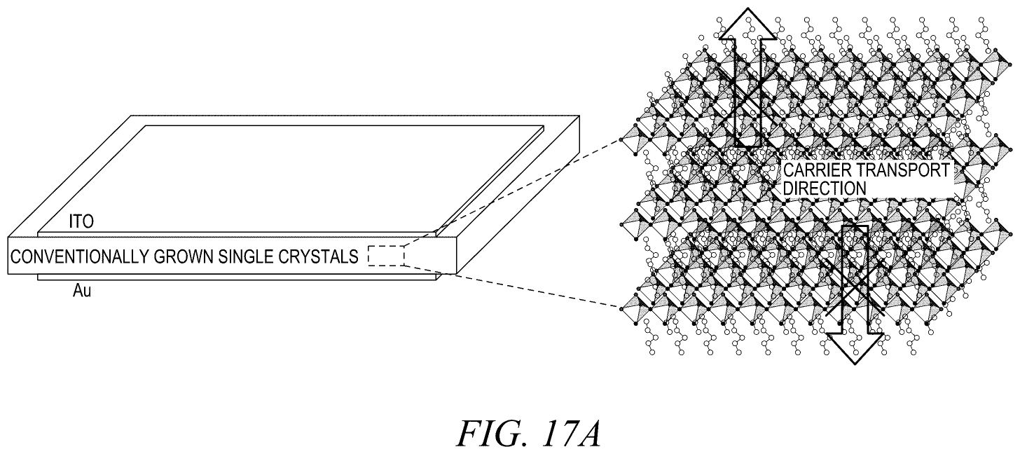

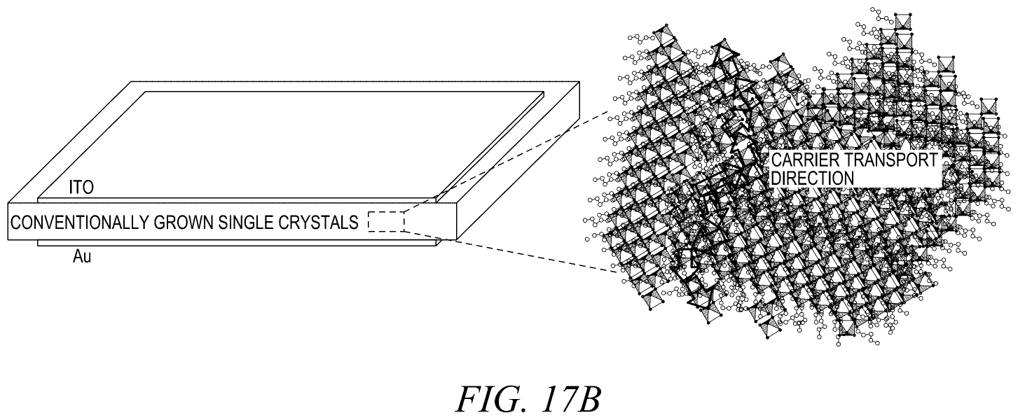

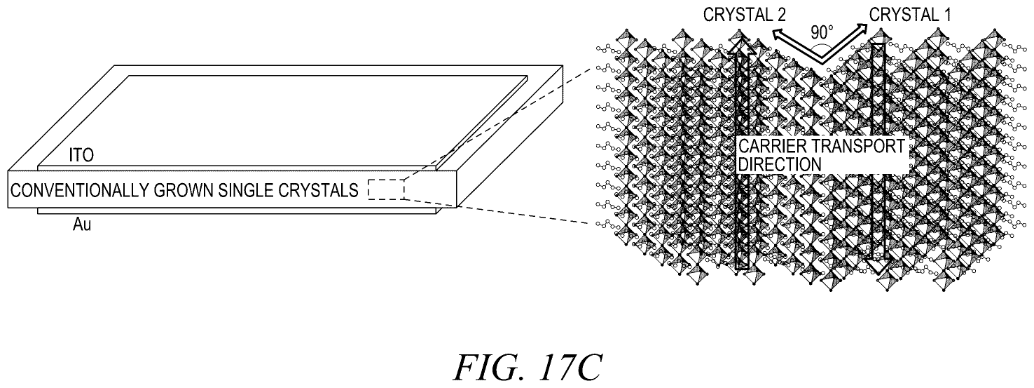

Because of the interconnected Sn—I slabs, carriers in the superlattice does not need to cross any grain boundaries or organic spacers. This allows the superlattice to have more efficient carrier dynamics along the film thickness (c) direction compared to its polycrystalline and conventionally grown single crystal counterparts. Transient photocurrent measurements along the film thickness direction show a much higher carrier mobility in the superlattice than in the polycrystalline or conventionally grown single crystal sample (FIG. 2a). The grain boundaries in the polycrystal act as traps, which significantly reduce carrier mobility (FIG. 16). The conventionally grown single crystal shows the lowest mobility, with only in-plane carrier transport (FIG. 17). Power-dependent time-resolved photoluminescence measurements reveal that the superlattice has a longer carrier lifetime than the polycrystal (FIG. 2b), indicating minimal restriction of the carriers in the superlattice. Additionally, the superlattice shows better tolerance to high excitation power than the polycrystal, suggesting that better crystallinity can reduce material degradation under high excitation power.

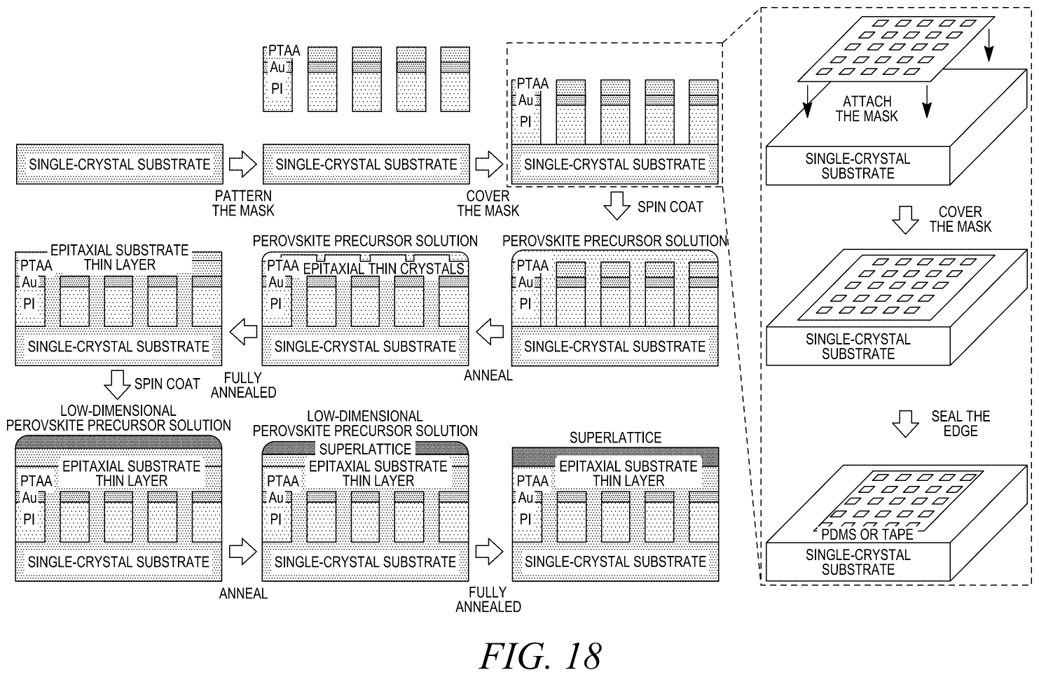

The structural advantages of the superlattice are validated with temperature-dependent photovoltaic J-V characteristics of a BA₂SnI₄ solar cell. BA₂SnI₄ is the most challenging for engineering the quantum mechanics to achieve high-efficiency carrier dynamics compared to higher n-value quasi-2D perovskites, which usually forms the horizontally aligned quantum-well structure and has the highest exciton binding energy and, therefore, the worst carrier dynamics. The effective engineering of BA₂SnI₄ superlattice solar cell here is not a solar cell performance study, but to compare its internal energy barrier for carrier transport with that of polycrystalline BA₂SnI₄. Solar cell fabrication was conducted on the as-grown film as the in-situ device to minimize any possible confounding factors introduced by the fabrication process (see the section below concerning In-situ devices and FIGS. 18, 19, and 20). As the temperature gradually drops, thermal energy becomes too small for the carriers to overcome barriers (e.g., due to ionized impurity scattering), so the fill factor (FE) decreases substantially for both the superlattice and polycrystalline devices (FIG. 2c). However, the decrease is less significant in the superlattice, indicating lower internal energy barriers and a higher charge-collection efficiency.

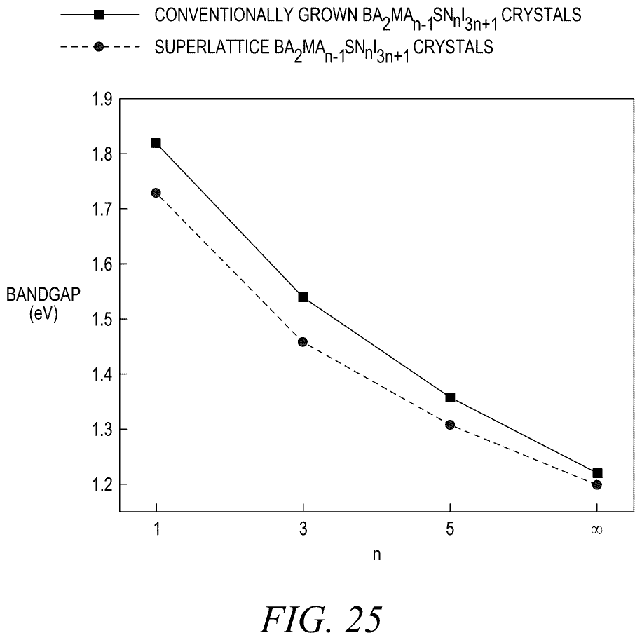

We measured the electron-beam-induced-current to directly visualize carrier transport behaviors. For the polycrystal, the collected currents on the thin film surface heavily depend on the grain orientations, indicating the existence of strong barriers for carrier transport (FIG. 2d, left). In contrast, the superlattice yields higher and much more uniform currents due to the well-aligned crystal structure (FIG. 2d, right). Note that the superlattice currents exhibit a crisscross pattern due to the imperfect merging of the crystals during solution growth (FIG. 25). Similar observations can also be made in the sample cross-sections (see FIG. 2e and the section below concerning EBIC mapping).

The improved carrier dynamics of the superlattice allow a higher absorber thickness and thus more efficient light harvesting. The absorber thickness of the polycrystalline devices is usually highly restricted because of the limited carrier diffusion length. For polycrystalline BA₂SnI₄, the external quantum efficiency (EQE) peaks at an absorber thickness of ˜400 nm (FIG. 2f, top). Due to the improved carrier dynamics in the superlattice, the absorber thickness can be increased to ˜700 nm with enhanced light absorption and thus EQE (FIG. 2f, bottom).

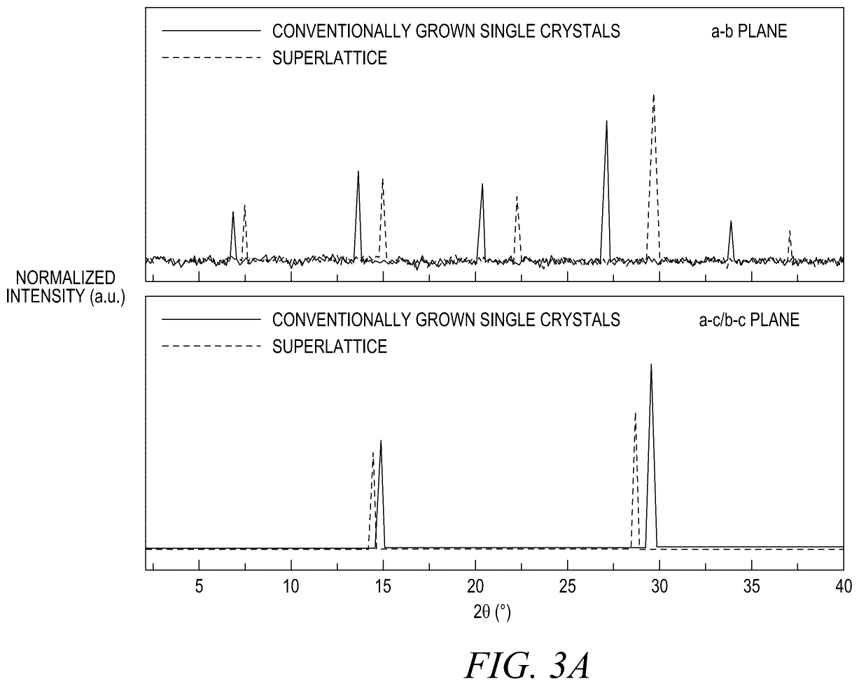

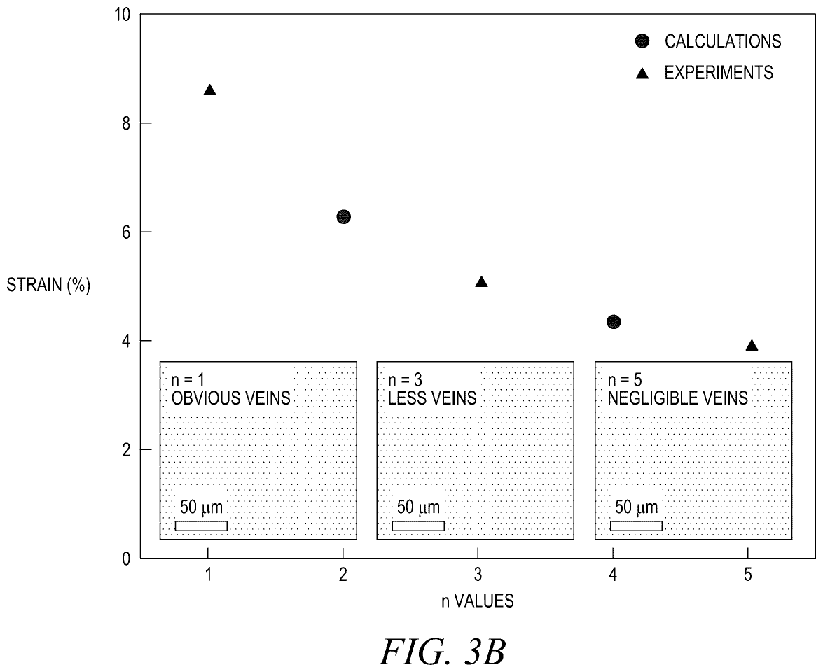

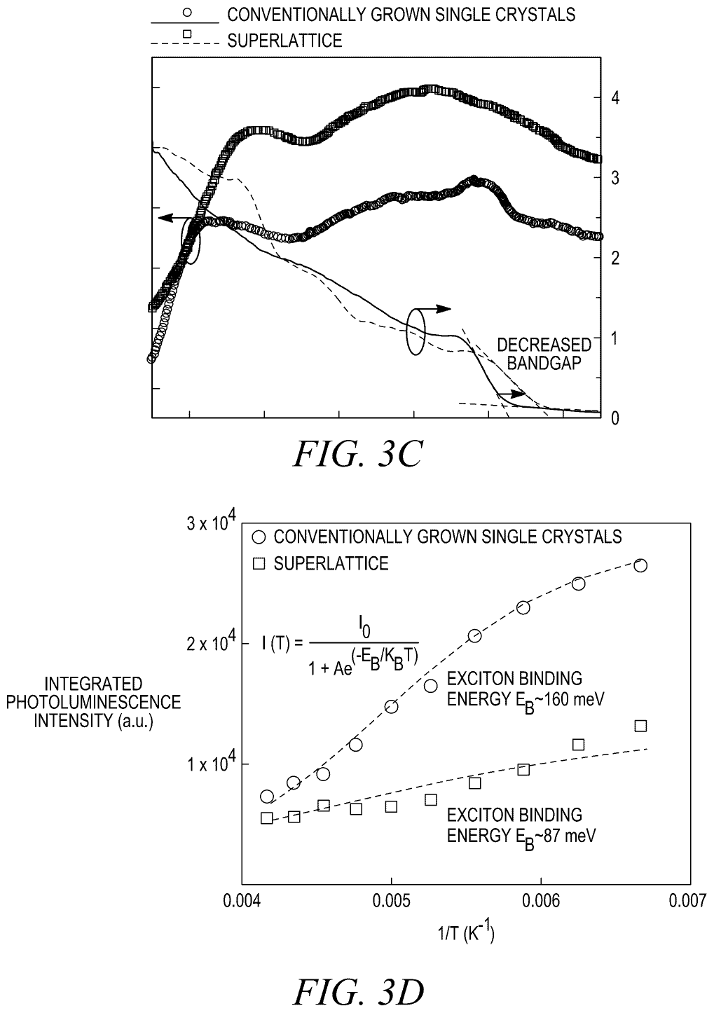

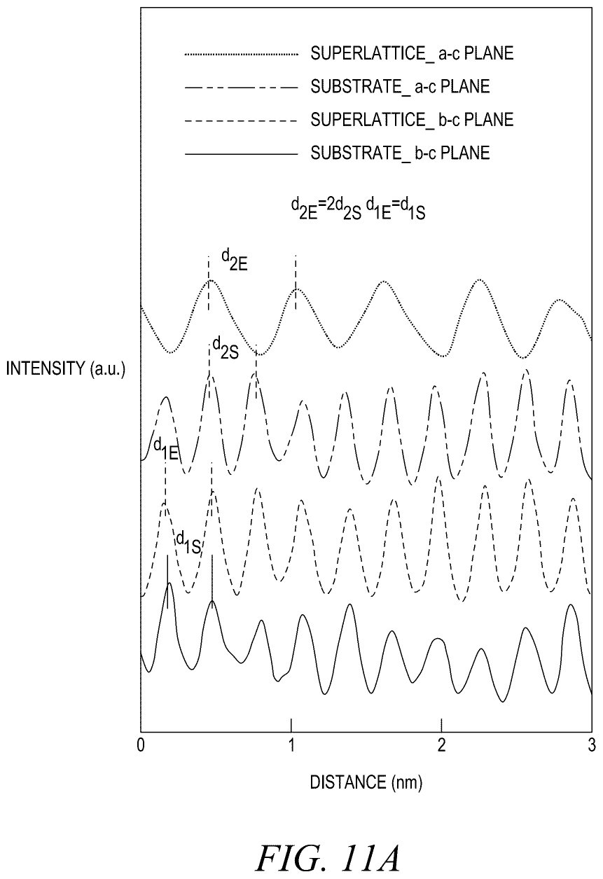

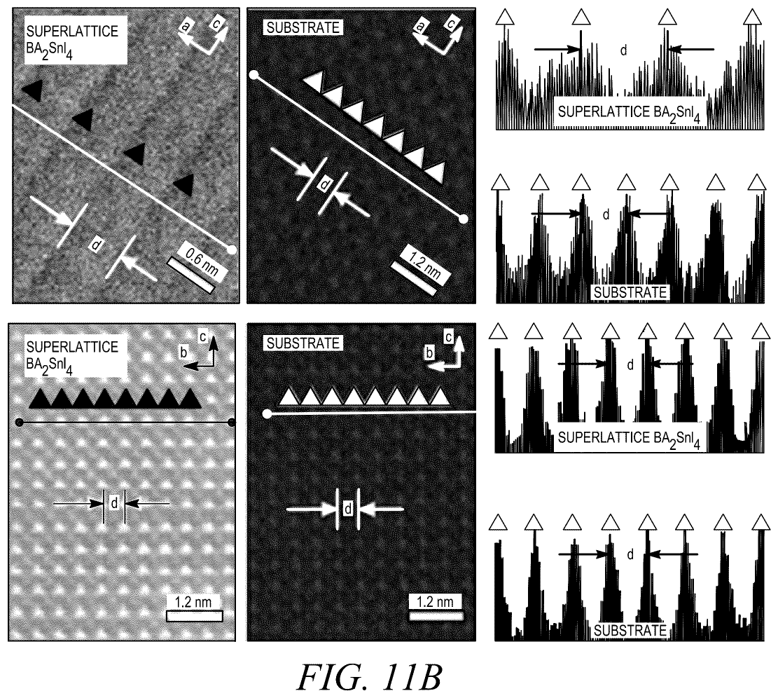

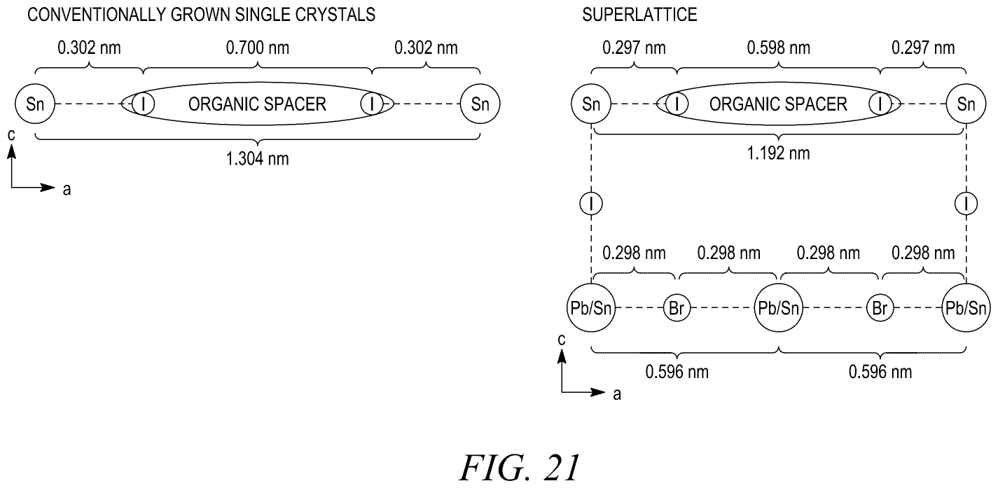

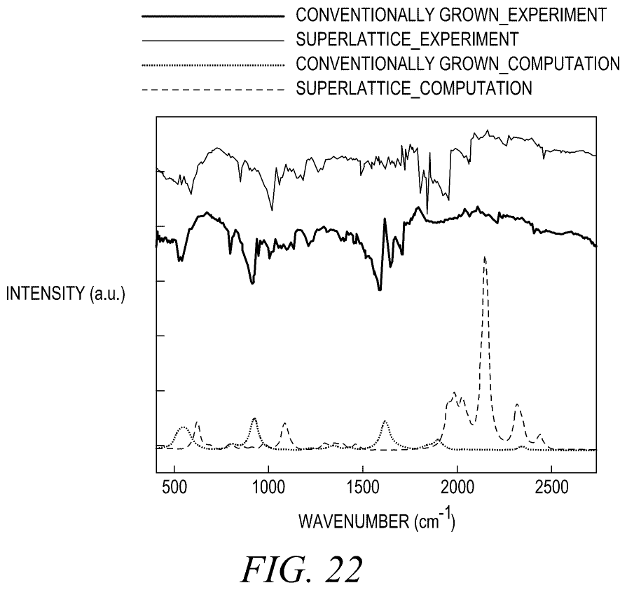

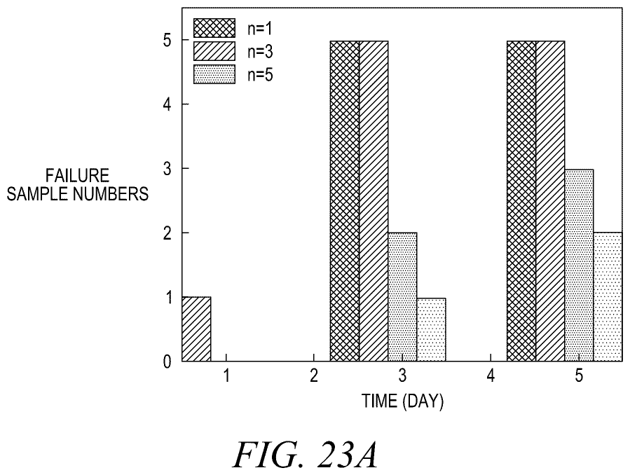

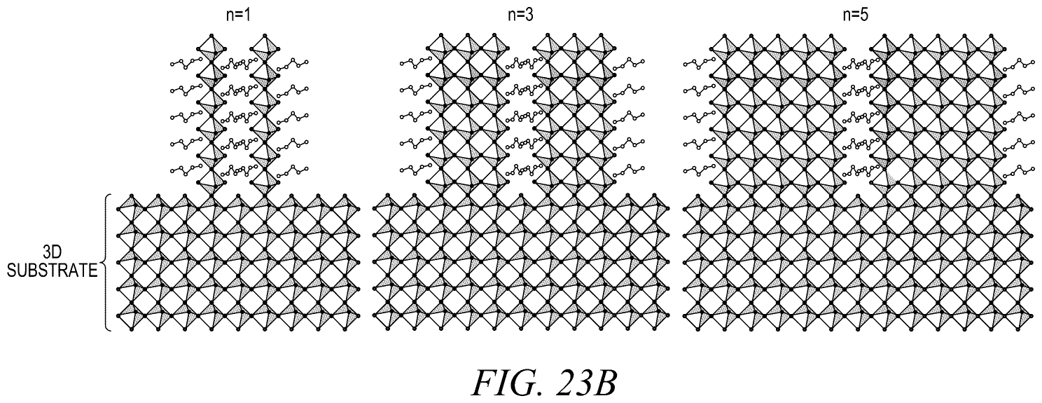

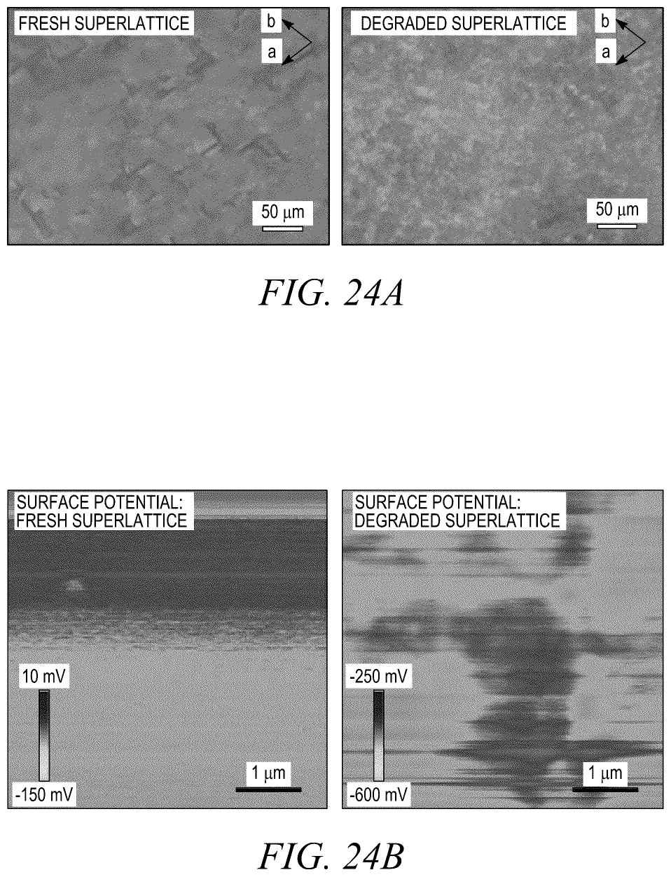

We investigated the heteroepitaxial strain in the BA₂SnI₄ superlattice quantitatively by X-ray diffraction. Compared to conventionally grown single crystals, high overall compressive strains are present in the superlattice along the a and b directions, at ˜8.59% and ˜1.32%, respectively (FIG. 3a, top); a tensile strain of ˜0.99% is present in the c direction due to Poisson effect (see FIG. 3a, bottom, the section below concerning lattice strain and Table 1). These strains are validated by calculations using the lattice constants extracted from the scanning transmission electron microscope images (see FIG. 11 and the section below concerning lattice strain). Structural computation by density-functional theory (DFT) further reveals that the lattice constant of Sn—I slabs in the a direction is compressed from ˜6.04 Å to ˜5.94 Å (FIG. 21), yielding a ˜1.66% strain, which is close to the 1.32% strain in the b direction; the width of the organic spacer is compressed from ˜7.00 Å to ˜5.98 Å (FIGS. 21 and 22), corresponding to a 14.6% strain. Therefore, the high compressive strain is mostly accommodated by the organic spacer. High strain reduces the stability of the superlattice (FIGS. 23 and 24). For general heteroepitaxial BA₂MAₙ₋₁SₙI₃ₙ₊₁, as n increases, the volume ratio of the Sn—I slabs increases, and the overall lattice strain decreases (FIG. 3b), and the structure is more stable. Moreover, lower strain results in less structural defects and smoother surfaces (FIG. 3b, inset images).

To avoid potential phase change and achieve reliable measurements of the superlattice, we chose BA₂MA₂Sn₃I₁₀ (n=3) to study their strain-controlled optoelectronic properties, and found that the high compressive strain in the a-b plane alters the quantum effects of the superlattice. We used ellipsometry to study the dielectric functions (ε′+iε″) of the superlattice and a conventionally grown single crystal. The higher ε′ of the superlattice indicates weakened quantum confinement by the compressed organic spacers (FIG. 3c), a larger Bohr radius in the multiple-quantum-well, and therefore a higher rate of free carrier generation (see the section below concerning the dielectric confinement). Besides, the shift in ε″, which reflects the absorption wavelength, suggests a smaller bandgap in the superlattice compared with the conventionally grown single crystal, which is also evident by the longer-wavelength collection edge of the superlattice (FIG. 2f; FIG. 25). Temperature-dependent photoluminescence measurements also show a much-reduced fitted exciton binding energy in the superlattice compared to the conventionally grown single crystal (FIG. 3d). In addition, the carrier lifetime in the superlattice is slightly longer than the conventionally grown single crystal at 0° in the transient photovoltage measurements (FIG. 1d). All these characteristics can be attributed to the weakened quantum confinement in the superlattice.

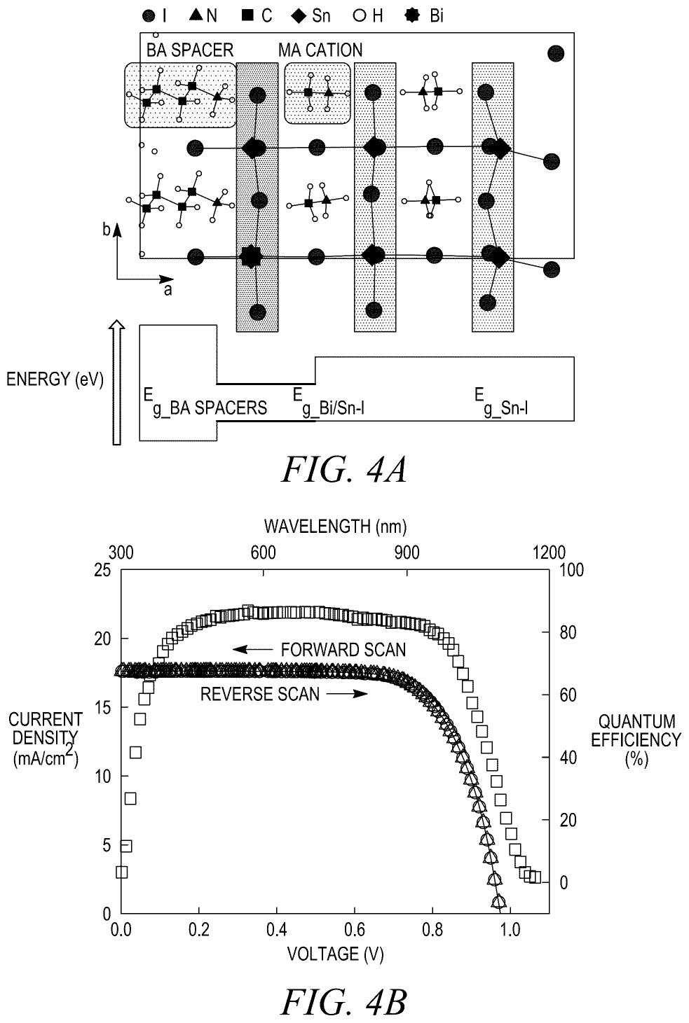

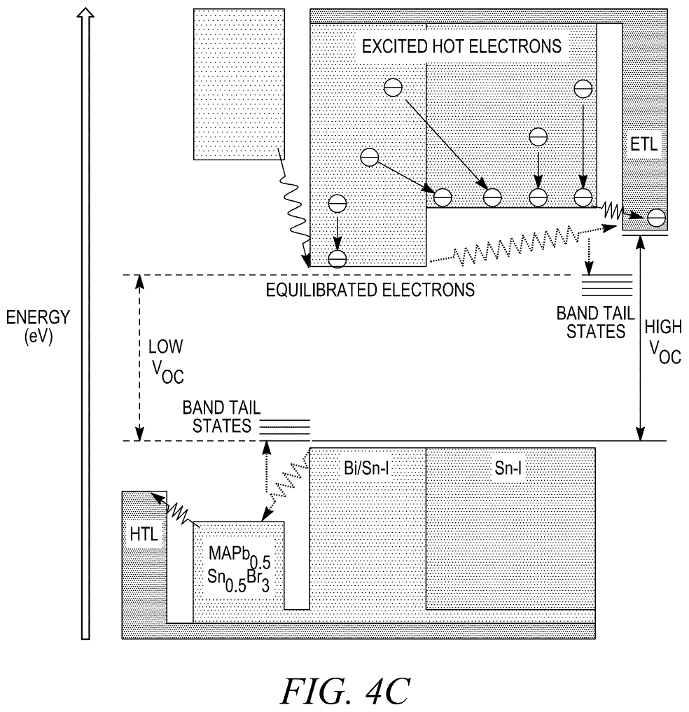

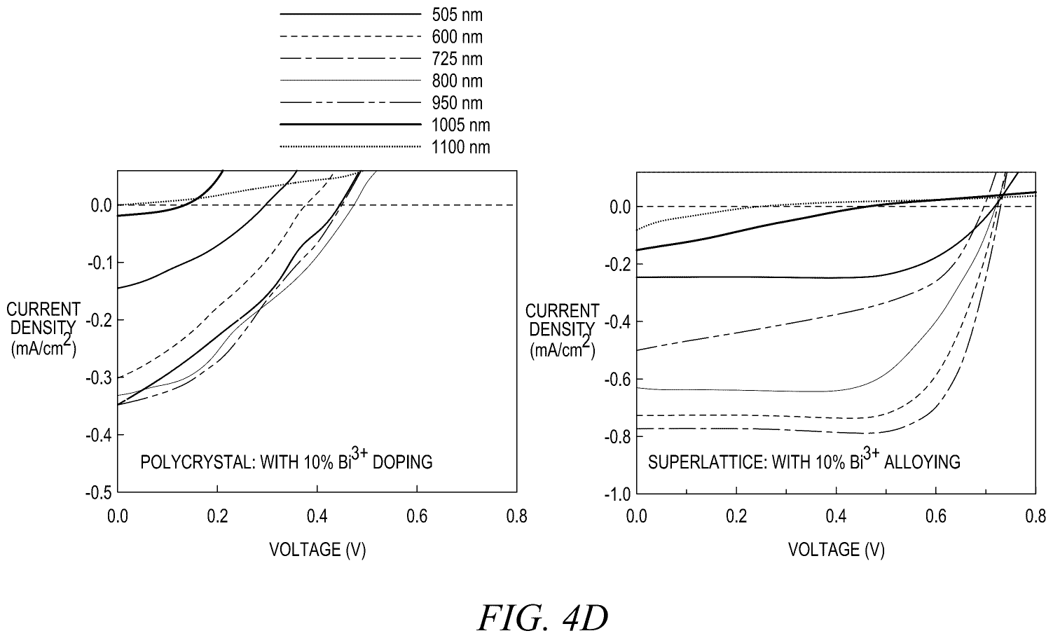

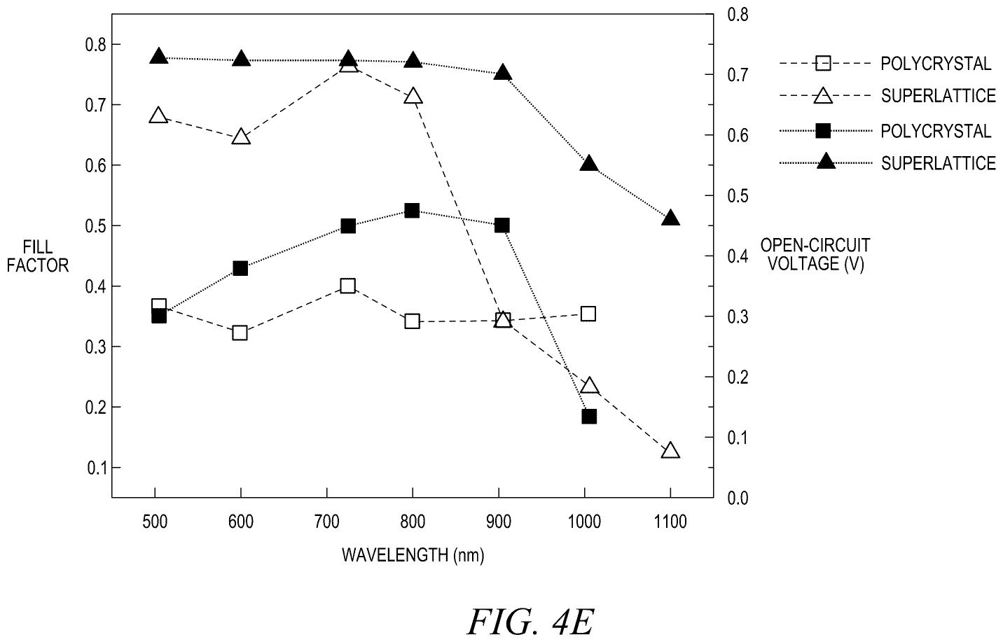

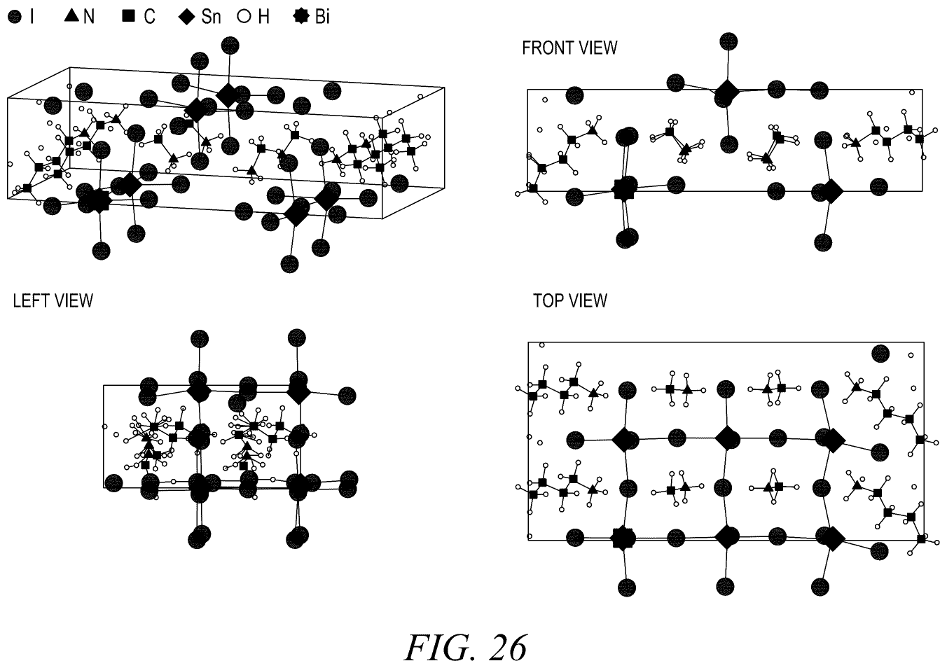

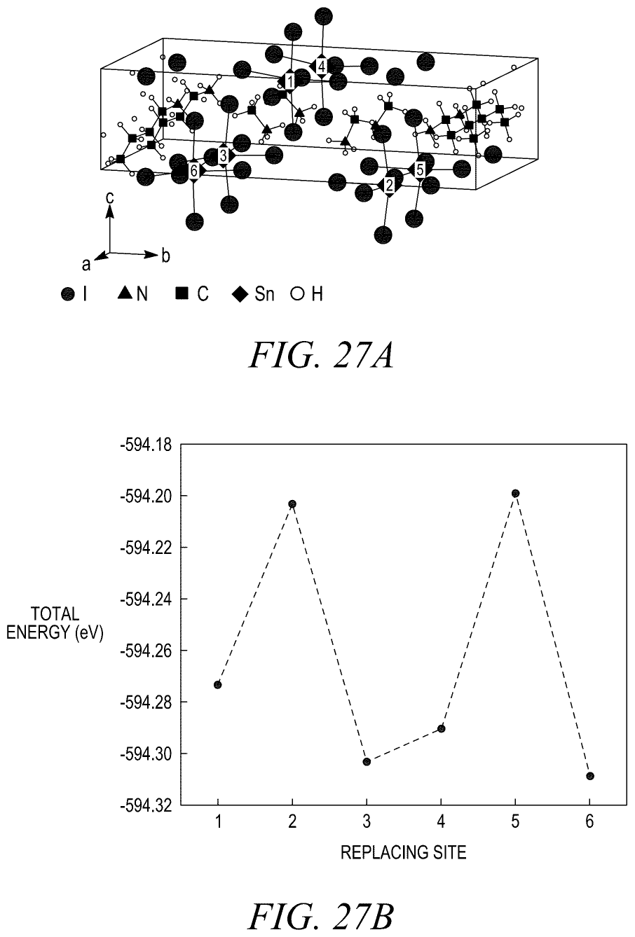

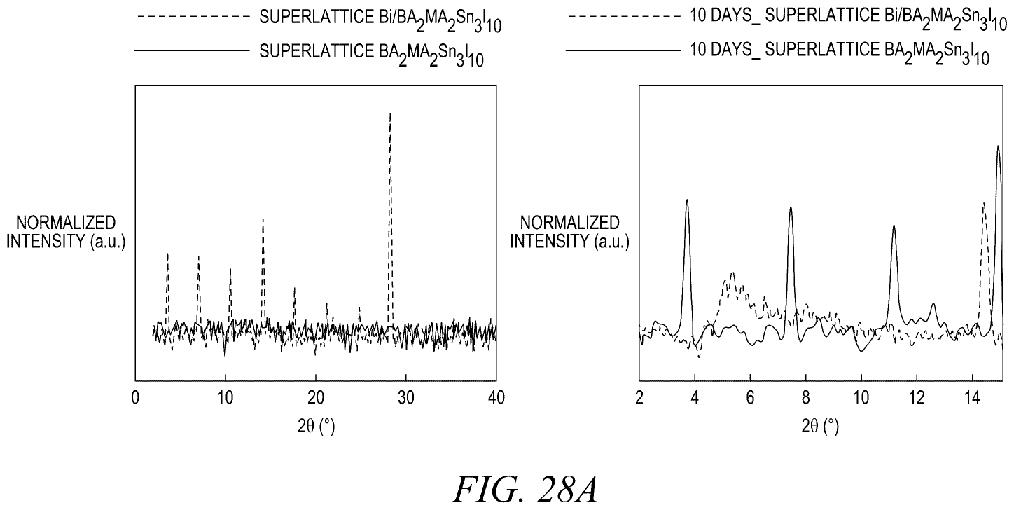

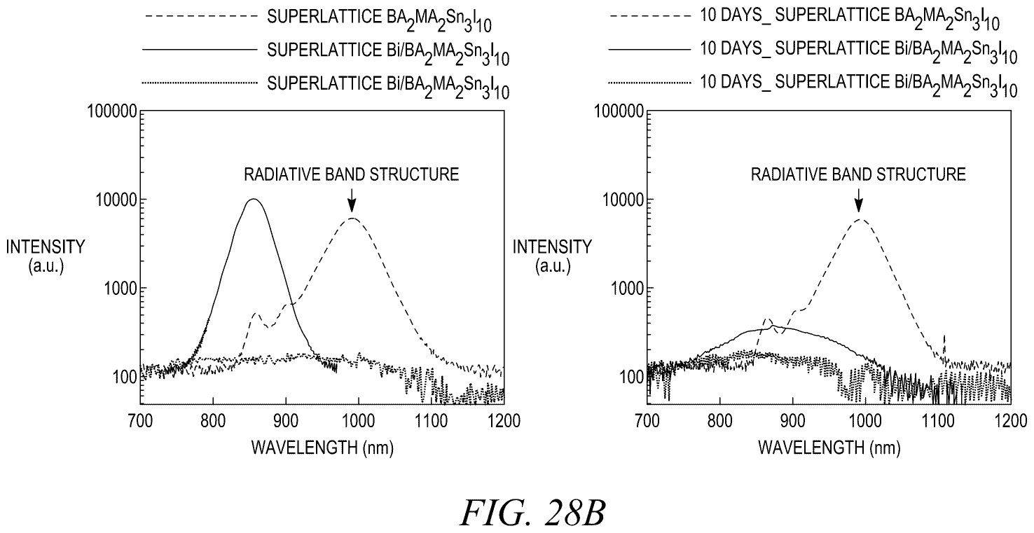

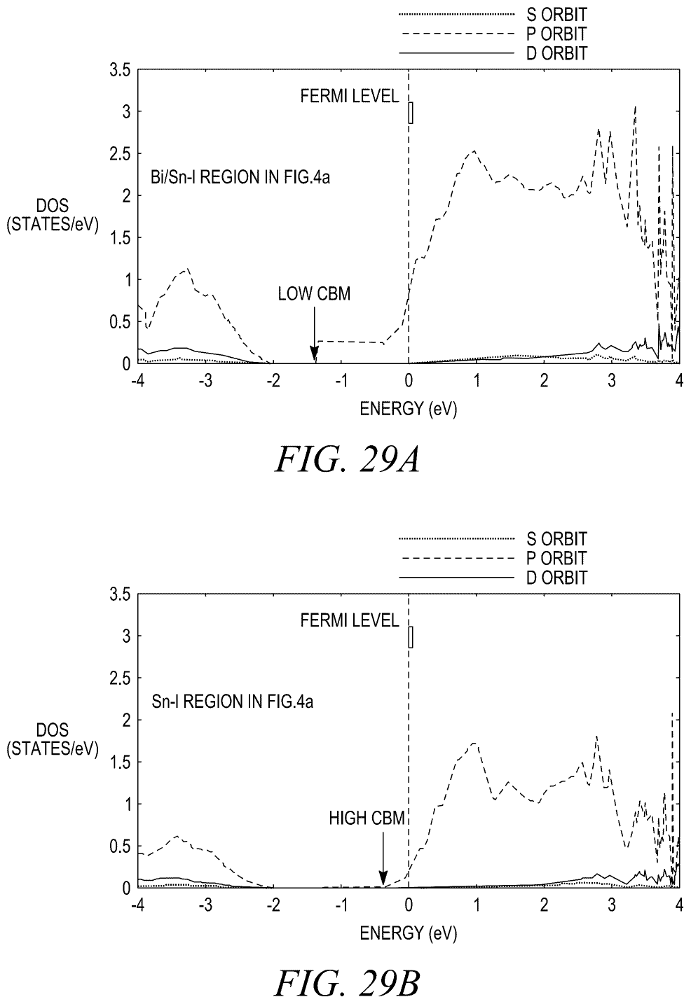

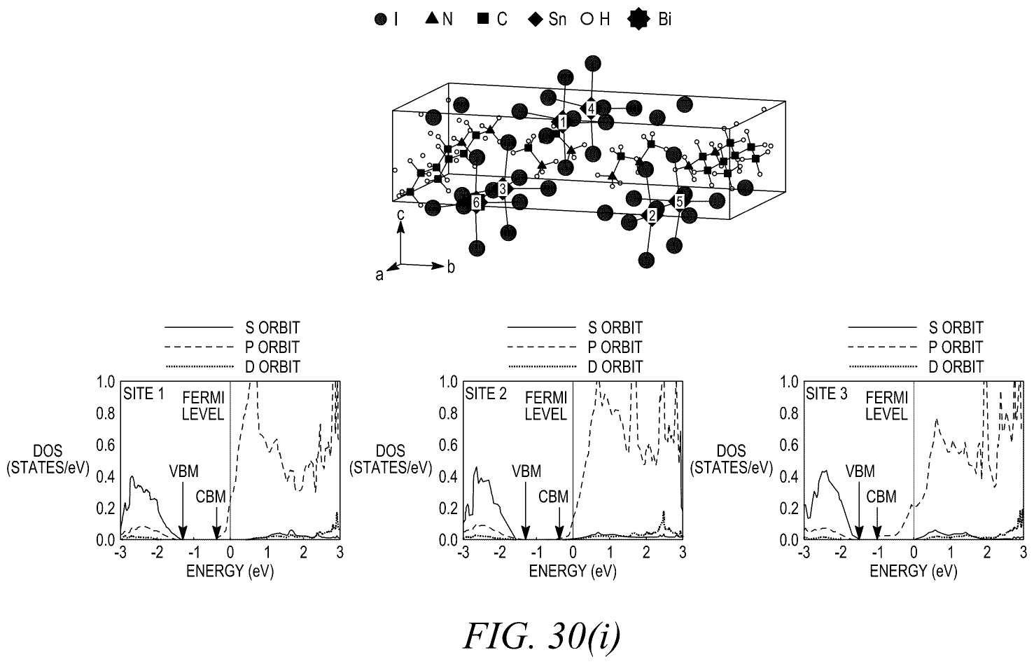

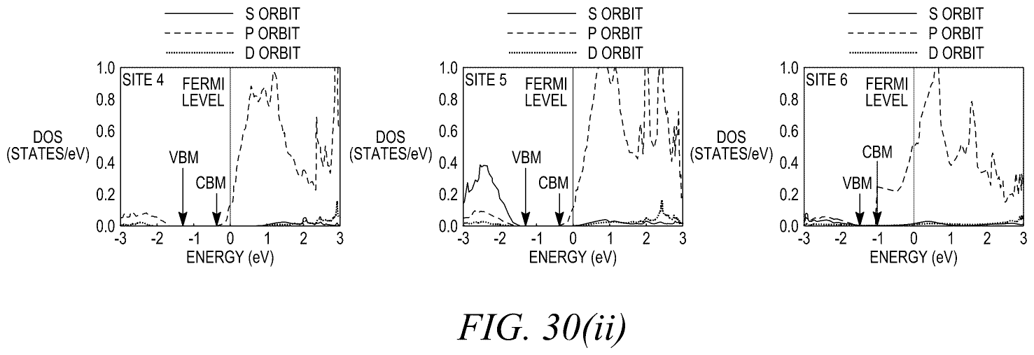

The enhanced carrier dynamics of the superlattice suggest potential improvements in photovoltaic performance Because the large heteroepitaxial strain heavily influences the stability of superlattices, the larger n-value component with a smaller lattice strain indicates a more stable device structure (see the section below concerning lattice strain and FIG. 3b, FIGS. 23 and 24). Therefore, BA₂MA₄Sn₅I₁₆ (n=5) is adopted to investigate the device performance due to its better stability and practicability. To further relieve the compressive strain and create an even more stable structure, we investigated using Bi³⁺ (103 μm in radius) to partially replace Sn²⁺ (118 μm in radius). DFT calculations show that the Bi³⁺ tends to aggregate at the interface between the inorganic slab and the organic spacer to relieve the compressive strain (FIG. 4a, top; FIG. 26), forming a Bi³⁺ rich atomic layer (see FIG. 27 and the section below concerning Bi³⁺ alloying). This effectively decreases the formation energy of the superlattice and yields a much more stable structure (FIG. 28). Furthermore, Bi³⁺ alloying alters the local electronic structure of the superlattice, which substantially decreases the conduction band minimum (CBM) (FIG. 4a, bottom; FIGS. 29 and 30). The region without Bi³⁺ alloying remains intact. The result is an inorganic slab with a double-band structure.

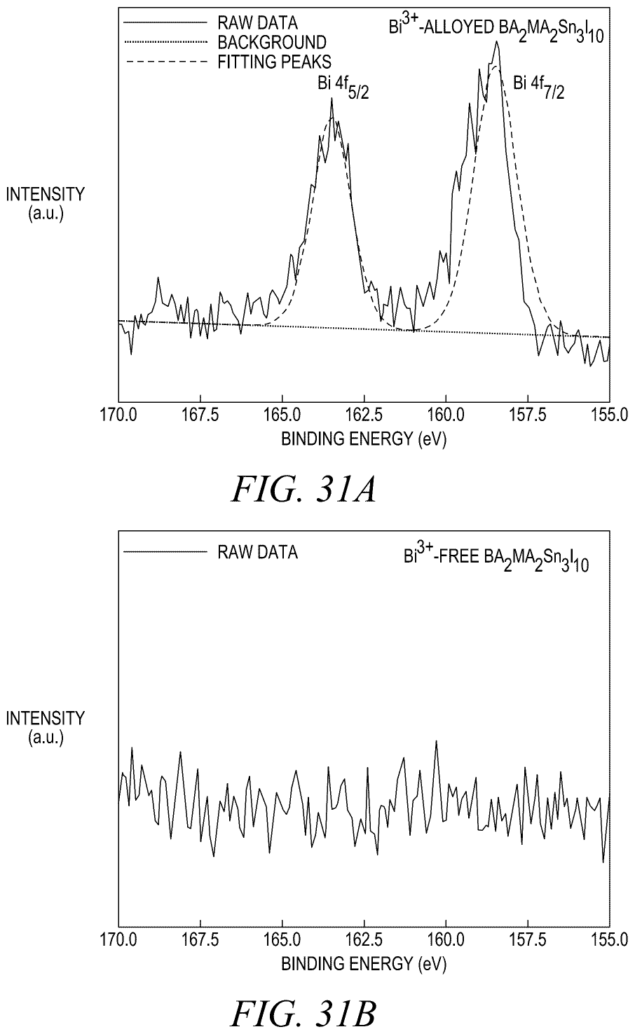

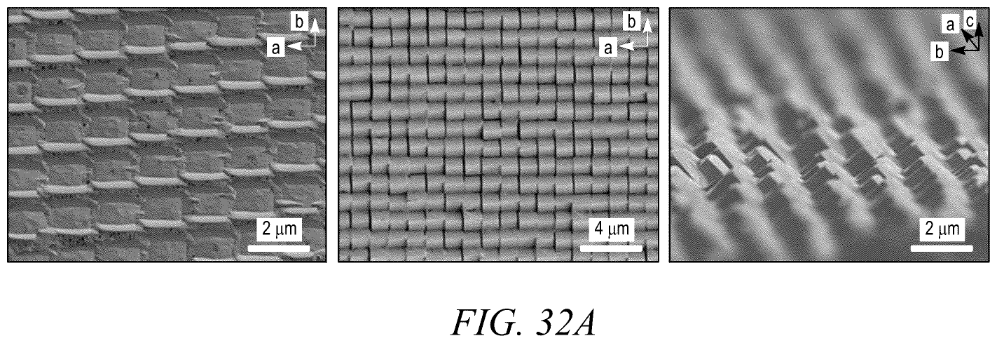

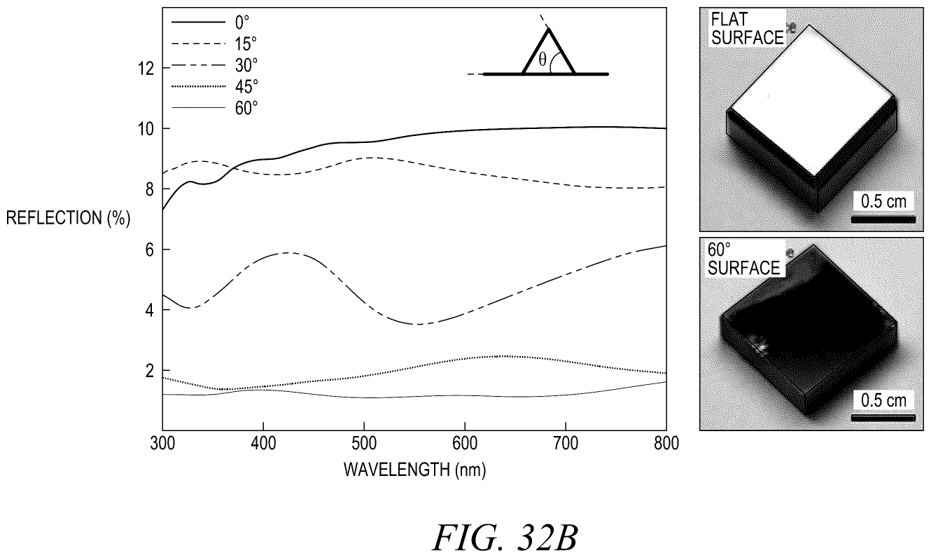

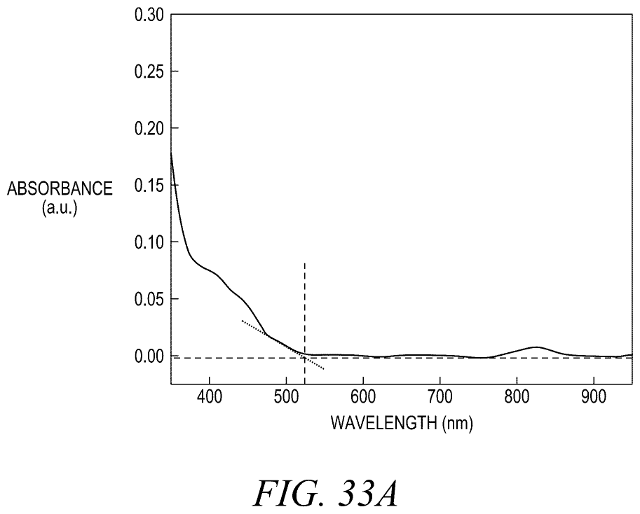

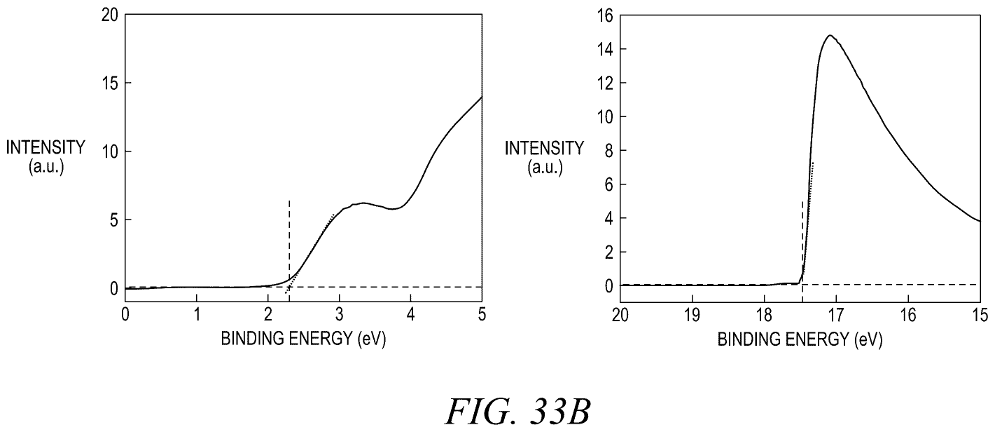

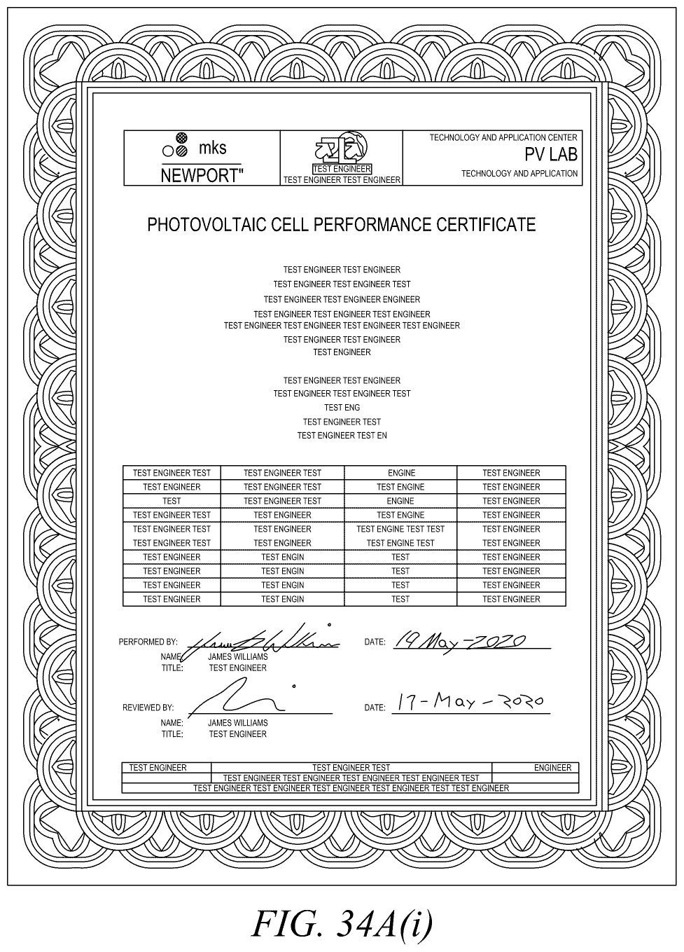

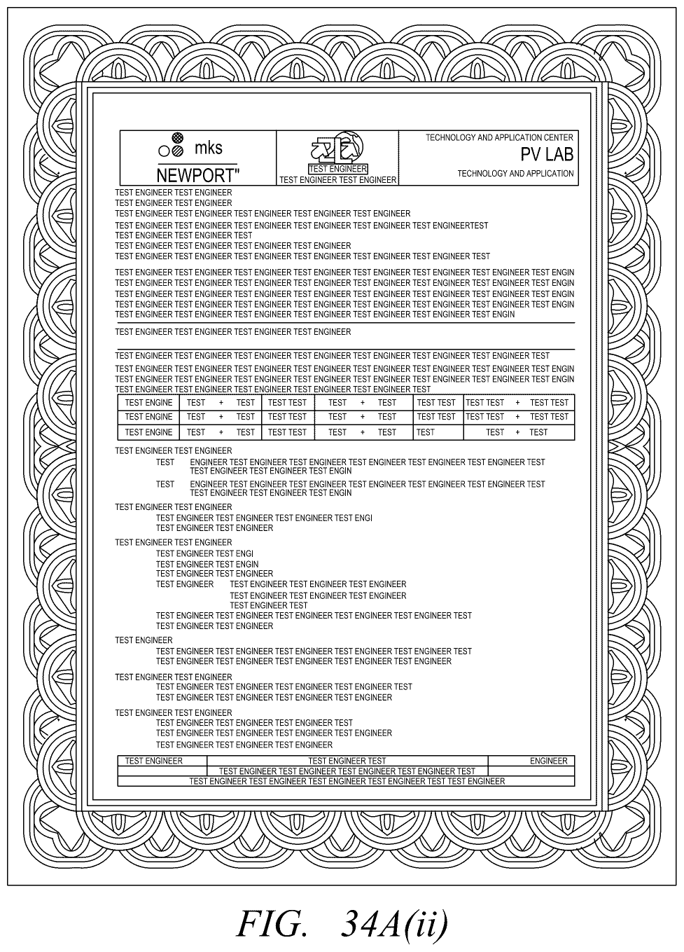

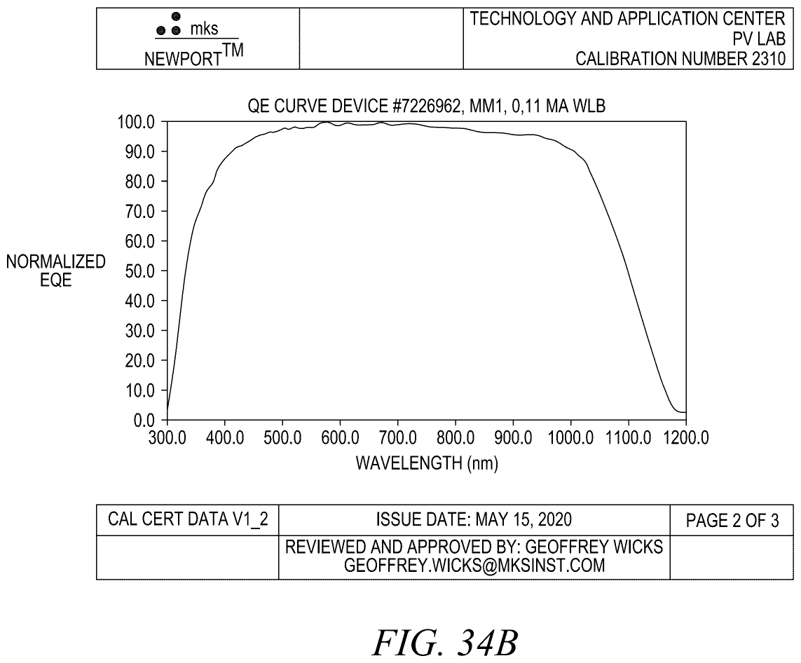

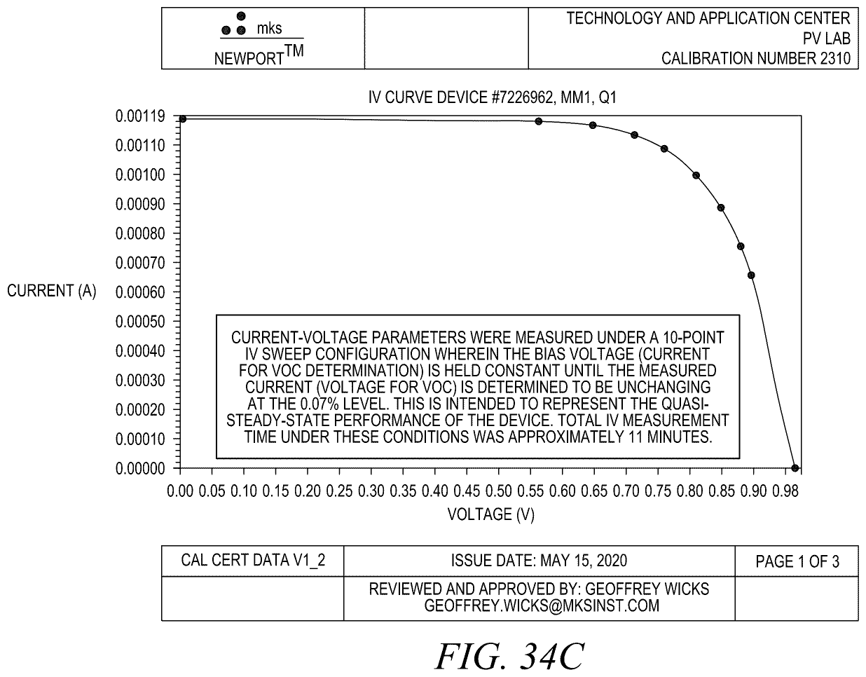

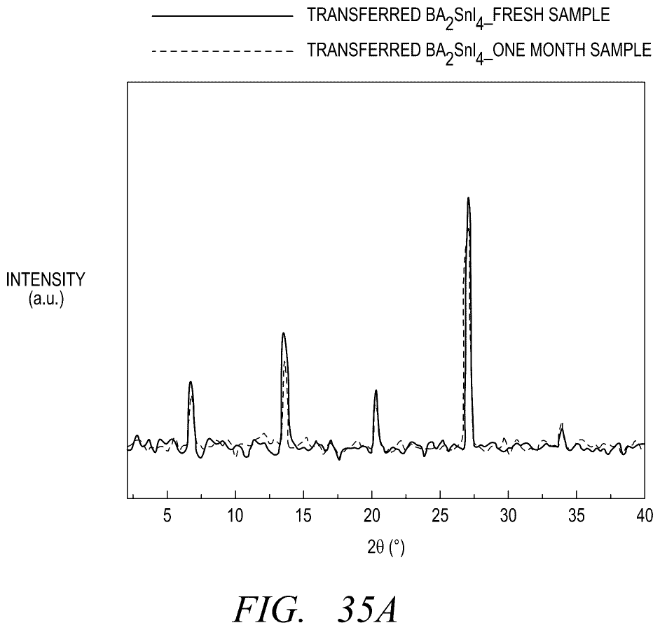

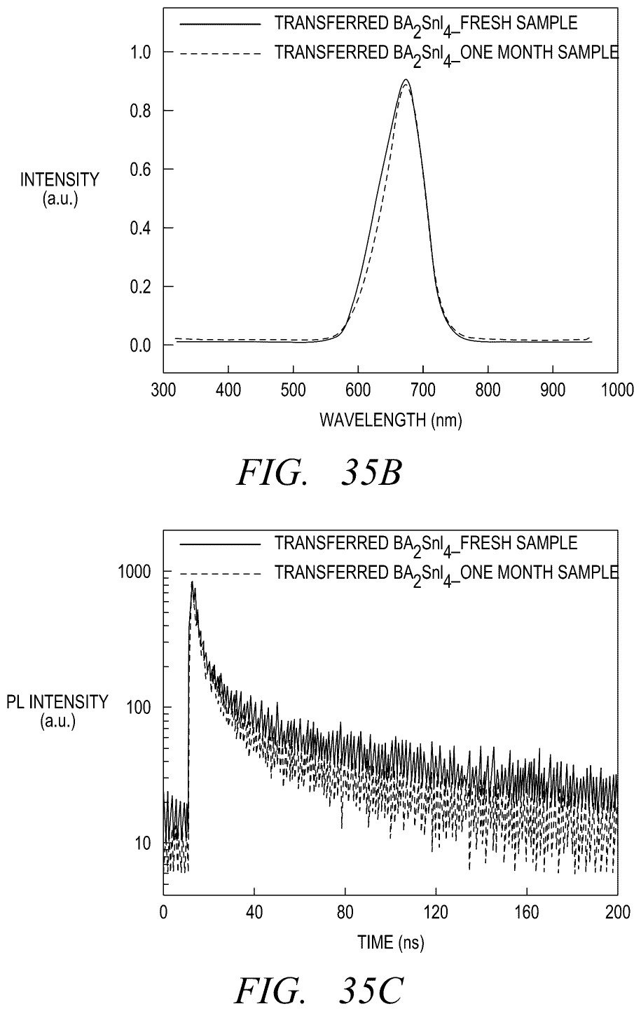

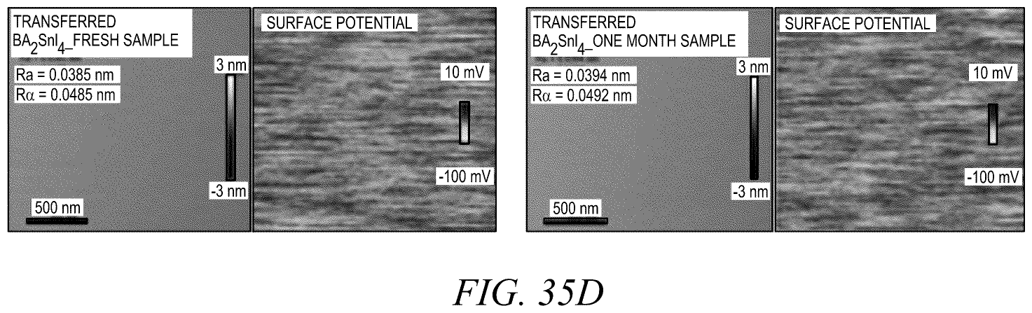

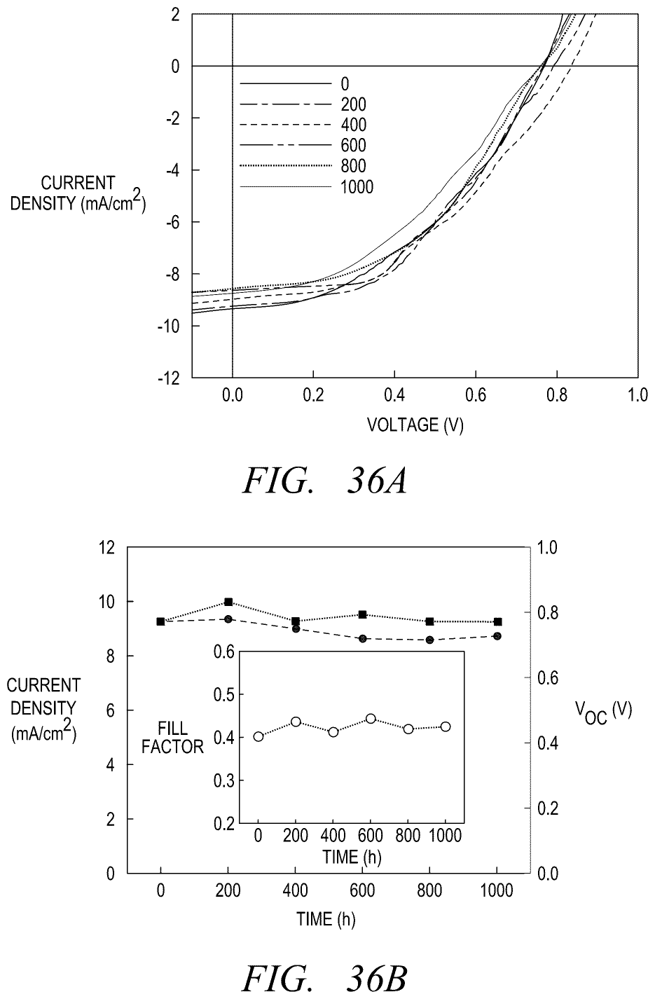

We grew 10% Bi³⁺-alloyed BA₂MA₄Sn₅I₁₆ (n=5) superlattices with a textured surface and fabricated solar cells directly on the substrate (FIGS. 31 and 32). We chose BA₂MA₄Sn₅I₁₆ due to its relatively weak quantum confinement, stable structure, and small bandgap. Additionally, since the Bi³⁺-alloying could slightly hinder the carrier dynamics and alters the electrical structure of superlattices, the Bi³⁺-alloying here only serves to enhance the structure stability for device characterizations and demonstrations but not to reflect the intrinsic carrier properties, which has been discussed above with the Bi³⁺-free structure. Indene-C60 bisadduct was used as the electron transport layer (ETL) because its CBM level (FIG. 33) is higher than that of the Bi/Sn—I but lower than the Sn—I slabs (Table 2). Because Bi³⁺ ions are distributed along the vertical slab direction, the Bi/Sn—I and the Sn—I regions are both in contact with the ETL. It is the first low-dimensional metal halide perovskite based solar cell to pass the quasi-steady state test (FIG. 34). It exhibits a certified stable 12.36% photoelectric conversion efficiency—the highest in lead-free low-dimensional perovskite solar cells. It is worth pointing out that even the certified in-situ superlattice solar cell was integrated with a bulk MAPb_{0.5}Sn_{0.5}Br₃ substrate, it only served as the template to support the growth of the superlattice and was not a functional component in the fabricated solar cell. Besides, it is also practical to use other substrates (e.g., Cs₂AgSbCl₆ in FIG. 8 and BaF₂ in FIG. 10) to replace the lead-containing substrates. Additionally, transfer strategies could further be adopted to exfoliate the superlattice from the substrate onto a general substrate (FIGS. 35 and 36) to fabricate lead-free devices. Moreover, the certified quantum efficiency plot of the solar cell (FIG. 4b; FIG. 34) shows a carrier collection cutoff at ˜1190 nm, which gives a bandgap of ˜1.042 eV and a V_{OC} of at most 0.802 V according to Shockley-Queisser-limit. However, the certified V_{OC} is 0.967 V, which is much higher than what detailed balance would allow.

FIG. 4c shows the schematic band diagram of the solar cell. Because Bi³⁺ alloying in single-crystal perovskites will not lead to a high density of traps or band tail states, nor does it cause macroscale phase-separation between Bi³⁺ and Sn²⁺ regions (FIG. 28), the high V_{OC} is not attributed to any defect levels in the bandgap of the superlattice. The carrier collection cutoff of the solar cell is determined by the component of the lowest bandgap, i.e., 1.042 eV of the Bi/Sn—I region in this case. However, this low bandgap region does not seem to affect the overall V_{OC} of the final device.

We performed wavelength-dependent J-V measurements of the solar cell to investigate the carrier transport process (FIGS. 4d-4e). Under short incident wavelengths (<˜1000 nm), most electrons are excited into energy states higher than the CBM of both Sn—I and Bi/Sn—I regions. Those electrons from the Sn—I region naturally relax to the CBM of the Sn—I region. Additionally, a substantial portion of the electrons from the Bi/Sn—I region can also diffuse to the CBM of the Sn—I region through intra-band relaxation (solid arrows in FIG. 4c). This intra-band transition is possible because the atomic-thin Bi/Sn—I region is easy for carriers to diffuse across. Also, the built-in potential in the p-i-n solar cell structure might facilitate the atomic-scale relaxation of hot electrons from Bi/Sn—I regions to Sn—I regions, which is different from the situations with only perovskite material (e.g., during the PL measurement); moreover, the ETL layer favors electron collection from the Sn—I region (solid arrow in FIG. 4c). Therefore, most of carriers are in the Sn—I region, yielding a high V_{OC} and a high EE (FIGS. 4d and 4e). Under long incident wavelengths (>˜1000 nm), electrons can only be excited in the Bi/Sn—I region. The relatively low-energy electrons cannot transit to the Sn—I region; they can only relax to the CBM of the Bi/Sn—I region, and then to the ETL via inter-band transition (dashed arrows in FIG. 4c). Therefore, most of carriers are in the Bi/Sn—I region, yielding a low V_{OC} (FIGS. 4d and 4e). The energy barrier between the Bi/Sn—I region and the ETL can cause serious charge accumulation and recombination (see the section below concerning intra-band exciton relaxation), which results in inefficient carrier transport and a low EE (FIGS. 4d and 4e). When the device is excited under mixed incident wavelengths, the high-energy electrons excited in both Bi/Sn—I and Sn—I regions by the short wavelengths facilitate the quasi-fermi-level splitting in the Sn—I region. The low-energy electrons excited by the long wavelengths will have a relatively small influence on the overall V_{OC}, because the long-wavelength portion (between ˜1000 nm and ˜1200 nm) of the solar radiation spectrum is small (˜9%), so the quantity of the low-energy electrons is low. Therefore, the overall outcome is an unusually high V_{OC} that is predominantly determined by the bandgap of the Sn—I region (see FIG. 37 and the section below concerning intra-band exciton relaxation).

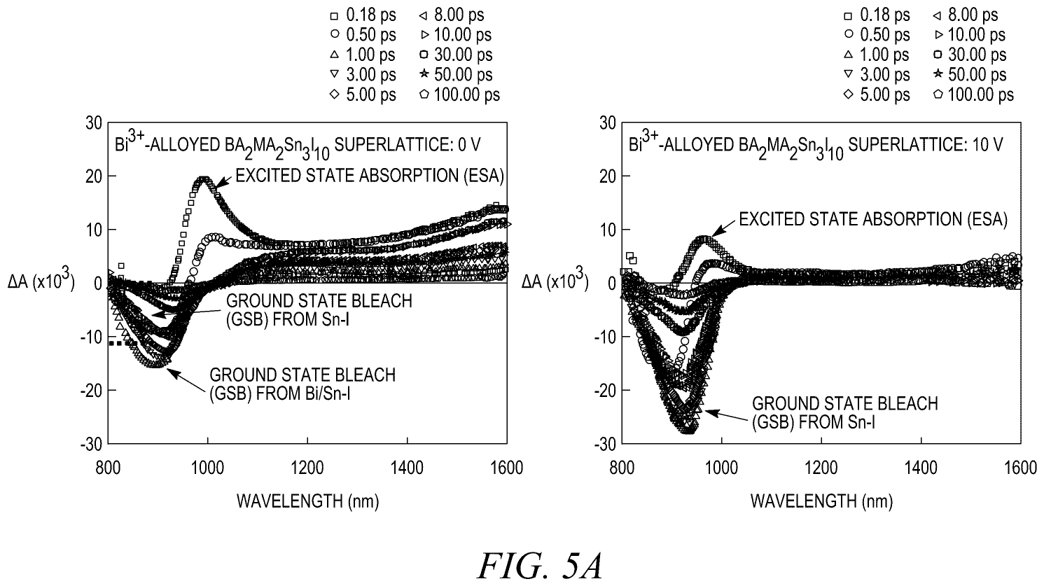

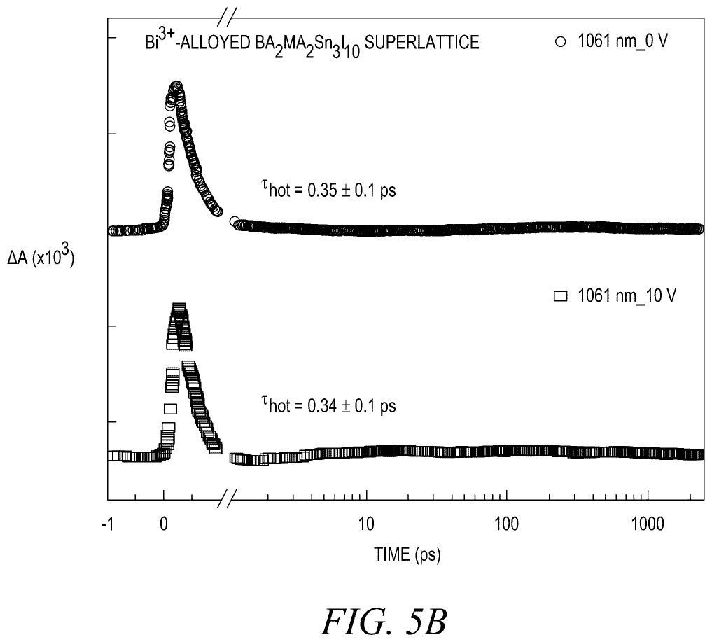

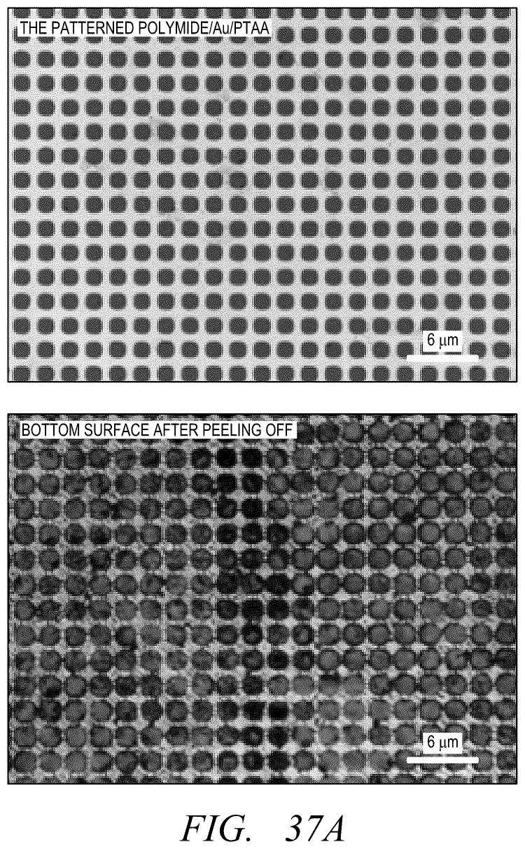

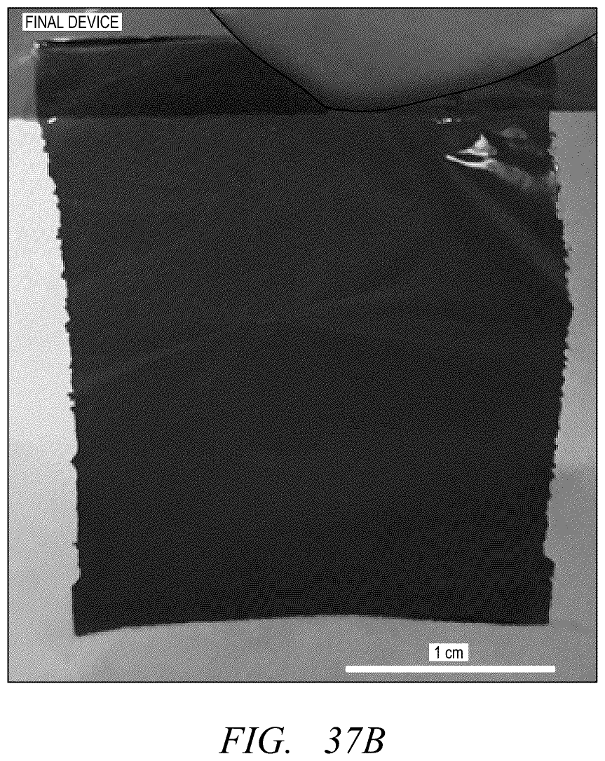

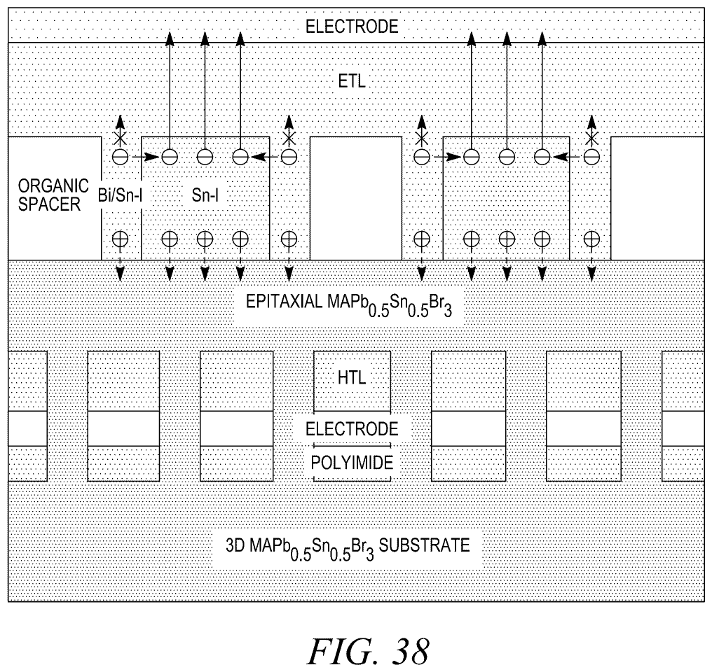

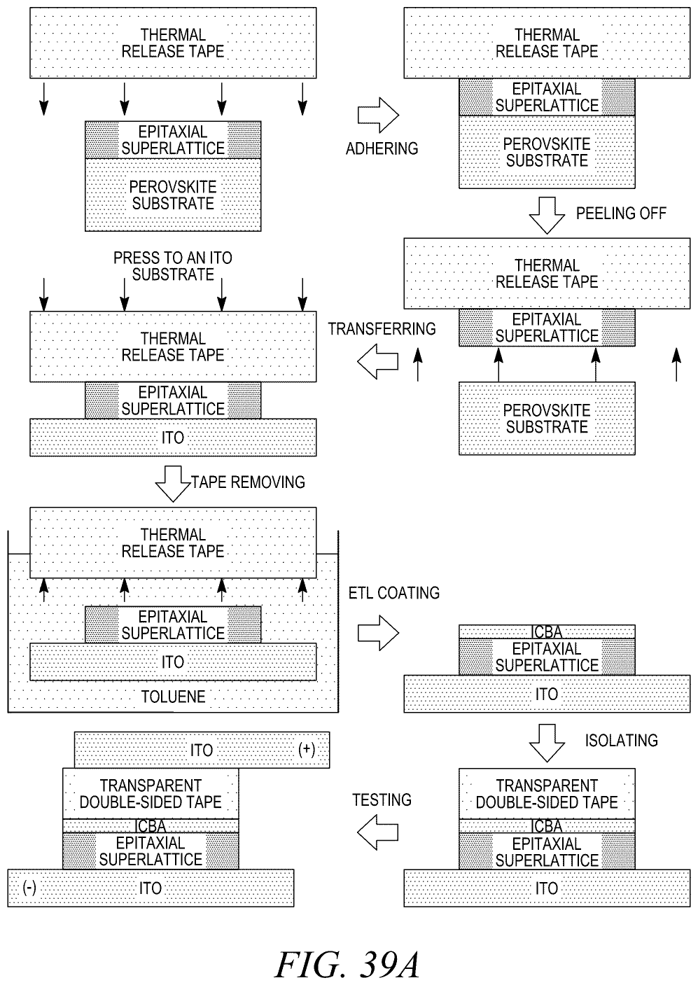

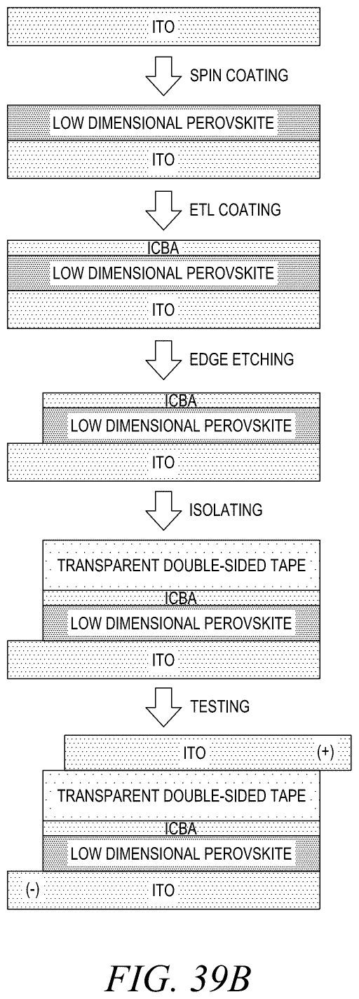

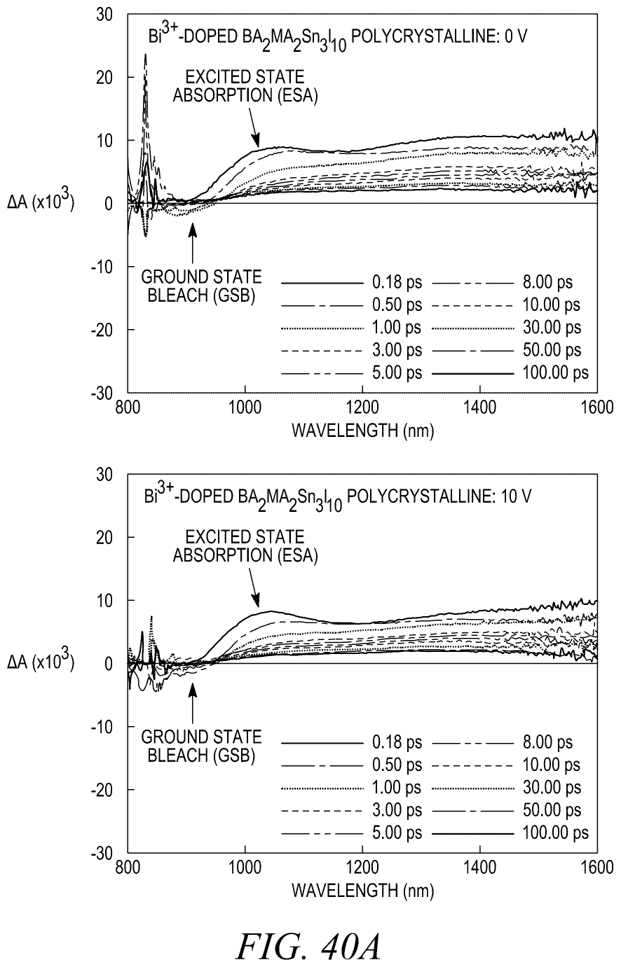

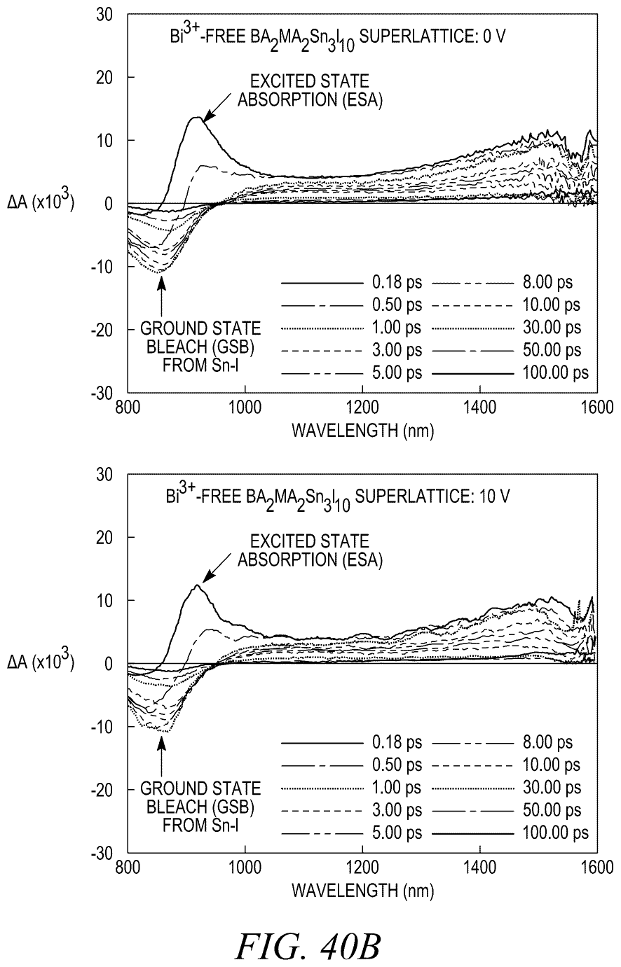

To gain more verifications on this mechanism, we performed pump-probe ultrafast transient absorption spectrum measurements on the superlattice devices to investigate their hot carrier dynamics (see the section below concerning pump-probe ultrafast transient absorption spectrum measurements). To meet the measurement requirement, a transferred device structure (ITO/superlattice/ICBA/polypropylene tape/ITO) (FIG. 38) was adopted under an external electrical field to mimic the built-in potential of the solar cell. The measured transient absorption spectra with and without the bias are shown in FIG. 5a and FIG. 39 for Bi³⁺-alloyed superlattices, Bi³⁺-doped polycrystalline thin films, and Bi³⁺-free superlattices. The measurement mechanisms are shown in FIG. 40. The polycrystalline thin films (FIG. 39a) exhibit very different spectral profiles from superlattices (FIG. 5a and FIG. 39b). Obvious ground state bleaching (GSB) (the depletion of the ground state electrons to excited states) signals in the negative intensity region could be observed in superlattices, indicating more efficient carrier dynamics in the superlattices than those in the polycrystalline thin film.

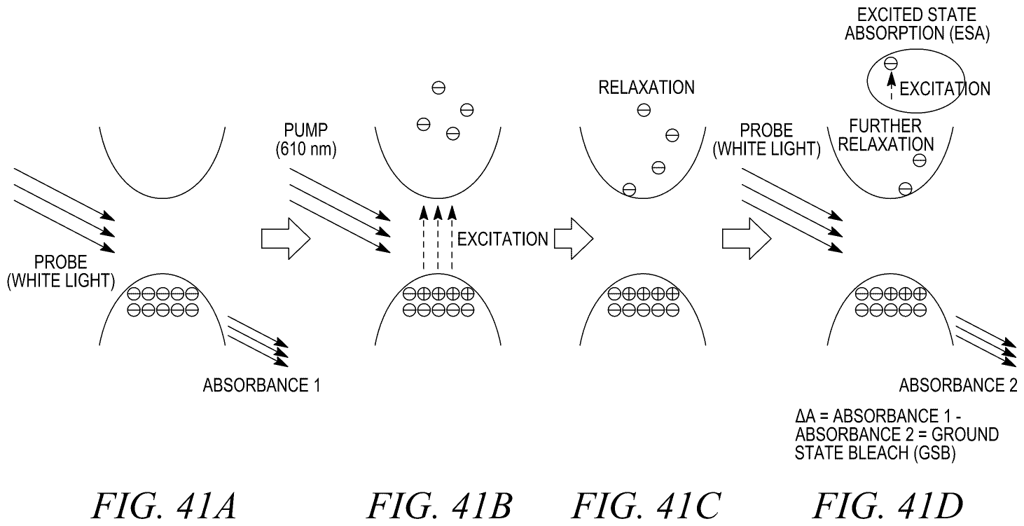

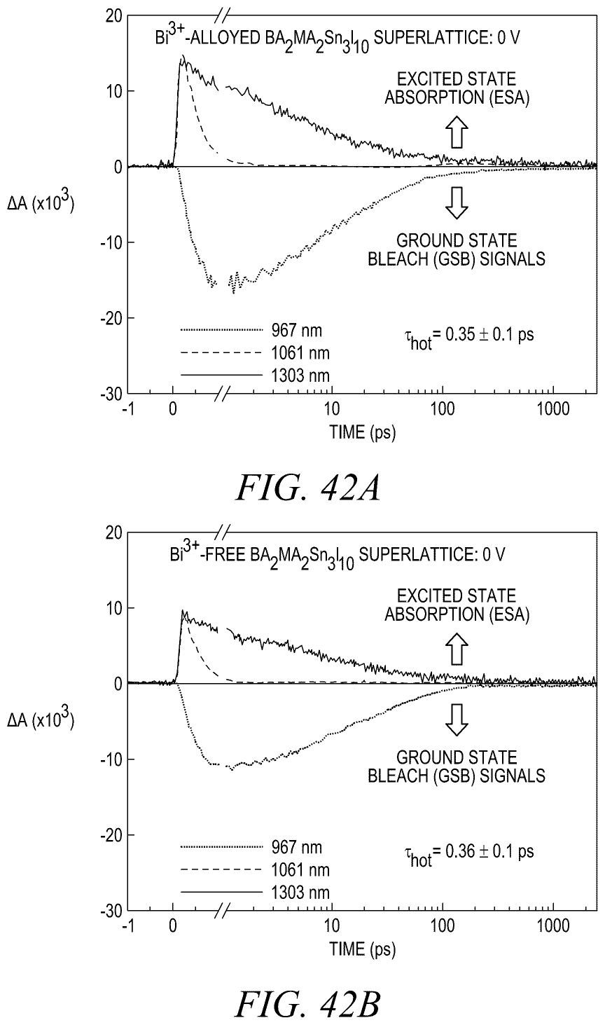

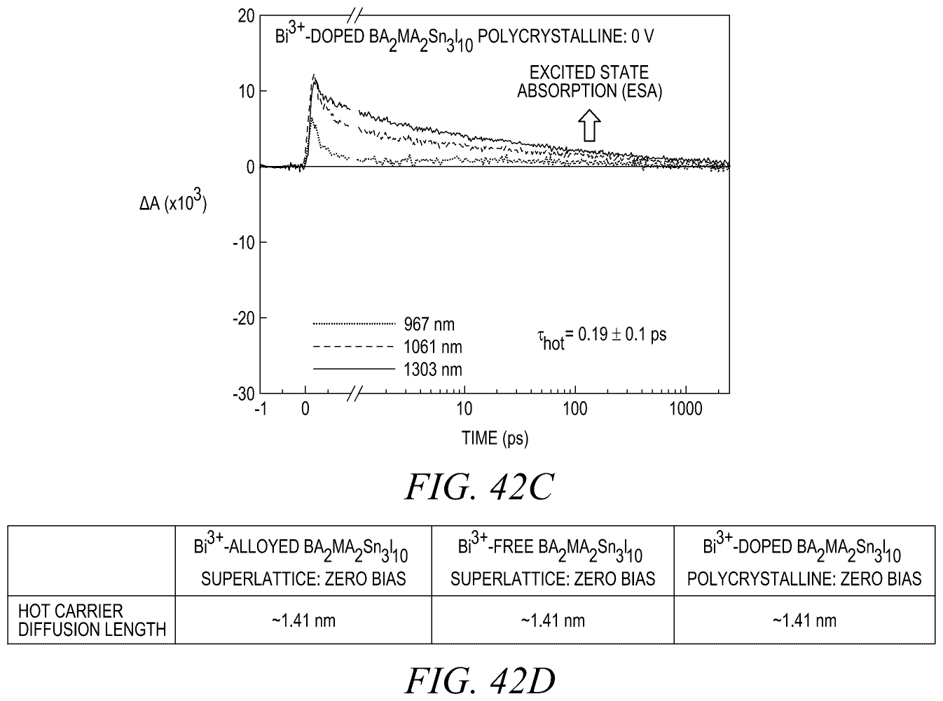

The lifetime of hot electrons in those three samples could be fitted by extracting their relaxation time profiles at selected wavelengths (FIG. 5b and FIG. 40). The hot electron lifetimes of superlattices (Bi³⁺-alloyed and Bi³⁺-free) are 0.35 ps˜0.36 ps, which are almost twice that of polycrystalline thin films (˜0.19 ps) (FIG. 41a). Accordingly, the calculated hot electron diffusion lengths in superlattices are near ˜3.86 nm, which is more than six times longer than the width of the Bi/Sn—I regions (˜0.6 nm) (FIG. 41b), suggesting that the hot electron can readily travel across the Bi/Sn—I regions to the Sn—I regions. Additionally, transient absorption spectrums show an obviously enhanced GSB signal intensity in superlattices when the applied bias increases from 0 V to 10 V (FIG. 5a). In contrast, the excited state absorption (ESA) signal, which is the absorption of a photon from a lower excited state to a higher excited state of an atom, molecule or ion, decreases (FIG. 5a). However, none of such phenomenon could not be observed in Bi³⁺-free superlattices and Bi³⁺-doped polycrystalline thin films (FIG. 39), indicating unique carrier mechanisms in Bi-alloyed superlattices: the increased GSB signal intensity in Bi-alloyed superlattices indicates a reduced number of electrons at the ground-state in the valence band. Because the excitation setup for 0 V and 10 V measurements are the same, the reduced electrons at the ground-state in the valence band is not from a stronger excitation. Therefore, it suggests that the number of electrons relaxing from the conduction band to the valence band after excitation is reduced. However, because the hot carrier lifetime in the device is not influenced by the applied electrical field (FIG. 5b, FIGS. 41 and 42), it is likely that those “reduced” electrons can only transport to Sn—I regions but not ITO or ICBA layer because of the applied direction of the electrical field (for ITO) and the strong interfacial barriers (for ICBA; e.g., in the Bi-doped polycrystalline thin-film, the GSB signals do not increase obviously, suggesting that the 10 V electrical field is not sufficient to drive electrons at the CBM in Bi/Sn—I regions to overcome the interfacial barrier to the ICBA) (see the section below concerning pump-probe ultrafast transient absorption spectrum measurements).

The decreased ESA signal intensities further confirm the explanation. Because the changes in ESA signal intensities reflect the excited electron population that is excited further, the decreased ESA signal intensity is due to a reduced number of hot electrons in the valence band. However, because of the same excitation setup and similar hot electron lifetimes for 0 V and 10 V measurements (FIG. 5b, FIGS. 41 and 42), the obviously reduced hot electron population is not from a weaker excitation or more rapid relaxation but from additional relaxation routes. Because the ESA signals only refer to hot electrons in excited-states with short lifetime, it is impossible for them to transport for long-distance. Therefore, it is likely that they can only relax to Sn—I regions due to the atomic-scale diffusion distance. The only two other layers contacting with Bi/Sn—I regions are ITO and ICBA, which have relatively long diffusion distances (see the section below concerning pump-probe ultrafast transient absorption spectrum measurements)

Besides the unique intra-band relaxation mechanism discussed here, other carrier transport processes may also be possible to contribute to the unusual high V_{OC}, such as superposition principles, multiple exciton generation in atomic-scale structures, and ion diffusions, etc. Further device performance improvements are possible with optimizations of the design of the electrode patterns, the resistivity of the top electrode, and the band alignment of the ETL/hole transport layer. Additionally, even though all superlattices in this work do not exhibit good long-time stabilities, they are all based on in-situ structures, where the large heteroepitaxial strains determine their rapid degradations. However, by transferring the superlattices to fully release the lattice strain, the intrinsic stability of superlattices is found to be promising (FIGS. 35 and 36). The low-dimensional perovskites are intrinsically flexible without any additional mechanical packaging because of the low bending stiffness of the inorganic slabs (FIG. 42). Therefore, these materials can be promising candidates for large-area flexible solar cells as power sources for flexible devices that can be integrated with non-planar surfaces. The strategy demonstrated here can be applied to general low-dimensional perovskites, which may pave the way for exploring solution-based superlattice optoelectronics with high efficiencies.

### Device Fabrication and Characterization Methods

The following techniques were employed to fabricate and characterize some embodiments of the perovskite supperlattices described herein.

Materials: The materials used in this study were as-purchased without further purification, which included lead iodide (PbI₂, 99.99%, Tokyo Chemical Industry), lead bromide (PbBr₂ (98%, Alfa Aesar), hydrobromic acid (HBr, 48 wt % in water, Sigma Aldrich), methylamine (CH₃NH₂, 40% in methanol, Tokyo Chemical Industry), tin (II) oxide (SnO, 97%, Sigma Aldrich), hydroiodic acid (HI, 57% in water, Sigma Aldrich), hypophosphorous acid (H₃PO₂, 50 wt % in water, Sigma Aldrich), methylammonium iodide (MAI, 99.9%, Greatcell Solar), n-butylammonium iodide (BAI, 99.9%, Greatcell Solar), cesium chloride (CsCl, 99.9%, Sigma Aldrich), silver chloride (AgCl, 99%, Sigma Aldrich), antimony (III) chloride (SbCl₃, 99%, Sigma Aldrich), bismuth (III) iodide (BiI₃, 99%, Sigma Aldrich), indene-C60 Bisadduct (ICBA, LT-S9030, Luminescence Technology), poly[bis(4-phenyl)(2,4,6-trimethylphenyl)amine] (PTAA, LT-N168, Luminescence Technology), chlorobenzene (C₆H₅Cl, TCI America), anhydrous dimethylformamide (DMF, C₃H₇NO, 99.8%, Sigma Aldrich), anhydrous gamma-butyrolactone (GBL, C₄H₆O₂, 99% Sigma Aldrich), anhydrous dimethyl sulfoxide (DMSO, C₂H₆OS, 99.9%, Sigma Aldrich), isopropanol (IPA, C₃H₈O, 99.5%, Sigma Aldrich), and methanol (99.8%, CH₃OH, Sigma Aldrich).

Preparation of single-crystal perovskite: MAPbBr₃: Flat and smooth centimeter-sized bulk MAPbBr₃ single crystals were prepared by solution-based growth. The MAPbBr₃ were used as the 3D perovskite substrate to grow the low-dimensional perovskite superlattice without any further treatment. MAPbI₃: MAPbI₃ single crystals were prepared by solution-based growth. The as-obtained crystals were ultrasonically cleaned in an anhydrous IPA solvent for 5 mins. Then, the crystals were crushed into powers for growth precursor preparation.

Synthesis of low-dimensional perovskites: 0.3 g SnO powder was dissolved into a mixture of 3 ml hydroiodic acid solution and 0.5 ml hypophosphorous acid solution in a glass vial by heating to 180° C. under constant stirring until a bright yellow precursor solution was obtained. BA₂SnI₄ crystals were synthesized by injecting 1 mL BAI solution (2.5 mmol BAI in 1 mL methanol) into the precursor solution. BA₂MA₂Sn₃I₁₀ crystals were synthesized by injecting 1 mL MAI/BAI solution (1.67 mmol MAI and 0.83 mmol BAI in 1 mL methanol) into the precursor solution. BA₂MA₄Sn₅I₁₆ crystals were synthesized by injecting 1 mL MAI/BAI solution (2 mmol MAI and 0.5 mmol BAI in 1 mL methanol) into the precursor solution. Then, the vial was transferred into a nitrogen-filled glove box at room temperature. The as-formed crystals were then isolated by removing the solution, then quickly washed using IPA for three times. Then, the crystals were dried and then directly dissolved in GBL to form the growth solution (0.5 M) for low-dimensional perovskites. For the Bi³⁺ alloyed superlattice, 10% molar ratio of BiI₃ was also dissolved into the growth solution.

Preparation of precursors for mixed perovskites and double perovskites: The MAPb_{0.5}Sn_{0.5}Br₃ was prepared by mixing MABr, PbBr₂, and SnBr₂ with a 2:1:1 molar ratio in DMF (1.5 M). The double perovskites Cs₂AgSbCl₆ precursor solution was prepared by directly mixing CsCl, AgCl, and SbCl₃ with a 2:1:1 molar ratio in DMSO (0.4 M). The as-prepared solution was stirred under 60° C. until the solution became clear. Then, 0.4 M MAPbI₃ single crystal power is added to the solution to complete precursor solution preparation for achieving a suitable lattice constant with minimal lattice mismatch between the substrate and the inorganic slab of the epitaxial layer.

Device fabrication: MAPbBr₃ bulk crystals were used as the three-dimensional (3D) substrates as their synthesis is well-established. To further reduce the lattice mismatch, the mixed perovskite (or double perovskite) precursor was casted onto the MAPbBr₃ layer while hot to form a smooth epitaxial layer, which was the actual surface for growing the low-dimensional perovskites. The thickness of the smooth epitaxial layer does not influence the subsequent superlattice growth or device fabrication. Polyimide films (12.7 μm thick) were pre-patterned (with an opening size of 1 μm by 1 μm) to serve as the growth mask by following a reported method. Then, a layer of Au was deposited by sputtering to serve as the bottom electrode. Later, the PTAA solution (1.5 mg/mL in anhydrous toluene) was directly spin-coated onto the patterned polyimide/Au films at 2500 rpm for 30 s, followed by annealing at 80° C. for 3 min. Then the growth substrate was laminated with the polyimide/Au/PTAA mask and then spin-coated by supersaturated mixed perovskite (or double perovskite) precursor at 4000 rpm for 30 s followed by annealing at 100° C. for 5 min. Subsequently, low-dimensional perovskite growth solution (0.5 M in GBL) was spin-coated on the substrate at 1500 rpm for 60 s followed by annealing at 180° C. for 2 min to form the superlattice absorber layer. After that, ICBA (20 mg/mL in chlorobenzene) was spin-coated onto the epitaxial layer, followed by annealing at 100° C. for 5 min. Finally, a layer of ITO was deposited by sputtering to serve as the transparent top electrode.

DFT calculations: First-principles DFT calculations were performed using the Vienna Ab initio Simulation Package. The Projector Augmented Wave pseudopotential was used for describing electron-ion interactions. The Generalized Gradient Approximation parametrized by Perdew, Burke, and Ernzerhof was used to treat the electron-electron exchange-correlation functional. The van der Waals functional DFT-D3 was applied to properly describe the long-range dispersion interactions between the organic molecules in the hybrid materials. The hybrid functionals within Heyd-Scuseria-Ernzerhof formalism with 70% Hartree-Fock exchange were employed to calculate band gaps for the Sn-based perovskites. The wave functions were expanded in a plane-wave basis set with a cutoff energy of 400 eV. The structures for conventionally grown single crystal Ruddlesden-Popper perovskites and epitaxially grown perovskites were built based on experimental results of the lattices. The atomic positions were fully optimized until all components of the residual forces were smaller than 0.03 eV/Å. The convergence threshold for self-consistent-field iteration was set at 10⁵ eV. Γ-centered 2×1×4 and 4×4×1 k-point grids were used for superlattice and conventionally grown single crystals, respectively. Due to the limited computational resources, we could only simulate the n=3 structure, but this will not influence the device (n=5) because the formation mechanism of the double-bandgap structure is the same.

Morphology characterization: All scanning electron microscope (SEM) images were taken using a Zeiss Sigma 500 SEM. All optical images were taken using a Zeiss Axio Imager Optical Microscope.

Structure characterization: X-ray diffraction was measured by a Rigaku 393 Smart lab diffractometer equipped with a Cu Kα1 radiation source (λ=0.15406 nm) and a Ge 394 (220×2) monochromator. The scanning transmission electron microscopy (STEM) images were taken using a cryo-FEI 200 kV Sphera microscope. Samples for the STEM were prepared using a frozen focused ion beam (FEI Scios Dual Beam FIB/SEM). The conventionally grown single crystal was hard to be imaged by STEM since the sample without an epitaxial substrate curled quickly due to its instability in the STEM. X-ray photoelectron spectroscopy (XPS) measurements were carried out using Kratos AXIS Supra with a He I (21.22 eV) source under 10⁻⁸ torr chamber pressure.

Optical characterizations: Photoluminescence (PL) and time-resolved PL (TRPL) measurements were performed with a confocal microscope system focusing a monochromatic 6 ps-pulsed laser with a ×4 objective lens (numerical aperture 0.13). Optical functions were measured by ellipsometry (J.A. Woollam M-2000D Spectroscopic Ellipsometer). Ultraviolet photoelectron spectroscopy (UPS) measurements were carried out using Kratos AXIS Supra with a He I (21.22 eV) source under 10⁻⁸ torr chamber pressure. Ultraviolet-visible spectroscopy (UV-vis) and absorption spectra were collected using a Perkin Elmer Lambda 1050 UV-vis system under the reflection mode.

Electrical characterizations: Polarized photocurrent was measured with a polarizer. Time-of-flight was measured by extracting the decay time of the transient photocurrent to calculate the carrier mobility. An external bias of 0.5 V was used to power the devices with a resistor connected in series. Orientation-dependent transient photovoltages were measured with an oscilloscope (Agilent MSO6104A Channel Mixed Signal) to study the carrier lifetime. A pulsed laser with a pulse width of less than 10⁻¹⁰ s was used as the light source. The electron beam induced photocurrent (EBIC) was collected using a FEI Scios Dual Beam microscope with a Mighty EBIC 2.0 controller (Ephemeron Labs) and a Femto DLPCA-200 preamplifier. Lateral Au electrodes were deposited by electron-beam evaporation for surface measurements; a pre-patterned Au-coated polyimide film was used as the bottom electrode for cross-section measurements; the top surface was deposited with a layer of Au by electron-beam evaporation to serve as the top electrode. The EBIC and SEM images of the same region of interest were collected simultaneously. The samples were several micrometers in thickness, while EBIC could penetrate up to several micrometers into the samples. The transient absorption spectroscopy was performed using an ultrafast transient absorption system with a tunable pump and white-light probe to measure the differential absorption through the sample. The laser system consists of a regeneratively amplified Ti:sapphire oscillator (Coherent Libra), which delivers 4 mJ pulse energies centered at 800 nm with a 1 kHz repetition rate. The pulse duration of the amplified pulse is approximately 50 fs. The laser output was split by an optical wedge to produce the pump and probe beams and the pump beam wavelength was tuned by an optical parametric amplifier (Coherent OPerA). The pump beam was focused onto the sample by spherical lens at near-normal incidence (spot size FWHM˜300 μm). The probe beam was focused onto a sapphire plate to generate a white-light continuum probe, which was collected and refocused onto the sample by a spherical mirror (spot size FWHM˜150 μm). The transmitted white light was collected and analyzed with a commercial absorption spectrometer (Helios, Ultrafast Systems LLC). Pulse-to-pulse fluctuations of the white light continuum were accounted for by a simultaneous reference measurement of the continuum. The pump wavelength was maintained at 610 nm with a pulse power of 100 nJ (or approximately 80 μJ/cm²). Pump and probe beam were linearly cross-polarized and any scattered pump-light into the detection path was filtered by a linear polarizer. The time delay was adjusted by delaying the pump pulse with a linear translation stage (minimum step size 16 fs). The individual component kinetic traces were fit to biexponential decays via least squares fitting.

Photovoltaic characterizations: Current density-voltage (J-V) measurements were carried out using a Keithley 2400 source meter under a simulated air mass of 1.5 irradiation (100 mW/cm²) and a xenon-lamp-based solar simulator (Oriel LCS-100). Temperature-dependent J-V measurements were performed with the sample in a liquid nitrogen cooled metal tank, where one side was glass to allow illumination. The same configuration was used for both epitaxial and polycrystalline devices. External quantum efficiency (EQE) data were collected by illuminating the device under monochromatic light using a tungsten source (chopped at 150 Hz) while collecting the photocurrent by a lock-in amplifier in the alternating current mode. The 2D mapping of the thickness-dependent EQE was generated from the Contour-Color Fill function. Wavelength-dependent J-V measurements were carried out by applying a series of bandpass filters (Newport) under the solar simulator to measure both the polycrystalline and epitaxial devices.

### Epitaxial Superlattice Structure

Low-dimensional perovskites show improved long-term stability due to the hydrophobic organic surface terminating ligands and hysteresis-free electrical transport, probably because of the high exciton binding energy of the multiple-quantum-well. Unlike the traditional three-dimensional (3D) metal halide perovskite (e.g., MAPbBr₃ and MAPbI₃; MA=methylammonium), low-dimensional perovskites are composed of two parts: the inorganic slab and the organic spacer. In the inorganic slab, the structure (metal-halide frameworks and the organic cations) is the same as that of the traditional 3D perovskite. However, because of the existence of the organic spacer (e.g., BA and PEA; BA=butylamine; PEA=phenethylammonium), the continuous crystal structure in the 3D perovskite is split evenly into periodic two-dimensional (2D) layered structures, which results in a natural multiple-quantum-well. Therefore, the major difference between the 3D and low-dimensional perovskites is the layered organic spacers, which determine the n value (i.e., the layer of the inorganic slabs) of the chemical formula B₂Aₙ₋₁MₙX₃ₙ₊₁ (e.g., B═R—NH₃⁺; A=CH₃NH₃⁺, HC(NH₂)₂⁺, Cs⁺, Rb⁺; M=Pb²⁺, Sn²⁺; X=Cl⁻, Br⁻, I⁻) for low-dimensional perovskites.

In polycrystals, low-dimensional perovskites cannot form a long-range order due to the misaligned orientations of the inorganic slabs, representing the major limiting factor for achieving highly efficient carrier dynamics. Bulk single crystals are valuable for studying fundamental material properties of low-dimensional perovskites but are less useful for building devices that usually require thin films. Thin plates of single-crystal low-dimensional perovskites have been demonstrated, but due to their natural growth behavior, those thin plates are usually made of large-area inorganic slabs stacking on top of another, so they have only in-plane carrier transport within the slab but not out-of-plane carrier transport between the slabs as required for building high-performance electronic devices. Specifically, carriers can transport along the inorganic slabs very efficiently, but when they travel across to the insulative organic spacers, strong recombination and trapping will take place. Even though 3D/2D thin films have been studied, the 2D components were only introduced to passivate 3D perovskites but not to engineer the 2D structure. As a result, the orientation, lattice strain, and carrier dynamics of formed low-dimensional perovskites are still uncontrollable.

The low-dimensional perovskite superlattice reported in this work overcame these challenges. BA₂SnI₄ (n=1) is the most challenging for engineering the quantum mechanics to achieve high-efficiency carrier dynamics compared to higher n-value quasi-2D perovskites, which usually forms the horizontally aligned quantum-well structure and has the highest exciton binding energy and, therefore, the worst carrier dynamics. Therefore, we chose BA₂SnI₄ as an example to study its growth mechanism and intrinsic electrical properties.

The superlattice could be obtained by a heteroepitaxial growth method (FIG. 7). In this epitaxial system, because the substrates were still perovskites, they were able to form strong metal-halide ionic bonds with the inorganic slabs (FIG. 1b), which was much stronger than the weak Van der Waals forces between the substrate and the organic spacers in the low-dimensional perovskite layer. In this case, we could use chemical bonds to selectively anchor different facets in the low-dimensional perovskites to realize accurate quantum-well alignment, as well as orientation control. In addition, the growth along horizontal orientations (FIGS. 6a and 6b) was not considered to be stable because it was not energetically favorable to form horizontal epitaxial layers where a complete organic or inorganic layer was grown on the substrate as the first layer, which would otherwise contain a perovskite layer of an infinite n, a thermodynamically unstable structure (FIG. 6).

Therefore, the epitaxial layer formed a vertically aligned rather than a horizontally aligned structure (FIGS. 1a and 1b; FIGS. 6, 7, and 8). The vertically aligned structure could be visualized by both scanning electron microscopy (SEM) and scanning transmission electron microscopy (STEM), showing apparent morphology differences from traditional 2D and 3D perovskites.

Besides the epitaxial orientation, the as-grown crystals were also found to exhibit a plate with crisscross morphologies (FIG. 1a; FIGS. 7 and 8). The reason originated from the growth rate and substrate. In general, the growth rates of perovskites along the horizontal or vertical directions can be controlled by tuning the growth temperature and the precursor concentration. At a low growth temperature, the growth rate in all directions is low because of the temperature-reversal growth behavior. Then the growth rate is surface reaction controlled. The precursor molecules have sufficient time to diffuse and adsorb at the most energetically favorable locations. The tri-phasic interface between the 3D perovskite substrate, the epitaxial low-dimensional perovskite, and the growth solution is more favorable for nucleation and growth than the bi-phasic interface between the epitaxial low-dimensional perovskite and the growth solution. Therefore, the precursor molecules would prefer to adsorb at the tri-phasic boundary, which contributes to the growth in the horizontal directions (i.e., along the substrate surface). This is also probably why in the literature, almost all of the freestanding bulk single crystals have footprints on the substrate larger than thicknesses. The same analysis applies to the scenario when the growth rate is low at a low precursor concentration. On the other hand, a high growth temperature and a high precursor concentration lead to growth along the vertical direction (perpendicular to the substrate). Because of the high growth rate under the high temperature and high concentration, the crystal would quickly consume the precursor molecules in their vicinity. The growth rate is diffusion controlled. Precursor molecules would be depleted in regions among the crystals, and therefore the growth along the horizontal directions is slowed down or limited due to the internal competition for precursor molecules. Then the growth rate would be dependent on the precursor diffusion from the bulk solution, which is from the vertical direction of the crystals. Fresh precursor molecules would first arrive at the top surface of the crystals and thus contribute to the fast growth along the vertical direction of the crystals. In this epitaxial process, the substrates in this study (e.g., MAPb_{0.5}Sn_{0.5}Br₃) all had a cubic lattice structure, suggesting that the lattice parameters in the a and b directions are symmetric. There would not be any differences if the epitaxial crystal plates were growing along the a or b direction. As a result, the chances for the epitaxial crystal plates to grow along the a and b directions were theoretically 50%-50%. Therefore, the as-grown epitaxial layers exhibit two perpendicular crisscross morphologies.

Besides, it was also worth pointing out that even though we also used spin coating as an approach, it was only a way to generate a uniform coating of the growth solution. The growth still followed an epitaxial growth mechanism, a much slower kinetic process, which was entirely different from that of the traditional spin coating method. In the traditional spin coating method for making low-dimensional perovskite thin films, the preparation of their precursor solution was usually done by a simple mixture of organic and inorganic materials under calculated molar ratios. Also, volatile solvents or co-solvents (e.g., dimethyl sulfoxide (DMSO); dimethylformamide (DMF); DMF/DMSO) were typically used. Some other approaches, such as antisolvents and hot-casting, were used to accelerate crystallization and obtain high-coverage and uniform films. Low-dimensional perovskite films could usually be formed during the spin coating process, which was also an indicator for its highly dynamic process. In this way, it was challenging to obtain component-pure high-n value 2D perovskites.

In the spin coating process of this work, there were three key fundamental differences:

1. Traditional spin coating was done on non-perovskite substrates (e.g., ITO (indium tin oxide) or FTO (fluorine-doped tin oxide), electron transport layer (ETL), or hole transport layer (HTL)). The spin coating in this work was performed on a single-crystal perovskite substrate. Only when the spin coating was on a single-crystal perovskite substrate, it was possible to trigger the chemical epitaxial growth of low-dimensional perovskite superlattice.
2. In this work, we used non-volatile γ-Butyrolactone (GBL) as the solvent to prepare the precursor solution. After spin coating, the surface was still wet with a clear precursor solution, and up to this point, no crystallization happened. Only the subsequent high-temperature annealing (e.g., >120° C.) could slowly evaporate the solvent and start the epitaxial growth. However, in the traditional spin coating process, the crystallization of low-dimensional perovskites was almost instant.
3. The precursor solutions we used were not a simple mixture of organic and inorganic materials under calculated molar ratios. In contrast, they were prepared by dissolving low-dimensional perovskite single-crystal flakes with certain n values, which had been reported for making high-n value low-dimensional perovskites. Those single-crystal flakes had been synthesized and purified, and flakes with different n-values had slightly different synthesis methods. Therefore, by using the flake-redissolved precursor solutions, the n-values in the as-grown superlattice materials were considered to be highly pure.

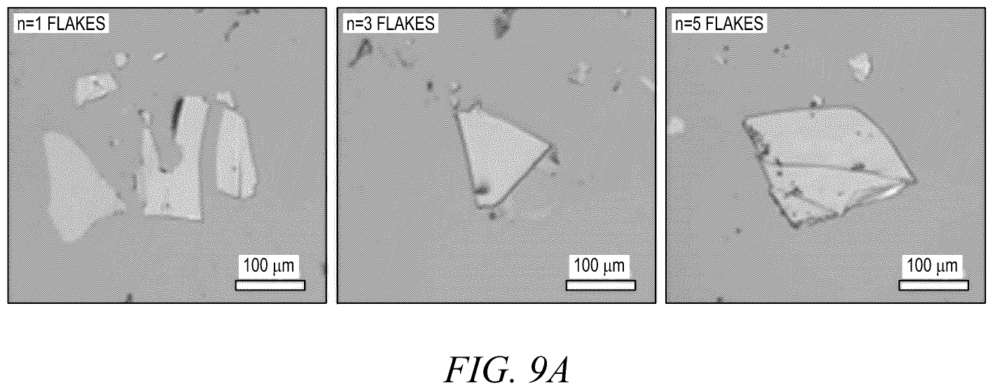

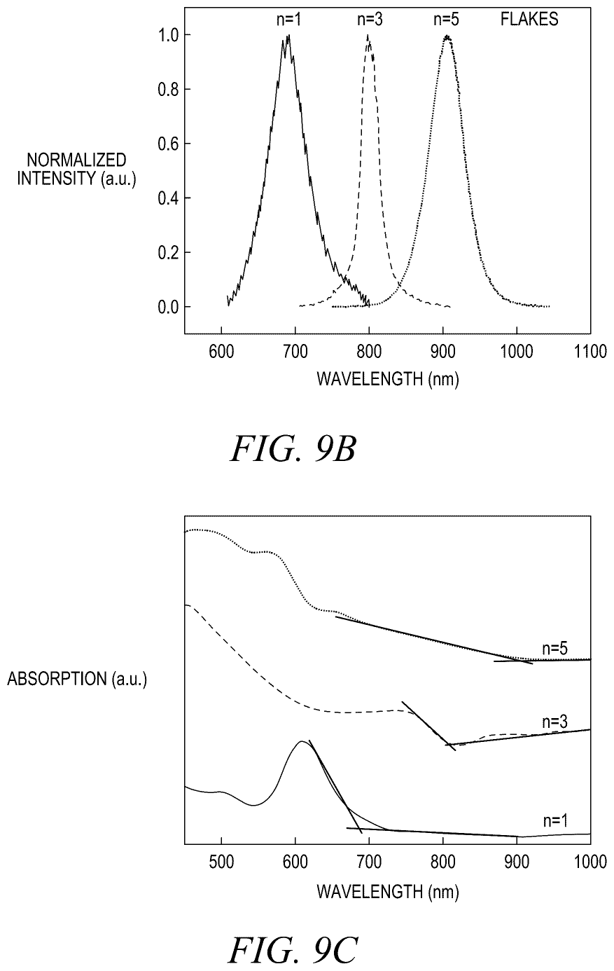

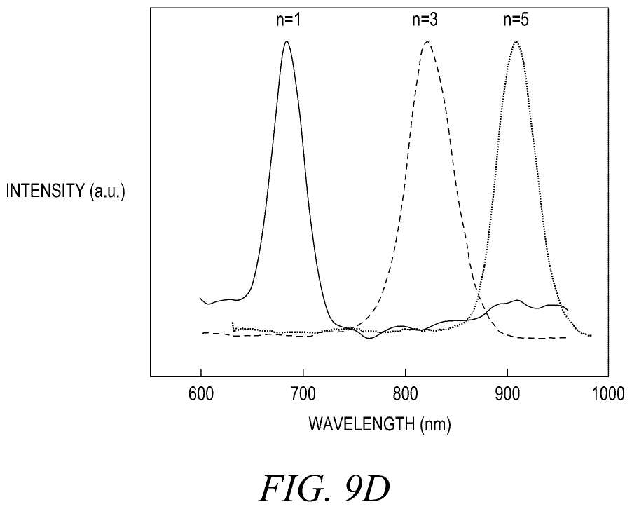

The verification of the purity of n values is shown in FIG. 9. It is clear to see that different single-crystal flakes (FIG. 9a) exhibited different but distinct photoluminescence (PL) signals (FIG. 9b), suggesting that they were not component-mixed crystals. Besides, we had also prepared corresponding precursors and fabricated polycrystalline thin films by spin coating. Similarly, both UV-vis (FIG. 9c) and PL (FIG. 9d) results of those samples exhibited distinct signals that were not likely to be composed of a multiple-n-value structure, indicating that the superlattice was not composed of a mixed n-value structure.

### In-Situ Devices

The fabrication of in-situ superlattice devices is illustrated in FIG. 18. In short, the epitaxial growth of superlattices was based on a single crystal 3D perovskite (e.g., MAPb_{0.5}Sn_{0.5}Br₃). In this work, the patterned opening has a size of 1 μm by 1 μm with a pitch of 0.5 cm by 0.5 cm. Then we sputtered a ˜100 nm thick layer of Au, followed by spin coating a ˜100 nm layer of poly[bis(4-phenyl)(2,4,6-trimethylphenyl)amine] (PTAA), on top of the patterned polyimide thin film. The Au and PTAA served as the bottom electrode and HTL in the solar cell, respectively. Because the polyimide was already patterned, the as-deposited Au/PTAA layers were also naturally patterned (FIG. 94a). The patterned polyimide/Au/PTAA layers were very thin and mechanically flexible, so we could tightly and conformally laminate them on top of a smooth 3D perovskite substrate as the growth mask. We used PDMS or scotch tape to seal the mask on the mask edges. After that, a thin layer of precursor solution was spin-coated on top of the mask at a rate of 4000 rpm/s to allow the solution to fill all patterned openings. The precursor solution had the same composition as that for growing the 3D perovskite substrate, which led to the epitaxial growth of a thin layer of substrate on top of the mask during annealing. Finally, another layer of precursor solution for growing the low-dimensional perovskites was spin-coated at a spin rate of 1500 rpm, followed by annealing to trigger the growth of epitaxial superlattices. Different annealing times led to different morphologies of the superlattice (FIG. 7).

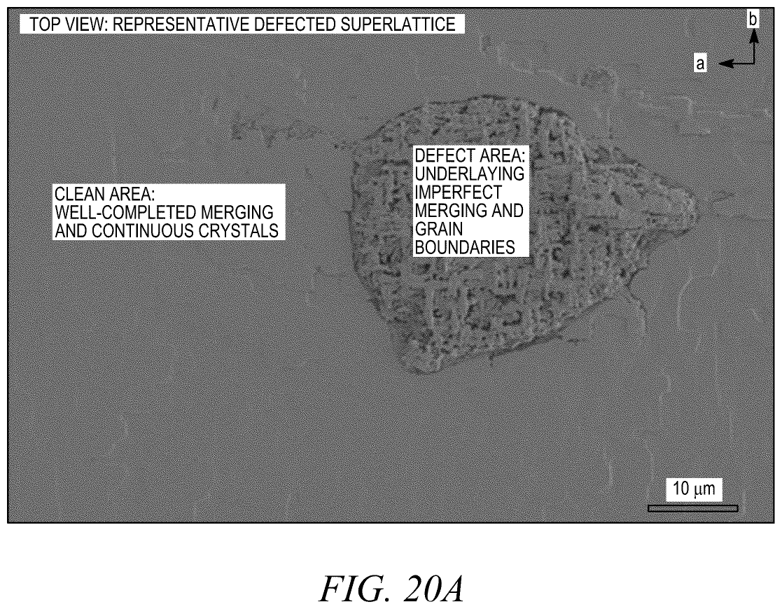

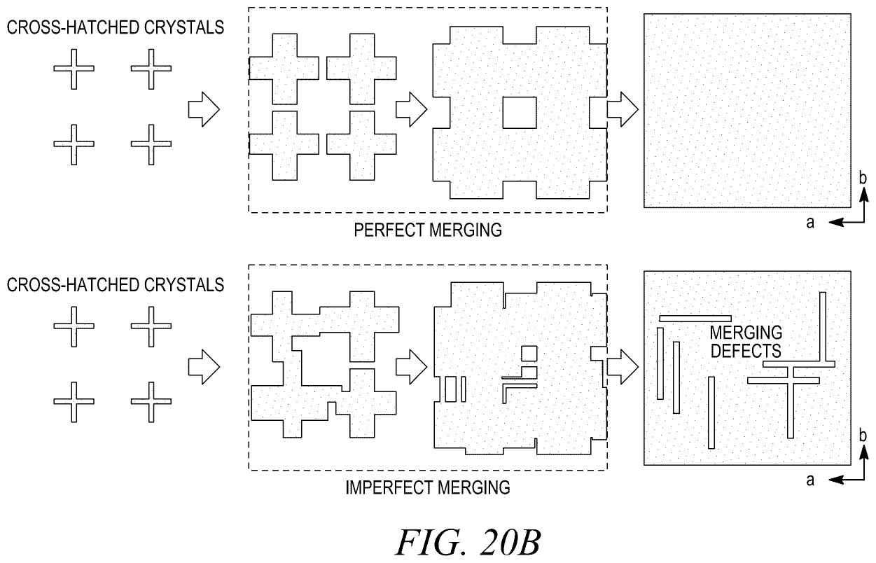

In this process, the very thick single-crystal substrate only served as the substrate to attach the patterned mask layers and support the growth of the epitaxial substrate layer. The thin epitaxial substrate layer was used as the template to support the epitaxial growth of low-dimensional perovskite superlattices, which ensured full contact between the substrate and the superlattice to minimize interfacial growth defects such as lattice dislocations. For example, if there were no epitaxial substrate layer (FIG. 19b), the superlattice in the dashed boxes would only contact PTAA. In this case, epitaxial growth could not be initiated by the PTAA, but only by a “horizontal merging process” from the existing epitaxial superlattices located on top of the patterned openings. Because the horizontal merging was not perfect, the defect density might be high (FIG. 20). Therefore, the epitaxial substrate layer was necessary and also integrated into the solar cell between the PTAA (HTL) and superlattice (absorber) layers.

The as-fabricated in-situ devices based on this method were not likely to be practical for high-performance device applications though. Both holes and electrons in perovskites had limited diffusion lengths. Interfacial charge recombination was critical for the perovskite devices performance. This epitaxial substrate layer not only increased the overall thickness of perovskite layers, but also introduced an additional interface for holes to overcome, which increased charge recombination. Therefore, the thickness of the epitaxial substrate layer would influence the extraction of holes in solar cells and the eventual device performance. With the current fabrication parameters, 4000-rpm spin coating of a supersaturated GBL solution produced a 200 nm˜300 nm epitaxial substrate layer. We kept the same procedural parameters for all different batches of devices.

Besides, they were based on a patterned bottom Au/HTL layers and a continuous electron transport layer/top ITO electrode. Because of the unbalanced size of the bottom and top electrodes (FIG. 19b), only parts of the superlattice layer would be activated under illumination of the superlattice absorber (the dashed square in FIG. 19b top). In this way, a large part of the superlattice layer was wasted. Additionally, the top electrode was homemade ITO, whose sheet resistance was not comparable to that of commercial ITO glasses, strongly limiting the solar cell performance. Therefore, the device performance could potentially be largely improved if we balanced the sizes of the top and bottom electrodes and adopt a transfer process to fabricate devices. Moreover, in-situ superlattices and their devices could not exhibit a promising stability due to the large heteroepitaxial strain, making those in-situ devices less practical.

However, because this work focuses on the new superlattice structure and its efficient carrier dynamics, the devices in this work were in-situ fabricated so that we could exclude those confounding influences from fabrication steps. The certified superlattice solar cell was integrated with a bulk MAPb_{0.5}Sn_{0.5}Br₃ substrate. In that case, the substrate only served as the template to support the growth of the superlattice and was not a functional component in the fabricated solar cell.

An epitaxial lift-off and transfer step works better for the device performance, but that would prevent us from studying the fundaments of superlattices (e.g., exciton binding energy, strain-induced ion aggregation, and atomic-scale band structure). Thus, we did not introduce the epitaxial lift-off and transfer in this work but only focused on the strained in-situ device. The solar cell certificate in this work mainly served to: confirm the efficient carrier dynamics in the low-dimensional perovskite superlattice and prove the unusually high open circuit voltage (V_{OC}).

### EBIC Mapping

We used EBIC mapping to visualize the surface current of different low-dimensional perovskites. The factors that would influence the current include the bandgap and the carrier recombination centers. In FIGS. 2d and 2e, the current mapping results from the polycrystalline samples showed a non-homogenous feature, indicating that different grains exhibited different carrier collection efficiencies, which was attributed to the random crystal orientations in those grains. Besides, the lowest current signals always appeared at the grain boundaries, suggesting that the polycrystalline structure suffered from serious carrier recombination, particularly at the grain boundaries.

In contrast, the epitaxial superlattice samples showed very different signals. Even though the SEM images exhibited flat surface morphologies, the EBIC signals captured simultaneously showed crisscross or linear signal features. Such a phenomenon was from the imperfect crystal merging during the processes of forming the epitaxial thin film, which was almost impossible to avoid due to the thin plate merging. Also, because of the strong lattice strain, the possibility for crystallography defects (e.g., lattice misorientation and dislocations between the organic spacers and the inorganic slabs) was relatively high (FIG. 3b; FIG. 20). SEM imaging is based on scattered electrons at the sample surface, while EBIC can collect current signals several micrometers deep into the samples. Therefore, those defects, even though not visible at the surface by SEM, were captured in EBIC. Additionally, the signal intensity was much higher in the superlattice samples than that in the polycrystals due to the enhanced carrier generation and collection, which were attributed to the reduced energy bandgap (FIG. 25) and transport barriers, respectively.

### Lattice Strain

The strain was caused by the lattice mismatch between the substrate and the epitaxial layer. In traditional 3D perovskites, the lattice strain was usually very small. Otherwise, the epitaxial layer would not grow at the first place because the large strain energy would significantly increase the barrier for nucleation. However, in low-dimensional perovskites, a large composition is the relatively soft organic spacers. Therefore, the structure becomes more deformable and can tolerate larger strain levels. As a result, even though the strain between the inorganic slabs and the substrate was still small, the strain between the organic spacers and the substrate could be much larger.

In the low-dimensional perovskite superlattice, each inorganic slab was epitaxially grown on the substrate through metal-halide ionic bonds. In this way, the organic spacers (BA, ˜0.700 nm in conventionally grown single crystals) in between the inorganic slabs would be compressed by the adjacent inorganic slabs to fit into a single lattice unit (˜0.596 nm) of the substrate (FIG. 1b). The organic spacers would not be stretched over two lattice units (˜1.192 nm) of the substrate, which would otherwise cause too large strain to be thermodynamically stable. Therefore, the overall lattice strain was from two aspects: the inorganic slab, which was relatively small, and the organic spacer, which was relatively large.

In FIG. 3a, the x-ray diffraction (XRD) results were used to calculate the overall lattice constants along the a, b, and c directions of the low-dimensional perovskites. The material in those measurements corresponds to n=1. The Sn—I bonds (in conventionally grown single crystals) in the a-b plane were treated the same as those in their 3D counterparts. Therefore, the first peak at 14.660 in the a-c b-c plane of the conventionally grown single crystal was used to calculate the d-spacing between two Sn atoms. According to Bragg's Law, the calculated d-spacing was ˜6.04 nm in both b and c directions. And the first peak at 6.77° in the a-b plane of the conventionally grown single crystal was also used to calculate the d-spacing between two Sn atoms along the a direction, resulting in a d-spacing of ˜13.04 nm.

Similarly, the first peak at 14.50° in the a-c b-c plane of the superlattice was used to calculate the d-spacing in the c direction, which was ˜6.10 nm. Therefore, the tensile strain along the c direction was (6.10-6.04)/6.04=0.99%. Additionally, the first peak at 7.41° in the a-b plane of the superlattice was used to calculate the d-spacing in the a direction, ˜11.92 nm. Therefore, the compressive strain along the a direction was (11.92-13.04)/13.04≈−8.59%. Finally, together with the STEM analysis, the compressive strain along the b direction was (6.04−11.92/2)/6.04=1.32%.

In the calculations, we only used the first peak because the other peaks were the multiple-order diffractions of the first peak.

### The Dielectric Confinement

The low-dimensional perovskites contain alternating inorganic slabs and organic spacers. The dielectric constants of those two parts are very different, where the dielectric constant of the inorganic slabs is much larger than that of the organic spacers, resulting in strong dielectric confinement. Therefore, due to the large compressive strain, the dielectric constant in organic spacers was increased, indicating that the difference between the inorganic slabs and the organic spacers was smaller, which resulted in weakened dielectric confinement. Additionally, the compressed thickness of organic spacers led to reduced barrier width of the multiple quantum well and therefore weakened dielectric confinement.

### Bi³⁺ Alloying

The epitaxial growth of low-dimensional perovskites on traditional 3D perovskites introduced enormous lattice strains. Even though the BA could tolerate the structural deformation to a certain extent, the compression from the organic spacers to their adjacent inorganic slabs could still cause structural failure of the Sn—I slabs from their original black phase to a transparent phase in just several days (FIG. 24). The degradation rate was found to be highly related to the n-value in the general formula of low-dimensional perovskites (FIG. 23). The smaller the n, the more rapid the degradation.

For example, when n=1, the width of a unit cell in a conventionally grown single crystal (containing one inorganic slab and one BA) is 0.604 nm+0.7 nm=1.304 nm, which would be fitted into two unit cells of the 3D perovskite substrate whose width is 0.596 nm+0.596 nm=1.192 nm, resulting in an overall epitaxial strain of 8.59% (Table 1). As the n value increases, the volume ratio of the inorganic slabs gets larger. Even though the lattice strain between the inorganic slabs and the substrate does not change, the overall epitaxial strain is reduced (FIG. 3b). For n=5, the overall strain is calculated to be 3.87%. Additionally, a high n-value inorganic slab can tolerate stronger compressive forces applied by the organic spacers because there are multiple inorganic layers to help share the force.

Even though high n-value epitaxial layers were more stable, they still underwent phase-change from black to transparent in usually less than 3-5 days (FIGS. 23, 24, and 28), which was challenging for device fabrication as well as practical applications. Therefore, it was necessary to find a strategy to reduce the strain and improve their stability further.

Reducing the lattice constant of the epitaxial layer by alloying/doping small sized-ions can potentially reduce the strain in the superlattice and thus enhance its stability. Bi³⁺ was chosen as a smaller metal ion to partially replace the Sn²⁺ to release more space for the BA. Density Functional Theory calculations were carried out to evaluate the effect of Bi³⁺ alloying. Perovskite with n=3 was adopted as a model in this work because it contained both MA and BA, and its structural complexity can be afforded by the computational capacity in this work (FIG. 26). Calculation results showed that the Bi³⁺ was more likely to replace the Sn²⁺ close to the BA to achieve a lower total energy of the entire lattice. When the replacement site was further away from the BA, the total energy became larger. Therefore, Bi³⁺ preferably aggregated at the BA/inorganic slab interface (FIG. 27).

The calculations also revealed that the aggregated Bi³⁺ alloying could vastly change the band structure (FIGS. 29 and 30): a much-decreased conduction band minimum (CBM) with an almost unchanged the valence band maximum (VBM) at the Bi³⁺ aggregated interfacial region. Therefore, the Bi³⁺ alloying resulted in a double-band structure in the inorganic slabs, where the alloyed Bi/Sn—I region showed a smaller bandgap than the intact Sn—I region, due to the strain-induced Bi³⁺ ion aggregation.

However, the PL characterization showed two kinds of phenomena, where both radiative emission and non-radiative emission were found at different excitation areas on the same sample (FIG. 28b). The non-radiative emission suggested that sub-band tail states were formed, which was attributed to the Bi³⁺ doping. The strong radiative emission suggested an altered electrical band structure, which was attributed to the aggregated Bi³⁺ alloying. Because Bi³⁺ ions were impossible to be perfectly aggregated at the interface throughout the entire sample area, the co-existence of doping/alloying resulted into two kinds of PL results.

### Intra-Band Exciton Relaxation

In principle, the V_{OC} of a photovoltaic device was determined by the internal quasi-fermi-level splitting, which always stayed inside the bandgap of the absorber. Photovoltaic devices based on the Bi³⁺ alloyed low-dimensional perovskite superlattice were found to exhibit a largely improved V_{OC} (FIG. 34). The carrier collection cutoff of the solar cell is determined by the component of the lowest bandgap, i.e., 1.042 eV of the Bi/Sn—I region in this case. This low bandgap region did not affect the overall V_{OC} of the final device. The observed high V_{OC} suggests unusual electron transport mechanisms in the superlattice.

To investigate the mechanism, we performed wavelength-dependent current density-voltage (J-V) measurements on both superlattice and polycrystalline devices (FIG. 4d). The polycrystalline devices also contained the same concentration of, but uniformly mixed, Bi³⁺.

We extracted the corresponding V_{OC} and fill factor (EE) to evaluate carrier collection efficiencies (FIG. 4e). It showed that the FE in the polycrystalline devices was maintained to be ˜0.3-0.4, which was relatively constant at different wavelengths of the incident light, because the band tail states (e.g., traps that are introduced by Bi³⁺ doping) of the thin film was uniform. In contrast, the FE in the superlattice devices kept ˜0.7 when the incident light wavelength was less than ˜900 nm and began to drop to ˜0.15 when the incident light wavelength was ˜1100 nm. The V_{OC} of the polycrystalline devices fluctuated within a reasonable range due to their defective band tail states and abruptly dropped at ˜1000 nm due to the below-band weak absorption (e.g., when the incident light wavelength was >˜1000 nm, the device was no longer working). However, even though the V_{OC} of the superlattice devices also began to drop when the incident light wavelength was at ˜900 nm, the device still exhibited a working condition with a V_{OC} of ˜0.45 V when the incident light wavelength was ˜1100 nm. Those results clearly revealed that the excitation energy was critical for the superlattice devices, and the band structure of superlattice devices was different from that of polycrystalline devices.

Structural computation illustrated that Bi³⁺ ions in the superlattice concentrated at the interface between the inorganic slab and the organic spacer to form an atomic-level alloyed layer. As a result, the superlattice exhibited an additional atomic-level heterostructure, which led to a different atomic-level electronic band structure (Bi/Sn—I region, FIG. 28b). Due to the vertically aligned superlattice structure, the Bi/Sn—I region and the Sn—I region in the inorganic slabs were connected to the ETL simultaneously (FIG. 4c). Under excitation, the electrons at the high-energy states could come from both the Bi/Sn—I and the Sn—I regions. During the high-energy electron relaxation process, those electrons generated from the Sn—I region will relax to the Sn—I region to be extracted by the ETL layer. Moreover, those high-energy electrons (higher than the CBM of the Sn—I) generated from the Bi/Sn—I region could also relax, by intra-band diffusion, to the Sn—I region rather than to the Bi/Sn—I region.

In this way, if the excitation energy was higher than the bandgap of the Sn—I region, the V_{OC} magnitude was mainly determined by the energy level of the ETL and the band tail states near the VBM of the Bi/Sn—I region, which is not related to the bandgap of the Bi/Sn—I region. When the excitation energy was less than the bandgap of the Sn—I region but higher than the bandgap of the Bi/Sn—I region, the V_{OC} magnitude was mainly determined by the energy level of the band tail states near the CBM and the band tail states near the VBM in the Bi/Sn—I region, which resulted in a low V_{OC}.

Under mixed excitation energies, those high-energy electrons, which were excited by the short-wavelength from both Bi/Sn—I and Sn—I regions to states higher than the CBM of the Sn—I region, were extracted by the ETL, indicating that the quasi-fermi-level splitting was mainly determined by the Sn—I region, which results into a high V_{OC}. In the meantime, those low-energy electrons excited by the long-wavelength only exist in the Bi/Sn—I and cannot efficiently transport to the CBM of the Sn—I or the ETL-they could not be either directly extracted by the ETL or transport to the Sn—I region. Their energy and quantity are both low, which minimally impacts the overall V_{OC} of the device.

In contrast, if a Bi/Sn—I based and a Sn—I based photovoltaic devices were fabricated separately and directly connected in parallel by external cables, the overall output voltage of this combined module would be equal to the output voltage of the Bi/Sn—I one because this integrated module would be two standard power sources connected in parallel. In addition, even when two separate photovoltaic devices were in close contact with each other (e.g., as defined by advanced lithography), their absorber material dimensions could not support the inter-band hot carrier transport because the rapid relaxation of these hot carriers would prevent from transporting between the two absorbers of the separate devices.

### Pump-Probe Ultrafast Transient Absorption Spectrum Measurements

In the PL spectra (red curves in FIG. 28b), the majority of free electrons relax to the low CBM of Bi/Sn—I regions, but there is still a small peak at the lower wavelength from the Sn—I region. However, the observed high V_{OC} indicates that the quasi-fermi-level splitting is not determined by the Bi/Sn—I bandgap, which seems to be contradictory to the PL results.

To explain this phenomenon, we developed an “intra-band relaxation” mechanism in the above discussions. Many hot electrons generated in the Bi/Sn—I region could relax to the CBM of the Sn—I region; then, these hot electrons could be extracted by the ETL together with the electrons excited in the Sn—I region, resulting in the unusually high V_{OC}.

The reason why we think this intra-band relaxation mechanism is possible is three-fold:

1. The atomic-scale thickness of Bi/Sn—I regions means ultra-short carrier diffusion length and thus an ultra-short diffusion time.
2. The solar cell structure here is a p-i-n junction. Under the solar cell structure, the built-in potential might facilitate the atomic-scale relaxation of hot electrons from Bi/Sn—I regions to Sn—I regions, which is different from the situations with only perovskite material (e.g., during the PL measurement).
3. The CBM position of the ETL favors carrier extraction from only the Sn—I regions, as evidenced by the UPS and UV-vis data in the Table 2.

To gain more understanding on the possibility of this intra-band relaxation mechanism, we have measured pump-probe ultrafast transient absorption spectra on the superlattice devices. The working principle of this measurement is shown in FIG. 41. To verify the atomic-scale hot electron diffusion, we studied their relaxation time to calculate the diffusion length. Additionally, to verify the hot electron relaxation from Bi/Sn—I regions to Sn—I regions facilitated by the built-in potential in the solar cell, we measured the transient absorption spectrum under biased and unbiased conditions.

Because the in-situ fabricated solar cell contains a bulky non-transparent substrate and the transferred solar cell includes a non-transparent Au electrode, we could not measure anyone of them in the pump-probe equipment. Alternatively, we used a different device structure where an external electrical field could be applied to mimic the built-in potential of the solar cell. The detailed fabrication processes and device structures for both superlattice and polycrystalline thin-film devices are shown in FIG. 39. In this structure, two ITO glass slides serve as transparent electrodes. A transparent double-sided tape made of polypropylene (˜25 μm in thickness; 7 eV in bandgap; without any delocalized electrons for holding or transporting electrons) serves as an insulation layer to avoid current injection into the superlattices or polycrystalline thin films, which mimics the open-circuit working condition. A layer of ICBA was spin-coated on the absorber to serves as the ETL. Superlattices with n=3 were adopted because superlattices with n=5 were challenging to peel off entirely from the epitaxial substrate to fabricate a sample of the required size for ultrafast transient absorption spectrum measurements.

The measured transient absorption spectra for three different samples with and without the bias are shown in FIG. 5 and FIG. 40. The polycrystalline thin films (FIG. 40a) exhibit very different spectral profiles from superlattices (FIG. 5a and FIG. 40b). Obvious ground state bleaching (GSB) (the depletion of the ground state electrons to excited states) signals in the negative intensity region could be observed in superlattices, indicating more efficient carrier dynamics in the superlattices than those in the polycrystalline thin film.

To verify the atomic-scale hot electron diffusions, we extracted their relaxation time profiles at selected wavelengths (FIG. 42). By fitting the relaxation profiles using the multiexponential decay, we could derive hot electron lifetimes of those three different samples. The hot electron lifetimes of superlattices (Bi³⁺-alloyed and Bi³⁺-free) were 0.35 ps˜0.36 ps, almost twice that of polycrystalline thin films (˜0.19 ps). We chose three different wavelengths (e.g., 967 nm, 1061 nm, and 1303 nm) for each sample to ensure the measured lifetimes were reasonable, if the derived lifetimes at different wavelengths were similar.

Accordingly, the diffusion length for hot electrons can be calculated as:

$${L}_{D} = \sqrt{\frac{{K}_{B} \cdot T \cdot μ \cdot τ}{e}}$$

where K_{B} is the Boltzmann's constant, T is the temperature, μ is the electron mobility (FIG. 2a), τ is the hot electron relaxation lifetime, and e is the electron charge. The calculated hot electron diffusion length in polycrystalline thin films (˜1.41 nm) was less than half of those in superlattices (FIG. 42d). In superlattices, the hot electron diffusion length of the Bi³⁺-alloyed superlattice (˜3.86 nm) is more than six times of the width of the Bi/Sn—I regions (˜0.6 nm), suggesting that the hot electron can readily travel across the Bi/Sn—I regions to the Sn—I regions.

To verify the hot electrons relaxation from Bi/Sn—I regions to Sn—I regions facilitated by the built-in potential, we compared the transient absorption spectra with and without bias under the same experimental setup. We used pump photons of a short wavelength of 610 nm (FIG. 41), with a pump fluence of 100 nJ·cm⁻², to full excite both Bi/Sn—I and Sn—I regions. The GSB signals in the Bi-doped polycrystalline thin films were much weaker than those in superlattices, due to the relatively poor carrier properties. Furthermore, in the Bi³⁺-doped polycrystalline thin films and Bi-free superlattices (FIG. 40), neither GSB nor excited state absorption (ESA; corresponding to the absorption of a photon from a lower excited state to a higher excited state of the system) signals showed noticeable intensity changes when a bias was applied. However, in the Bi³⁺-alloyed superlattice (FIG. 5a), the GSB signals increased and the ESA signals decreased substantially when a 10 V bias was applied.

At zero bias, the GSB peaks in Bi³⁺-free superlattices were located at ˜840 nm (FIG. 40b), corresponding to the larger bandgap (˜1.47 eV, 843 nm) of Sn—I regions. In contrast, the GSB peaks in Bi³⁺-alloyed superlattices were mainly located at ˜925 nm (FIG. 5a), corresponding to the smaller bandgap (˜1.34 eV, 925 nm) of Bi/Sn—I regions. Note that there were small broad peak shoulders at ˜830 nm in the dashed green square (FIG. 5a), which should be from the larger bandgap of Sn—I regions. Note that the GSB peak (˜925 nm) for Bi³⁺-alloyed superlattice (n=3) was shorter in wavelength than that measured by PL (˜990 nm; FIG. 28b), because of different sample platforms. In the transient absorption measurements, the superlattice was peeled off from the substrate, and the lattice strain was then fully released; however, in the PL measurements, the superlattice was still on the epitaxial substrate, and therefore, the organic spacers were largely compressed, reducing the superlattice bandgap (FIG. 3c and FIG. 25). Therefore, at zero bias, the transient absorption results were consistent with those PL results.

Under bias, only Bi³⁺-alloyed superlattices exhibited noticeable spectral changes compared to those at zero bias (FIG. 5a and FIG. 40). In general, the increased GSB signal intensities reflect the reduced population of ground-state electrons in the valence band: the higher the intensity (i.e., more negative the GSB peaks), the less the ground-state electrons in the valence band (i.e., the more electrons in conduction band). Therefore, the increased GSB signal intensities in Bi³⁺-alloyed superlattices under bias revealed a reduced number of electrons in the valence band. Because the excitation conditions for 0 V and 10 V measurements were the same (pump photons of 610 nm; pump fluence of 100 nJ·cm⁻²), the reduced number of electrons in the valence band was not from a stronger excitation. Therefore, we infer that the number of electrons relaxing from the conduction band to the valence band after excitation was reduced.

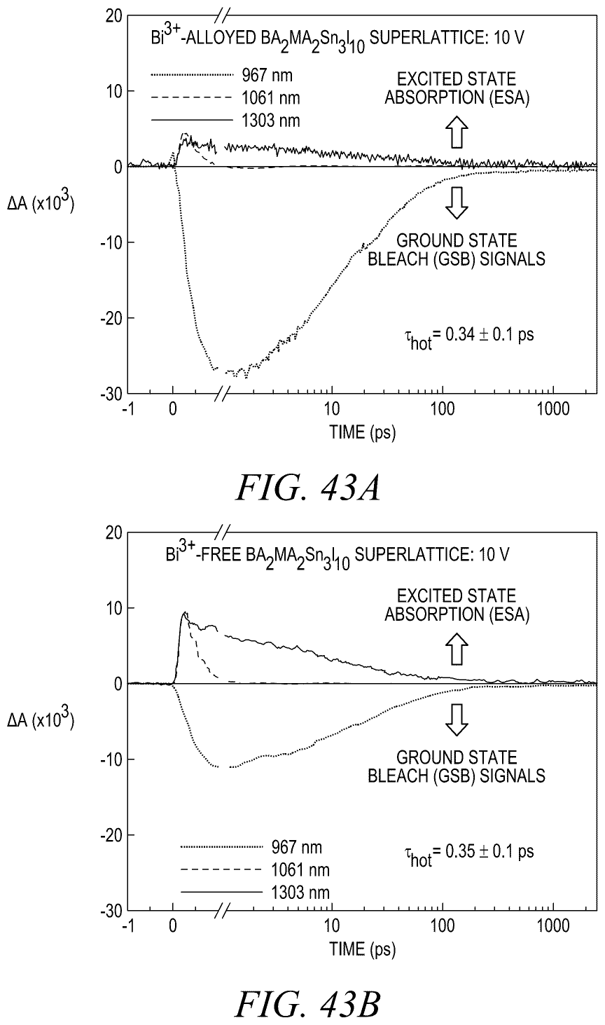

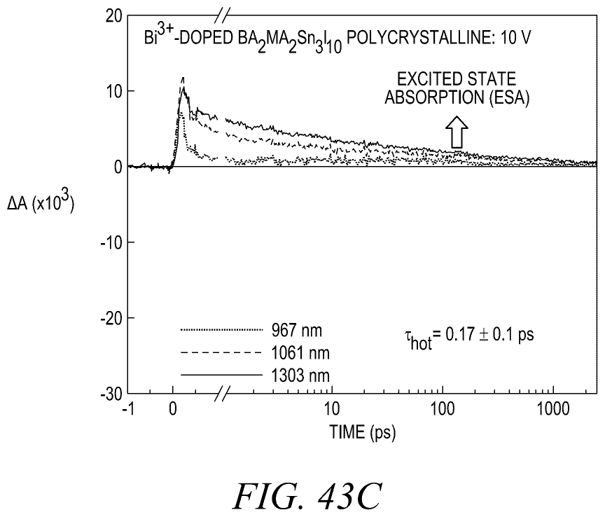

We measured the hot electron lifetime in all samples under bias (FIG. 43) and confirmed them to be close to those at zero bias (FIG. 42). Then those reduced number of electrons relaxing from the conduction band to the valence band after excitation must have transported to other adjacent layers. The direction of the electrical field determines that the electrons could not transport to the bottom ITO contact (FIG. 39). In this case, those reduced electrons could only transport to either the Sn—I regions or the ICBA ETL layer. In the Bi³⁺-doped polycrystalline thin-film, the GSB signals did not increase obviously, suggesting that the 10 V electrical field was not sufficient to drive electrons to overcome the interfacial barrier from the Bi/Sn—I region to the ICBA ETL (FIG. 4c). As a result, the only possibility was that those reduced electrons had transported to the Sn—I regions. Considering the even higher energy barrier between the CBM of Bi/Sn—I regions and that of Sn—I regions, the transport process could only be accomplished during the relaxation of hot electrons, supporting the intra-band relaxation mechanism.

We use a simplified physical picture to better describe this process: Without a bias, the probe has initially detected 100 electrons in the valence band of Bi/Sn—I regions (FIG. 41a). Then, the pump excited 50 electrons into the conduction band of Bi/Sn—I regions (FIG. 41b). Those excited electrons will relax; however, they can only go to the CBM of Bi/Sn—I regions but not the Sn—I regions or ICBA because of the high-energy barriers. Therefore, when the probe detects the ground state again, some of the excited electrons may be still under relaxation, or at the CBM, or already relaxed from the CBM to the valence band (FIG. 41c). Accordingly, the probe will detect, e.g., 75 electrons in the valence band. The GSB signal intensity (e.g., −25) corresponds to the reduced 25 electrons compared to the original 100 electrons (FIG. 41d).

With a bias, after the excitation, parts of the hot electrons can relax to the CBM in Sn—I regions (i.e., intra-band relaxation), because most of the hot electrons may already stay higher than the CBM of Sn—I and the atomic-scale diffusion length makes this intra-band relaxation efficient. However, those excited electrons are still not possible to travel to the ICBA because that requires a much longer diffusion length, as evidenced by the fact that there is almost no change in the transient absorption spectra for the Bi³⁺-doped polycrystalline device with and without the bias (FIG. 40a). Note that even though the Bi/Sn—I regions and the ICBA are in direct contact, the contact area is relatively small and the carriers have to diffuse through the entire thickness of the superlattice (a few hundreds of nanometers) along the c direction to access the ICBA. In contrast, the carriers in the Bi/Sn—I regions have to diffuse only the width of the Bi/Sn—I regions (˜0.6 nm) to access the Sn—I regions. Therefore, when the probe detects the valence band again, besides those excited electrons that are still during relaxation, at the CBM, or have already relaxed from the CBM to the valence band, there are also electrons relaxing to Sn—I regions. Accordingly, the probe will detect less than 75 electrons (e.g., 65 electrons) in the valence band. Those 10 electrons moved from the Bi/Sn—I region to the Sn—I region. As a result, the GSB signal intensity increases (more negative) to −35.

Besides the GSB signals, the decrease in ESA signal intensities in Bi³⁺-alloyed superlattice with a bias further supported the above mechanism. The changes in ESA signal intensities reflect the excited electron population that is excited further: the higher the intensity, the more the excited electrons get excited further (FIG. 41d). The decrease in ESA signals in Bi³⁺-alloyed superlattices with a bias was due to a reduced number of hot electrons in the conduction band. Because of the same excitation setup and similar hot electron lifetimes for 0 V and 10 V measurements (FIG. 42c and FIG. 43c), the obviously reduced hot electron population was not from a weaker excitation or more rapid relaxation but from additional relaxation routes. Because the ESA signals only refer to hot electrons in excited-states with short lifetimes, it was impossible for them to transport for long-distances. Therefore, we concluded that they could only relax to Sn—I regions due to the atomic-scale diffusion distance. The only two other layers contacting with Bi/Sn—I regions were ITO and ICBA, which had relatively long diffusion distances.

We can also use a simplified physical picture to better explain this process. Without a bias, there are 100 electrons in the valence band in Bi/Sn—I regions. When the pump excitation is on, 50 electrons are excited. Then, those excited electrons will relax. When the probe detects again, 25 electrons have already relaxed to the valence band, 5 electrons stay at the CBM, and 20 electrons are still during relaxation. Specifically, among the remaining 20 hot electrons, 10 of them (i.e., 50% of the possibility) can further absorb the excitation, which yields an ESA signal of +10.

With a bias, the same 50 electrons are excited. Because the bias yields a higher GSB intensity through the intra-band relaxation (FIG. 5a), there will be only 15 electrons relaxing to the valence band of Bi/Sn—I regions and 10 electrons relaxing to Sn—I regions. The rest 25 electrons are in the conduction band of Bi/Sn—I regions: 5 stay at the CBM and 20 are still during relaxation, while part of the latter (e.g., 6 electrons) can also relax to Sn—I regions. Then, there are only 14 electrons during the relaxation in Bi/Sn—I regions. Therefore, under the same 50% possibility for them to be re-excited, the number of excited hot electrons is 7, which yields an ESA signal of +7, smaller than the bias-free case (+10).

To summarize, the results of pump-probe ultrafast transient absorption spectra support the intra-band relaxation mechanism. Fundamental characterizations and device studies in this work have also confirmed the efficient carrier dynamics in the unprecedented low-dimensional perovskite superlattices, which can open a lot of exciting new opportunities in constructing high-performance devices using low-dimensional perovskite superlattices.

### FIGURES

FIG. 1 presents structural characterizations of the BA₂SnI₄ superlattice. In particular, FIG. 1(a) shows scanning electron microscope images showing the crisscross epitaxial BA₂SnI₄ superlattice before and after merging into a thin film. FIG. 1(b) shows schematics and atomic-resolution cryogenic-scanning transmission electron microscopy images showing the superlattice structure of a single plate. Cryogenic-scanning transmission electron microscope is essential to minimize the damage of beam-sensitive materials. The epitaxial layer has a well-aligned anisotropic structure without grain boundaries or dislocations. The insets are fast Fourier transform (FFT) patterns from the epitaxial layer in the a-c plane, which show a two-dimensional diffraction pattern of the superlattice and is different from that of the substrate. The inset FFT images in the b-c plane show the structural similarity between the inorganic slab and the substrate. Organic atoms are usually invisible under electron diffraction. FIG. 1(c) shows photocurrent measurements with a linearly polarized excitation source showing that the response of the epitaxial layer (top) exhibits a period that is half of a conventionally grown single crystal (bottom). FIG. 1(d) shows transient photovoltage measurements showing the orientation-dependent carrier lifetime in the a-b plane. The inset optical image shows the measurement setup. The error bars are from measurements of five different devices.

FIG. 2 illustrates carrier transport properties of the BA₂SnI₄ superlattice. In particular, FIG. 2(a) shows transient photocurrent measurements along the film thickness (c) direction. The superlattice shows the highest carrier mobility. The carrier mobility in the polycrystal is limited by grain boundaries and lattice misalignments between grains. The conventionally grown single crystal shows the lowest carrier mobility because of the energy barriers caused by the organic spacers along the film thickness direction. The inset shows the schematic measurement setup. The error bars are from measurements of five different devices. FIG. 2(b) shows time-resolved photoluminescence measurements showing a longer carrier lifetime in the superlattice than the polycrystal. The lifetime-power relationship in the polycrystal tends to deviate from a linear fit (the dashed lines) at high excitation power due to absorber degradation. The error bars are from measurements of five different devices. FIG. 2(c) shows temperature-dependent J-V measurements on solar cells (ITO/ICBA/perovskite/PTAA/Au; active size, 1 mm²) fabricated on as-grown films. The current density values are normalized. As temperature drops, the FE of the superlattice device does not change as dramatically as the polycrystal device, indicating a lower internal energy barrier in the superlattice. FIG. 2(d) shows scanning electron microscope images and corresponding EBIC mapping of the top surface of BA₂SnI₄ films. The polycrystal exhibits grain-dependent current signals. The superlattice exhibits stronger current signals with a crisscross pattern even with a smooth film surface. FIG. 2(e) show scanning electron microscopy images and corresponding EBIC mapping of the cross-section of BA₂SnI₄ films. The polycrystal exhibits grain-dependent current signals. The superlattice exhibits stronger current signals with a linear pattern. FIG. 2(f) shows thickness-dependent EQE measurements. The superlattice device exhibits a higher EQE with a larger optimum absorber thickness, indicating the carrier diffusion length in the superlattice is longer than that in the polycrystal. A broader collection range also indicates a smaller bandgap in the superlattice.

FIG. 3 illustrates strain properties of BA₂MAₙ₋₁SnₙI₃ₙ₊₁ superlattices. In particular, FIG. 3(a) shows X-ray diffraction measurements of the BA₂SnI₄ superlattice and conventionally grown BA₂SnI₄ single crystals. A compressive strain in the a-b plane and a tensile strain along the c direction are observed in the superlattice. FIG. 3(b) shows DFT computed and experimentally calculated lattice strain with different n in low-dimensional BA₂MAₙ₋₁SnₙI₃ₙ₊₁ perovskites. Crystals with larger n will have smaller strain. Inset scanning electron microscope images show that a larger n will result in a smoother surface, which is attributed to less defects under smaller epitaxial strain. FIG. 3(c) shows ellipsometry measurements of the dielectric function (ε′+iε″) of the BA₂MA₂Sn₃I₁₀ superlattice and conventionally grown BA₂MA₂Sn₃I₁₀ single crystals. The larger d in the superlattice indicates that the compressive strain can increase the dielectric constant and the Bohr radius in the superlattice. A redshift in the ε″ reveals that the compressive strain decreases the bandgap of the superlattice. FIG. 3(d) shows estimated exciton binding energies obtained from temperature-dependent photoluminescence measurements. The smaller fitted exciton binding energy in the superlattice than the polycrystal indicates a weaker quantum confinement effect because of the smaller width of the organic barrier. In the inset equation, I is the integrated photoluminescent intensity, I₀ is the integrated intensity at room temperature, A is an arbitrary constant, E_{B} is the exciton binding energy, k_{B} is the Boltzmann constant, and T is the temperature.

FIG. 4 presents photovoltaic studies of Bi³⁺-alloyed BA₂MA₂Sn₃I₁₀ superlattices. In particular, FIG. 4(a) shows the structure of the Bi³⁺-alloyed BA₂MA₂Sn₃I₁₀ superlattice computed by DFT. The Bi³⁺ ions preferentially aggregate at the interface between the organic and inorganic slabs to relieve the lattice strain (top). The Bi³⁺ alloying alters the electronic band structure, resulting in a substantially decreased CBM. Combined with the region without Bi³⁺, they form a double-band structure in the inorganic slab (bottom). FIG. 4(b) shows certified photovoltaic performance measurements, showing a bandgap of 1.042 eV and a V_{OC} of 0.967 V, beyond the Shockley-Queisser-limit. FIG. 4(c) shows unusual carrier transport processes with intra-band relaxation, resulting in beyond-band quasi-fermi-level splitting, and therefore, the high V_{OC}. Note that both Sn—I and Bi/Sn—I regions are in direct physical contact with the ETL. FIG. 4(d) shows single-wavelength excited J-V measurements of a polycrystalline solar cell with a uniform Bi³⁺ distribution and therefore, a single bandgap (left) and a superlattice (right) solar cell. In the polycrystalline device, reasonably small variations in the EE and V_{OC} are observed, indicating that the carrier transport and the collection efficiency are almost wavelength-independent. In the superlattice device, when the incident wavelength is shorter than ˜900 nm, neither EE nor V_{OC} exhibits an obvious wavelength-dependency. However, once the excitation wavelength is longer than ˜900 nm, both FE and V_{OC} drop substantially. FIG. 4(e) shows extracted EE and V_{OC} from FIG. 4(d).

FIG. 5 illustrates a dynamics analysis of hot electrons in Bi³⁺-alloyed superlattices. In particular, FIG. 5(a) shows the measured transient absorption spectra for Bi³⁺-alloyed BA₂MA₂Sn₃I₁₀ superlattice devices. It is clear to see the device exhibits obvious changes in GSB and ESA signal intensities with and without the 10 V bias, suggesting a bias dependent hot carrier dynamics in Bi³⁺-alloyed BA₂MA₂Sn₃I₁₀ superlattice devices. FIG. 5(b) shows the extracted hot carrier relaxation lifetime from FIG. 5(a) for Bi³⁺-alloyed BA₂MA₂Sn₃I₁₀ superlattice devices. Their lifetimes show negligible changes with and without the 10 V bias, excluding the influence of the applied bias on the hot carrier lifetimes.

FIGS. 6(a)-6(c) show schematics of different epitaxial models. Both models (a) and (b) can be considered to contain an infinite n-value perovskite layer, which is thermodynamically unstable. Only model (c) can form strong coherent metal-halide bonds between the substrate and the epitaxial layer with thermodynamically stable small n-values.

FIG. 7 shows detailed merging processes of epitaxial low-dimensional perovskites. SEM images clearly show that the initial crisscross crystals gradually expand and contact each other to form a completely merged thin film in the end.

FIG. 8 shows epitaxial growth of low-dimensional perovskites on different 3D perovskite substrates. Similar crisscross crystal morphology can be observed.

FIGS. 9 (a)-9(c) show studies of the precursors' n-purity. (a) Optical images showing the as-synthesized low-dimensional perovskites with different n values. Each has a flake morphology. (b) Distinct PL signals from those crystals suggesting that their n values are highly pure. Polycrystalline thin films fabricated by the as-prepared precursors exhibit similar behaviors, as shown by (c) UV-vis and (b) PL measurements, confirming that the as-prepared precursor yields low-dimensional perovskites with highly pure n values.

FIG. 10 shows fabrication of superlattices on commercially available BaF₂ substrates. Optical images show the commercially available BaF₂ (100) substrate before and after the superlattice growth (top panels). SEM images show the detailed growth steps: an epitaxial MAPb_{0.5}Sn_{0.5}Br₃ layer is grown on the BaF₂ first; then, the superlattice layer is grown on the MAPb_{0.5}Sn_{0.5}Br₃ layer, showing a similar cross-hatched crystal morphology (middle panels). Grazing-Incidence Wide-Angle X-ray Scattering mapping results show the crystal orientations of the MAPb_{0.5}Sn_{0.5}Br₃ and superlattice. The superlattice exhibits clear in-plane orientations.

FIGS. 11 (a)-11(b) show mapping of the d-spacing. (a) The extracted linear d-spacing curves from FIG. 1b. Along the b direction, the d-spacing of the epitaxial layer equals to that of the substrate. However, along the a direction, the d-spacing of the epitaxial layer is two times that of the substrate. (b) Detailed d-spacing mapping from both a-c and b-c planes. In the b direction, the lattice constant of the Sn—I slab (˜6.04 Å when conventionally grown, as calculated from XRD) is ˜5.96 Å, yielding 1.32% strain. In the a direction, the d-spacing is ˜11.92 Å, containing one Sn—I slab (˜6.04 Å when conventionally grown) and one organic spacer (˜7.00 Å when conventionally grown, as calculated from XRD), corresponding to an overall compressive strain of 8.59%, which matches to the XRD results perfectly.

FIG. 12 shows cross-sectional high-resolution STEM image of a polycrystalline film. It is clear that grain misorientations and boundaries exist along the thin-film thickness direction, indicating strong barriers for carrier transport in common devices with top and bottom contacts.

FIGS. 13(a)-13(b) show Grazing-Incidence Wide-Angle X-ray Scattering mapping of superlattices and polycrystalline thin films. (a) The epitaxial superlattices exhibit sharp and discrete Bragg spots that almost only appear along the xy and z directions. Specifically, periodic Bragg spots only appear along the xy axis in superlattices, which reveal that the inorganic slab/organic spacer quantum wells are perpendicular to the xy directions (i.e., the substrate surface) and parallel to the z direction, confirming their vertical out-of-plane orientations. In contrast, the random arc-like Bragg signals in polycrystalline thin films illustrate the random orientations of the crystal domains. (b) The 1D profiles extracted from a (top panel) match the XRD results from θ values in FIG. 3a

$$( Q = \frac{2 π}{θ} ; bottom panel ) ,$$

further confirming the vertical orientation of the superlattices. The peak splitting in the 1D profile of n=1 superlattice might come from the veined surface of the sample, where strong lattice strain generates lattice dislocations and a rugged surface (FIG. 3b insets).

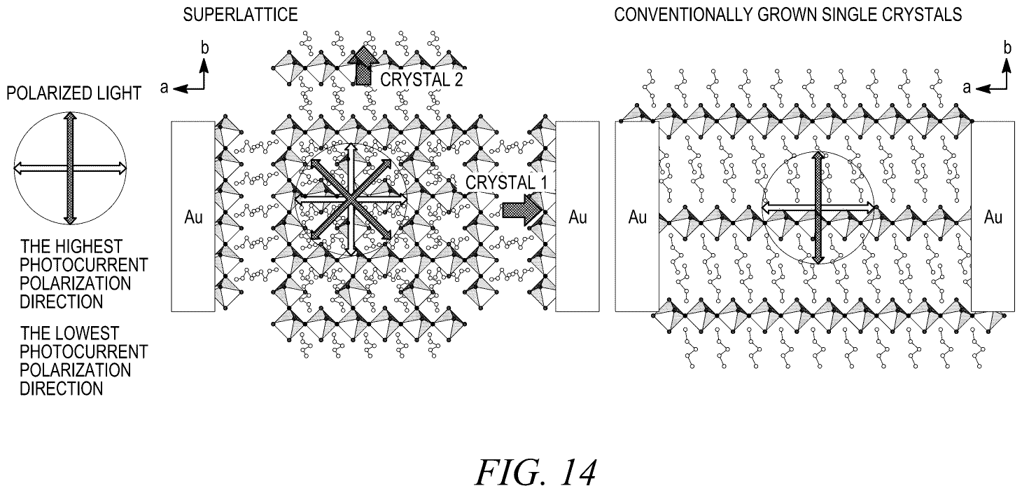

FIG. 14 shows schematics of polarized photocurrent measurements. The as-formed superlattice film contains a matrix-like structure, with two perpendicular crystals in two different orientations, corresponding to a 90° period for the polarized photocurrent. In contrast, the conventionally grown single crystal shows a 180° period due to its typical two-dimensional orientation.

FIGS. 15(a)-15(c) show orientation-dependent transient photovoltage measurements. (a) Schematics showing three Au electrode pairs on top of an epitaxial low-dimensional perovskite superlattice. The 0° and 90° are considered to be the same because the superlattice is formed by two perpendicular crystal plates, which exhibit a relatively long carrier lifetime. The 45° experiences organic barriers, leading to a relatively short carrier lifetime. (b) Schematics showing three Au electrode pairs on the side surface of a conventionally grown low-dimensional perovskite single crystal. The conventionally grown single crystals are relatively thin due to their intrinsic 2D characteristics. Therefore, a long-time is needed to grow such crystals so that the a-direction is thick enough for depositing electrodes on the side surface. The 0° exhibits the longest carrier lifetime due to the absence of organic barriers. In contrast, the 90° exhibits the shortest carrier lifetime, while the 45° condition shows a lifetime in between. (c) Representative raw data for samples with different orientation angles in FIG. 1d. The carrier lifetime was obtained by exponential fitting of the decay curves. The carrier lifetime is the interception between the slope of the decay curve and the decayed background.

FIG. 16 shows SEM images of polycrystalline thin films. Grain misorientations and boundaries are numerous, suggesting strong energy barriers in every direction.

FIGS. 17(a)-17(c) show schematics of transient photocurrent measurements of different device structures. (a) The conventionally grown single crystal has all organic spacers in the carrier transport direction, indicating the strongest energy barriers. (b) The polycrystal contains randomly orientated grains, where the organic spacers and the grain boundaries are isotropically distributed, suggesting strong energy barriers. (c) The epitaxial superlattice has no organic spacer in the carrier transport path, indicating negligible energy barriers.

FIG. 18 |shows fabrication processes for in-situ superlattice devices. The schematics show detailed steps for fabricating in-situ superlattice devices with fully strained superlattice perovskites in this work. Deposition of the ETL and top electrode follows the growth of superlattice.

FIGS. 19(a)-19(b) show configuration of in-situ fabricated devices. (a) An optical image of the pre-patterned polyimide mask with deposited Au and PTAA layers. (b) Schematic cross-section of the device (top panel). A pre-pattern polyimide (PI) is deposited with layers of Au and PTAA and used as the growth mask and the bottom contact. A thin epitaxial layer of substrate is grown first to facilitate the growth of strained low-dimensional perovskite superlattice. The top and bottom electrodes do not have the same size, where the calculated overlapped area (highlighted in orange) between the top and bottom electrodes is around 55% of the entire area, which sacrifices the achievable power conversion efficiency (bottom panel).

FIGS. 20(a)-20(b) show imperfect merging in the superlattice. (a) An SEM image of a superlattice that is intentionally broken to investigate the merging process. The merged film, albeit with a flat surface, may still bury invisible crystal boundaries. Structural defects are from the imperfect crystal merging because of the large lattice mismatch between the substrate and the organic spacer in the epitaxial layer. (b) Schematics showing the merging process with those crisscross thin crystal plates. The perfect merging, which requires the lattice orientation to be matched in both a and b directions, is impractical due to the existence of both organic spacers and inorganic slabs. The lattice misorientation between the organic spacers and inorganic slabs is impossible to avoid in practice, resulting in merging defects.

FIG. 21 shows schematic models of the epitaxial lattice strain. Computational results show the lattice parameters from optimized stable crystal structures. In the conventionally grown Ruddlesden-Popper structure, the length of the Sn—I bond adjacent to the organic spacer is ˜0.302 nm, and the distance between two I atoms is ˜0.700 nm, which contains one organic spacer. In the superlattice, the length of the Sn—I bond adjacent to the organic spacer is ˜0.297 nm, and the distance between two I atoms is ˜0.598 nm, which contains one organic spacer. The substrate has a Pb/Sn—Br bond of ˜0.298 nm. Due to the epitaxy, the superlattice is not the Ruddlesden-Popper structure anymore.

FIG. 22 shows Fourier-transform infrared spectroscopy characterizations. Both superlattice and conventionally grown single crystals have been characterized. The results show that the peaks in the superlattice shift apparently to higher wavenumbers, indicating the vibration frequencies of the organic bonds in the superlattice are enhanced, which is from the compressed organic spacers in the superlattice. To verify the observations, the Fourier-transform infrared spectroscopy has been simulated by only tunning the organic spacer from the original (conventionally grown) to the compressed (superlattice) states. In the computational results, the as-modeled superlattice exhibits clear peak shifting to higher wavenumbers than the conventionally grown structure, which is similar to the experimental measurement results, confirming that the compressed bonds in the organic spacer of the superlattice are the reason for the enhanced vibration frequency.

FIGS. 23(a)-23(b) show summary of degradation of superlattices with different n-values. (a) The degradation of superlattices is found to be highly related to the n-values. A higher n-value exhibits higher stability. (b) Schematics show the epitaxial superlattices with different n-values. If the volume ratio of the inorganic slabs is higher, the inorganic slabs are more resistant to the lattice strain applied from the compressed organic spacers.

FIGS. 24(a)-24(b) show degradation in the superlattice. (a) Optical images showing clear changes in the morphology and color from the fresh to the degraded superlattices, where the degraded samples show obviously amorphous structures. (b) Kelvin probe force microscopy measurements confirming that the work function decreases enormously in the degraded sample, suggesting more insulating properties. Additionally, the larger variations in the measured voltages of the degraded sample than those of the fresh sample also indicate that the surface uniformity has been largely damaged by the degradation.

FIG. 25 shows bandgaps for conventionally grown and superlattice low-dimensional Sn perovskites. Those values are from UV-Vis measurements under the reflection mode. The superlattices generally exhibit a smaller bandgap than the conventionally grown single crystals. As n increases, the bandgap also becomes smaller due to the reduced quantum confinement from the organic spacers. An extreme case is that when n equals to infinity, the low-dimensional perovskites become 3D perovskites.

FIG. 26 shows simulated unit cell of the BA₂MA₂Sn₃I₁₀ (n=3) superlattice. One unit cell has been modeled to represent the overall structure due to the limited computational resource available. Because only six Sn²⁺ ions are included in the modeling, the minimal Bi³⁺ percentage in the alloyed unit cell is 16.7%, which results from the replacement of one Sn²⁺ ion from the original six Sn²⁺ ions.

FIGS. 27(a)-27(b) show total energy calculations with Bi³⁺ alloying. (a) The unit cell structure for the BA₂MA₂Sn₃I₁₀ superlattice before Bi³⁺ alloying. To simplify the modeling, the lattice strain from the organic spacers is only applied from the left side. Sn atoms at different sites are marked with numbers from 1 to 6, which are replaced by the Bi³⁺ to form six different structures. (b) The total energy with the different sites (from 1 to 6) of Sn²⁺ to be replaced by Bi³⁺. When the Bi³⁺ is set to be at sites 3 or 6, the unit cell exhibits the smallest total energy, indicating the most stable structure.

FIGS. 28(a)-28(b) show XRD and PL characterizations of the Bi³⁺ alloyed superlattice. (a) XRD results show that there is no noticeable peak shifting after 10% Bi³⁺ alloying, and the superlattice structure also does not change because it is anchored by the substrate (left). After 10 days, the structure of the Bi³⁺ alloyed superlattices is still stable, but the structure of the Bi³⁺-free superlattices degrade obviously (right). (b) PL results show that the Bi³⁺ alloying decreases the bandgap (from a radiative band structure; red curve) compared with Bi³⁺-free superlattices (black curve). Additionally, Bi³⁺ alloying forms the band tail structure (from a non-radiative trap state; light brown curve) at different areas on the same sample (left). There has been a substantial decrease in the PL intensity of the Bi³⁺-free superlattices (black curve) but no noticeable change in the Bi³⁺ alloyed superlattices (red curve) after 10 days (right).

FIGS. 29(a)-29(b) show calculated electronic structures of the Bi³⁺ alloyed BA₂MA₂Sn₃I₁₀ superlattice. Bi³⁺ alloying vastly decreases the CBM position, resulting in a smaller bandgap. (a) The density of states (DOS) plot of the Bi/Sn—I region in FIG. 4a. (b) The DOS plot of the Sn—I region in FIG. 4a. The CBM position in a has been noticeably decreased compared with b, indicating that Bi/Sn—I region exhibits a smaller bandgap, which is mainly because of the energy contribution from the p orbitals of the Bi³⁺ ions.

FIG. 30 shows calculated electronic structures of the BA₂MA₂Sn₃I₁₀ superlattice when Bi³⁺ replaces Sn²⁺ at different sites. The Bi³⁺ can influence the electronic structure of surrounding Sn²⁺ by replacing the original Sn—I—Sn with the Sn—I—Bi. The DOS plots of the six ions in the unit cell are shown. Those ions closer to the Bi³⁺ have a smaller bandgap, which is caused by the decreased CBM position from the p orbitals of the Bi³⁺ ions.

FIGS. 31(a)-31(b) show X-ray photoelectron spectroscopy measurements of Bi³⁺ alloyed superlattice. Obvious peaks in (a) from the Bi 4f_{5/2} and Bi 4f_{7/2} are evident in the Bi³⁺ alloyed BA₂MA₂Sn₃I₁₀ superlattice. However, the Bi³⁺-free BA₂MA₂Sn₃I₁₀ superlattice in (b) does not have any noticeable peaks associated with Bi in this range of binding energy.

FIGS. 32(a)-32(b) show textured surfaces and light-trapping properties of the superlattice. (a) SEM images showing the textured surface of the epitaxial BA₂MA₄Sn₅I₁₆ layer grown on different crystal facets of the 3D perovskite substrate. (b) Reflection measurement results showing that the optimized tilting angle of the microstructures is 60° (left), which gives the smallest reflection, as evidenced by the optical images (right).

FIGS. 33(a)-33(b) show band structures of the ICBA layer. (a) UV-Vis measurements of the ICBA layer under the absorption mode. The bandgap is determined by the cutoff from the dash lines. (b) UPS measurements of the ICBA layer. The CBM is calculated by the cutoff from the dash lines in both high and low binding energy regions.

FIGS. 34(a)-(c) show the photovoltaic performance of a certificate device. A beyond-Shockley-Queisser-limit V_{OC} of 0.967 V has been recorded with a bandgap of 1.042 eV in a single-junction device. (a) The detailed report from Newport, where the Sn-based 2D perovskite (n=5) serves as the absorber layer with an Au/PTAA/perovskite/ICBA/ITO structure. The certified V_{OC} is 0.967 V under the quasi-steady-state condition. (b) The quantum efficiency plot of the certified device. The carrier collection cutoff (˜1190 nm) in the plot indicates that the device bandgap is 1.042 eV However, according to the Shockley-Queisser-limit, the theoretical maximal V_{OC} for such a photovoltaic is 0.802 V (c) The I-V curve of the certified device under the quasi-steady-state, showing negligible hysteresis because the high quality structure of the superlattice suppresses ion migration, reduces internal charge recombination, and eliminates accumulation of ions.

FIGS. 35(a)-35(d) show stability studies of strain-free superlattices. (a) In-plane XRD characterizations showing that the transferred strain-free superlattice can maintain an intact structure without degradation for at least one month. (b) PL and (c) time-resolved PL measurements confirming that carrier properties of the transferred strain-free superlattice do not degrade for at least one month. (d) Atomic force microscopy and Kelvin probe force microscopy measurements also indicate that the transferred strain-free superlattice does not experience morphological or electrical degradation.

FIGS. 36(a)-36(b) show stability studies of strain-free superlattice solar cells. (a) J-V measurements under 1000-hour continuous illumination showing that the strain-free superlattice solar cell exhibit a similar shape, indicating no obvious efficiency drop. The device is based on an ITO/SnO₂/BA₂SnI₄ superlattice/Spiro/Au structure, which might not give an optimal efficiency but is appropriate for studying the device stability. (b) Extracted short-circuit current density, fill factor, and V_{OC} from curves in a, confirming that the device decay is negligible. Those results suggest that the strain-free superlattice structure itself is stable because they are composed of stable low-dimensional perovskites.

FIGS. 37(a)-37(b) show the in-situ fabricated flexible superlattice photovoltaics. (a) Depositing Au and PTAA layers on the pre-patterned polyimide flexible mask to form a functionalized mask that can be directly used to fabricate devices. (b) The final device peeled off from the substrate without breaking the superlattice, suggesting the intrinsic flexibility of low-dimensional perovskites, where the soft organic spacers can serve as effective strain-releasing regions.

FIG. 38 shows schematics of carrier transport in the superlattice photovoltaic device. The patterned polyimide serves as the mask for epitaxial growth. A thin layer of MAPb_{0.5}Sn_{0.5}Br₃ (˜200 nm) is first epitaxially grown on the MAPb_{0.5}Sn_{0.5}Br₃ bulk substrate to provide uniform strain to the low-dimensional perovskites. The strained low-dimensional perovskite layer exhibits a vertical alignment to form a superlattice. In particular, the strain-induced Bi³⁺ alloying creates two different band structures in the inorganic slabs (Bi/Sn—I region and Sn—I region), where the Bi/Sn—I shows a smaller bandgap with a lowered CBM. Due to the energy barrier and long diffusion length between the Bi/Sn—I and the ETL layer, electrons are not likely to transport directly from the Bi/Sn—I to the ETL (white arrows). Instead, electrons are excited to high-energy states and diffuse to the Sn—I by intra-band relaxation and then transfer to the ETL (red arrows). Due to the energy barrier between the superlattice and the MAPb_{0.5}Sn_{0.5}Br₃ layer, holes are likely to accumulate/recombine at their interface to form band tail states. The holes can still be extracted by the HTL to close the charge flow loop.

FIGS. 39(a)-39(b) show fabrication processes of devices for transient absorption characterizations. The detailed schematics are for (a) superlattice devices and (b) polycrystalline devices. A bias can be applied to the perovskites and ICBA ETL by the two ITO electrodes, mimicking the built-in-potential in solar cells. A transparent double-sided polypropylene tape is used to prevent any current injection to the device, mimicking the open-circuit condition in solar cells.

FIGS. 40(a)-40(b) show measurements of transient absorption spectra. Transient absorption spectra are measured for (a) Bi³⁺-doped BA₂MA₂Sn₃I₁₀ polycrystalline thin film, and (b) Bi³⁺-free BA₂MA₂Sn₃I₁₀ superlattice. No obvious changes in GSB or ESA signals can be noticed with and without a 10 V bias, indicating the applied bias doe not influence the hot carrier dynamics in those samples.

FIGS. 41(a)-41(d) show processes of transient absorption measurements. (a) Probe pulse measurement, where the absorbance of the perovskite is proportional to the number of electrons in the valence band. (b) Pump pulse measurement, where the photo excitation happens. (c) Delay process, where a short time duration allows a portion of hot electrons to relax to the CBM and recombine with holes in the valence band. (d) Probe pulse measurement, where the absorbance of the perovskite will be measured again. The change in the number of electrons in the valence band leads to the GSB signal, while the change in the number of electrons in the conduction band results in the ESA signal.

FIGS. 42(a)-42(d) show measurements of hot carrier relaxation lifetimes and diffusion lengths without bias. The hot carrier relaxation lifetime is measured by transient absorption for (a) Bi³⁺-alloyed BA₂MA₂Sn₃I₁₀ superlattice, (b) Bi³⁺-free BA₂MA₂Sn₃I₁₀ superlattice, and (c) Bi³⁺-doped BA₂MA₂Sn₃I₁₀ polycrystalline thin film under zero bias. Both superlattices exhibit a much longer hot carrier relaxation lifetime than that of the polycrystalline thin film, indicating superb carrier dynamics in superlattices, which could be further confirmed by (d) the calculated hot carrier diffusion lengths, which are much larger than the width of the Bi/Sn—I region. Those results support the possibility of the intra-band relaxation from the Bi/Sn—I region to the Sn—I region.

FIGS. 43(a)-43(b) show measurements of hot carrier relaxation lifetimes with bias. The hot carrier relaxation lifetime is measured by transient absorption for (a) Bi³⁺-alloyed BA₂MA₂Sn₃I₁₀ superlattice, (b) Bi³⁺-free BA₂MA₂Sn₃I₁₀ superlattice, and (c) Bi³⁺-doped BA₂MA₂Sn₃I₁₀ polycrystalline thin film with a 10 V bias. All of these lifetimes show negligible changes from those without a bias. The results exclude the influence of the applied bias on the hot carrier lifetimes.

### ADDITIONAL EMBODIMENTS

The particular perovskite superlattices and the techniques employed for their fabrication have been presented for illustrative purposes and not as a limitation on the subject matter described herein. More generally, in one aspect, a method of forming a perovskite superlattice may comprise providing a single crystal substrate and exposing the single crystal substrate to a precursor composition having ions and molecules therein of which a perovskite is composed to thereby form a perovskite superlattice on the single crystal substrate. The perovskite superlattice includes at least one series of layers having alternating inorganic slabs and organic spacers. The single crystal substrate and the inorganic slabs have lattice constants that differ from one another by less than a prescribed amount.

In some embodiments the prescribed amount may be less than 20% and in other embodiments less than 13%.

In some embodiments the series of layers may include a first and second series of layers, the first series of layers extending in a plane that is orthogonal to the second series of layers, the first and second series of layers each including alternating inorganic slabs and organic spacers.

In some embodiments the orthogonal series of layers provide charge carrier transport in three-dimensions.

In some embodiments the perovskite superlattice is a metal halide perovskite superlattice.

In some embodiments the single crystal substrate includes a single crystal perovskite on which the perovskite superlattice is formed.

In some embodiments the precursor composition includes perovskite single crystals.

In some embodiments the precursor composition is a precursor solution in which the perovskite single-crystals are dissolved.

In some embodiments exposing the single crystal substrate to a precursor composition includes spin coating, drop coating, or solution soaking the precursor solution onto the single crystal substrate.

In some embodiments the precursor composition is a precursor gas.

In some embodiments the perovskite superlattice is formed from a metal halide perovskite with a formula of B₂Aₙ₋₁MₙX₃ₙ₊₁, where B=R—NH₃⁺; A=CH₃NH₃⁺ (MA), HC(NH₂)₂⁺, Cs⁺, or Rb⁺; M=Pb²⁺ or Sn²⁺; X=Cl⁻, Br⁻, or I⁻.

In some embodiments the substrate is patterned to thereby control distribution, orientation, and morphology of the perovskite superlattice.

In some embodiments the morphology of the perovskite superlattice includes an array of pyramids that serve as an antireflective structure.

In some embodiments the single crystal substrate is coated and patterned by one or more additional functional layers prior to formation of the perovskite superlattice.

In some embodiments the one or more additional functional layers include at least one functional layer selected from the group consisting of an electron transport layer, a hole transport layer, an electrode layer, a dielectric layer, a reflective cavity, and a semiconductive polymer layer.

In some embodiments the perovskite superlattice is doped with ions and/or molecules to change electronic and optical properties of the perovskite superlattice.

In some embodiments a lattice mismatch between the perovskite superlattice and the single crystal substrate gives rise to strain that changes electronic and optical properties of the perovskite superlattice.

In some embodiments the perovskite superlattice is peeled off from the single crystal substrate and transferred onto another substrate for characterization and device integration.

In some embodiments an optoelectronic device is provided that employs a perovskite superlattice formed in accordance with any of the embodiments of the method described above.

In some embodiments the optoelectronic device is selected from the group consisting of a solar cell, a sensor, a laser, and a light emitting diode.

In some embodiments the optoelectronic device is a solar cell having an open circuit voltage that appears to exceed a Shockley-Queisser limit.

In some embodiments the perovskite superlattice is doped with Bi³⁺, the Bi³⁺ being segregated due to lattice strain.

In some embodiments the segregated Bi³⁺ gives rise to formation of a double-band structure of the perovskite superlattice.

In some embodiments charge carriers in the double-band structure follow an intraband relaxation transport process that gives rise to the open circuit voltage that appears to exceed the Shockley-Queisser limit.

While various embodiments have been described above, it should be understood that they have been presented by way of example, and not limitation. It will be apparent to persons skilled in the relevant art(s) that various changes in form and detail can be made therein without departing from the spirit and scope. In fact, after reading the above description, it will be apparent to one skilled in the relevant art(s) how to implement alternative embodiments. Thus, the present embodiments should not be limited by any of the above described exemplary embodiments.

TABLE 1
Summarized lattice parameters and strains
in the epitaxial growth processes.

| Structure | a | b | c |
|---|---|---|---|
| MAPbBr₃ | ~0.598 nm | ~0.598 nm | ~0.598 nm |
| BA₂SnI₄ | ~1.304 nm | ~0.604 nm | ~0.604 nm |
| MASnBr₃ | ~0.594 nm | ~0.594 nm | ~0.594 nm |
| MAPb_{0.5}Sn_{0.5}Br₃ | ~0.596 nm | ~0.596 nm | ~0.596 nm |
| Superlattice BA₂Snl₄ | ~1.192 nm | ~0.596 nm | ~0.610 nm |
| BA spacer | ~0.700 nm | | |

| Structure | Lattice strain | Lattice strain |
|---|---|---|
| Superlattice BA₂SnI₄ | ~−1.66% along | ~0.99% |
| (inorganic slab) | the a direction | along the c |
| | ~−1.32% along | direction |
| | the b direction | |
| Superlattice BA₂SnI₄ | ~−14.60% | — |
| (organic spacer) | | |
| Superlattice BA₂SnI₄ | ~−8.59% | ~0.99% |
| (overall) | | |

Those values are calculated from STEM and XRD results. Negative means compressive strain, and positive means tensile strain.

TABLE 2
Summarized band structures of the materials
used in the certified photovoltaic device.

| Material | VBM | Bandgap | CBM |
|---|---|---|---|
| ICBA | −5.96 eV | 2.35 eV | −3.61 eV |
| PTAA | −5.02 eV | / | / |
| MAPb_{0.5}Sn_{0.5}Br₃ | −5.45 eV | 2.12 eV | −3.33 eV |
| BA₂MA₄Sn₅I₁₆ | −4.76 eV | 1.26 eV | −3.50 eV |
| 10% Bi-BA₂MA₄Sn₅I₁₆ | −4.76 eV | 1.04 eV | −3.72 eV |

Those values are calculated from UV-Vis and UPS measurements.

1. A method of forming a perovskite superlattice, comprising:
providing a single crystal substrate; and
exposing the single crystal substrate to a precursor composition having ions and molecules therein of which a perovskite is composed to thereby form a perovskite superlattice on the single crystal substrate, wherein the perovskite superlattice includes at least one series of layers having alternating inorganic slabs and organic spacers, the single crystal substrate and the inorganic slabs having lattice constants that differ from one another by less than a prescribed amount.

2. The method of claim 1 wherein the prescribed amount is less than 20%.

3. The method of claim 1 wherein the prescribed amount is less than 13%.

4. The method of claim 1 wherein the series of layers includes a first and second series of layers, the first series of layers extending in a plane that is orthogonal to the second series of layers, the first and second series of layers each including alternating inorganic slabs and organic spacers.

5. The method of claim 4 wherein the orthogonal series of layers provide charge carrier transport in three-dimensions.

6. The method of claim 1 wherein the perovskite superlattice is a metal halide perovskite superlattice.

7. The method of claim 1 wherein the single crystal substrate includes a single crystal perovskite on which the perovskite superlattice is formed.

8. The method of claim 1 wherein the precursor composition includes perovskite single crystals.

9. The method of claim 8 wherein the precursor composition is a precursor solution in which the perovskite single-crystals are dissolved.

10. The method of claim 9 wherein exposing the single crystal substrate to a precursor composition includes spin coating, drop coating, or solution soaking the precursor solution onto the single crystal substrate.

11. The method of claim 1 wherein the precursor composition is a precursor gas.

12. The method of claim 1 wherein the perovskite superlattice is formed from a metal halide perovskite with a formula of B₂Aₙ₋₁MX₃ₙ₊₁, where B=R—NH₃⁺; A=CH₃NH₃⁺ (MA), HC(NH₂)₂⁺, Cs⁺, or Rb⁺; M=Pb²⁺ or Sn²⁺; X=Cl⁻, Br⁻, or I⁻.

13. The method of claim 1 further comprising patterning the substrate to thereby control distribution, orientation, and morphology of the perovskite superlattice.

14. The method of claim 13 wherein the morphology of the perovskite superlattice includes an array of pyramids that serve as an antireflective structure.

15. The method of claim 1 wherein the single crystal substrate is coated and patterned by one or more additional functional layers prior to formation of the perovskite superlattice.

16. The method of claim 15 wherein the one or more additional functional layers include at least one functional layer selected from the group consisting of an electron transport layer, a hole transport layer, an electrode layer, a dielectric layer, a reflective cavity, and a semiconductive polymer layer.

17. The method of claim 1 wherein the perovskite superlattice is doped with ions and/or molecules to change electronic and optical properties of the perovskite superlattice.

18. The method of claim 1 wherein a lattice mismatch between the perovskite superlattice and the single crystal substrate gives rise to strain that changes electronic and optical properties of the perovskite superlattice.

19. The method of claim 1 further comprising peeling off the perovskite superlattice from the single crystal substrate and transferring the perovskite superlattice onto another substrate for characterization and device integration.

20. A perovskite superlattice formed in accordance with the method of claim 1.

21. An optoelectronic device employing a perovskite superlattice formed in accordance with the method of claim 1.

22. The optoelectronic device of claim 21 wherein the optoelectronic device is selected from the group consisting of a solar cell, a sensor, a laser, and a light emitting diode.

23. The optoelectronic device of claim 21 wherein the optoelectronic device is a solar cell having an open circuit voltage that appears to exceed a Shockley-Queisser limit.

24. The optoelectronic device of claim 23 wherein the perovskite superlattice is doped with Bi³⁺, the Bi³⁺ being segregated due to lattice strain.

25. The optoelectronic device of claim 24 wherein the segregated Bi³⁺ gives rise to formation of a double-band structure of the perovskite superlattice.

26. The optoelectronic device of claim 25 wherein charge carriers in the double-band structure follow an intraband relaxation transport process that gives rise to the open circuit voltage that appears to exceed the Shockley-Queisser limit.
